(19) United States
(12) Patent Application Publication
(10) Pub. No.: US 2026/0133486 A1
(43) Pub. Date: May 14, 2026

(54) RESIST COMPOSITION, LAMINATE AND PATTERNING PROCESS

(71) Applicant: SHIN-ETSU CHEMICAL CO., LTD., Tokyo (JP)

(72) Inventors: Kousuke OHYAMA, Joetsu-shi (JP); Shun Kikuchi, Joetsu-shi (JP); Satoshi Kusama, Joetsu-shi (JP); Masaki Ohashi, Joetsu-shi (JP)

(73) Assignee: SHIN-ETSU CHEMICAL CO., LTD., Tokyo (JP)

(21) Appl. No.: 19/383,193

(22) Filed: Nov. 7, 2025

(30) Foreign Application Priority Data
Nov. 14, 2024 (JP) 2024-199085

(51) Int. Cl. G03F 7/004; G03F 7/00; G03F 7/11

(52) U.S. Cl. CPC G03F 7/0045; G03F 7/11; G03F 7/70033

(57) ABSTRACT

A resist composition containing a hypervalent iodine compound represented by the following formula (1), a carboxy group-containing compound, and a solvent:

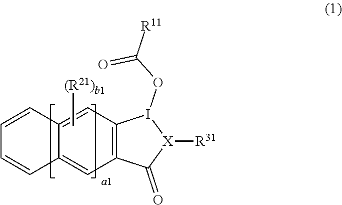

wherein a1 and b1 are each integers, when a1 is 0, b1 is 0 to 4, when a1 is 1, b1 is 0 to 6, and when a1 is 2, b1 is 0 to 8; R¹¹ is a halogen atom, or hydrocarbyl group having 1 to 10 carbon atoms and optionally containing a heteroatom; R²¹ is a halogen atom, or hydrocarbyl group having 1 to 40 carbon atoms and optionally containing a heteroatom; X is NR³¹ or S; and R³¹ is a hydrogen atom, a halogen atom, or hydrocarbyl group having 1 to 20 carbon atoms and optionally containing a heteroatom. This provides a non-chemically amplified resist composition excellent in sensitivity and resolvability in photolithography with a high energy line, and a patterning process using the resist composition.

### TECHNICAL FIELD

The present invention relates to a resist composition, a laminate, and a patterning process.

### BACKGROUND ART

Along with the expansion of the IoT market, LSIs are further required to have higher degree of integration, higher speed and lower power consumption, and the miniaturization of pattern rules are in rapid progress. In particular, logic devices lead the miniaturization. State-of-art miniaturization techniques carried out include volume manufacturing of 10-nm node devices by double patterning, triple patterning and quadruple patterning with ArF immersion lithography, and furthermore there are advanced studies about 7-nm node devices with next-generation extreme-ultraviolet (EUV) lithography at a wavelength of 13.5 nm.

With the progression of miniaturization, image blurs due to acid diffusion are problematic (Non Patent Document 1). In order to ensure the resolvability in fine patterns with a processing dimension of 45 nm or less, there is proposed the importance of not only an enhancement in dissolution contrast, which has been conventionally proposed, but also control of acid diffusion (Non Patent Document 2). However, chemically amplified resist compositions are increased in sensitivity and contrast by acid diffusion, and therefore, if acid diffusion is tried to be suppressed as much as possible by a reduction in post-exposure bake (PEB) temperature or a decrease in PEB time, such sensitivity and contrast remarkably deteriorate.

It is effective to suppress acid diffusion by addition of acid generators that generate bulky acids. There is then proposed copolymerization of acid generators of onium salts having polymerizable olefins, with polymers. However, patterning on resist films with a processing dimension of 16 nm or less is considered not to be able to be achieved with chemically amplified resist compositions from the viewpoint of acid diffusion, and non-chemically amplified resist compositions are demanded to be developed.

Examples of materials for non-chemically amplified resist compositions include polymethyl methacrylate (PMMA). PMMA is a positive resist material whose solubility in an organic solvent developer increases due to decreased molecular weight caused by scission of the main chain by EUV irradiation.

Hydrogen silsesquioxane (HSQ) is a negative type resist material that is made insoluble in an alkali developer due to crosslinking by a condensation reaction of silanol generated by EUV irradiation. Chlorine-substituted calixarene also serves as a negative type resist material. These negative type resist materials are small in molecular size before crosslinking and do not cause any blurs due to acid diffusion, therefore are small in edge roughness and very high in resolvability to allow the resolving limit of an exposure apparatus to be exhibited, and therefore are used as pattern transfer materials. However, these materials are insufficient in sensitivity and are required to be further improved.

Examples of factors making material development for EUV lithography difficult include a small number of photons in EUV exposure. The energy of EUV is much higher than that of ArF excimer laser light, and the number of photons in EUV exposure is one-fourteenth that of ArF exposure. Furthermore, the dimension of patterns formed in EUV exposure is less than half that in ArF exposure. Therefore, EUV exposure is easily affected by the variation in number of photons. The variation in number of photons in the region of radiation light at extremely short wavelengths is shot noise as a physical phenomenon, and the influence of this shot noise cannot be eliminated. Therefore, so-called probability theory (Stochastics) attracts attention. Although the influence of shot noise cannot be eliminated, how to reduce this influence is discussed. There is observed a phenomenon in which the influence of shot noise leads to not only increases in dimension uniformity (CDU) and line width roughness (LWR), but also blocking of holes at a probability of one several millionth. Such blocking of holes causes electric conduction failure not to allow for transistor operations, and therefore adversely affects the performance of the entire device. In a case where practical sensitivity is considered, resist compositions mainly containing PMMA or HSQ are largely affected by Stochastics, and cannot achieve the desired resolving performance.

With respect to methods for reducing the influence of shot noise by resists, introduction of elements with large absorption of EUV light attracts attention. Patent Document 1 proposes a chemically amplified resist composition containing an iodine atom with large absorption of EUV light. However, as described above, chemically amplified resist compositions cannot realize excellent resolving performance in EUV lithography in which processing dimensions will be hereafter increasingly miniaturized.

Patent Document 2 proposes a negative type resist composition in which a tin compound is used. This composition mainly contains a tin element with large absorption of EUV light, and therefore Stochastics can be improved and high sensitivity/high resolvability can be realized. However, so-called such metal resists have many problems such as insufficient solubility in solvents for resists, storage stability, and defects due to residues after etching.

On the contrary, Patent Document 3 proposes a positive type resist composition in which a hypervalent iodine compound is used. This composition contains an iodine element with large absorption of EUV light, and therefore Stochastics can be improved and high sensitivity/high resolvability can be realized as in metal resists. Furthermore, this composition is constituted from only organic molecules, and therefore the problems of metal resists, such as developer solubility and defects due to residues, can be improved. However, performance in the case of use as a resist material is still not satisfactory, and there is a demand for development of a resist material useful for further fine patterning.

### CITATION LIST

### Patent Literature

Patent Document 1: JP 2018-5224 A
Patent Document 2: JP 2021-503482 A
Patent Document 3: JP 2023-167368 A

### Non Patent Literature

Non Patent Document 1: SPIE Vol. 5039 p 1 (2003)
Non Patent Document 2: SPIE Vol. 6520 p 65203L-1 (2007)

### SUMMARY OF INVENTION

### Technical Problem

The present invention has been made in view of the above circumstances, and an object thereof is to provide a resist composition which is excellent in sensitivity and resolvability in photolithography with a high energy line, in particular, electron beam (EB) lithography and EUV lithography, and a patterning process in which the resist composition is used.

### Solution to Problem

In order to solve the above problems, the present invention provides a resist composition comprising a hypervalent iodine compound represented by the following formula (1), a carboxy group-containing compound, and a solvent:

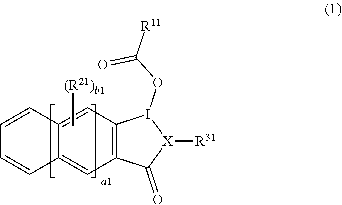

wherein a1 is 0, 1 or 2; when a1 is 0, b1 is 0, 1, 2, 3 or 4; when a1 is 1, b1 is 0, 1, 2, 3, 4, 5 or 6; when a1 is 2, b1 is 0, 1, 2, 3, 4, 5, 6, 7 or 8; R¹¹ is each independently a halogen atom, or a hydrocarbyl group having 1 to 10 carbon atoms and optionally containing a heteroatom; R²¹ is each independently a halogen atom, or a hydrocarbyl group having 1 to 40 carbon atoms and optionally containing a heteroatom; when b1 is 2 or more, R²¹s are the same as or different from each other, and plural R²¹s are optionally bound to each other to form a ring together with carbon atoms in an aromatic ring to which these are bound; “X” is a nitrogen atom or a sulfur atom, and optionally has R³¹ in the case of being a nitrogen atom; and R³¹ is a hydrogen atom, a halogen atom, or a hydrocarbyl group having 1 to 20 carbon atoms and optionally containing a heteroatom.

Such a resist composition of the present invention is excellent in sensitivity and resolvability in photolithography with a high energy line, in particular, EB lithography and EUV lithography.

In this case, the carboxy group-containing compound is preferably one or both of a polymer containing a repeating unit represented by the following formula (2) and a compound represented by the following formula (3):

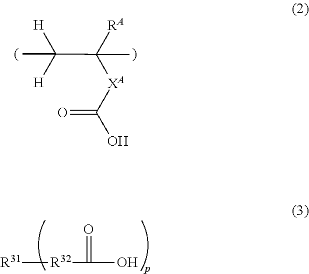

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone;
p is 1, 2, 3 or 4;
R⁴¹ is a p-valent hydrocarbon group having 1 to 40 carbon atoms or a p-valent heterocyclic group having 2 to 40 carbon atoms, and when p is 2, R⁴¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; and
R⁴² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when p is 2, 3 or 4, R⁴²s are the same as or different from each other.

The carboxy group-containing compound contained in the resist composition of the present invention is preferably the polymer or the monomolecular compound.

The resist composition can further comprise at least one of a hypervalent iodine compound represented by the following formula (4) or (5):

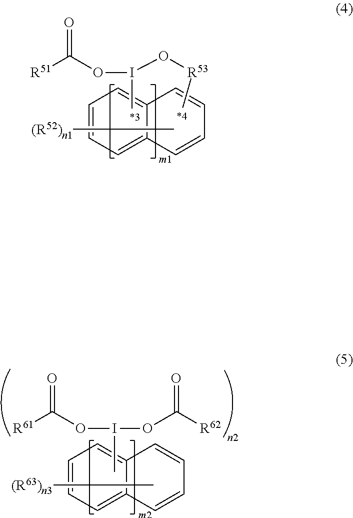

wherein m1 and m2 are each an integer of 0 to 2, and n1 is an integer of 0 to 4 when m1 is 0, n1 is an integer of 0 to 6 when m1 is 1, and n1 is an integer of 0 to 8 when m1 is 2; when m2 is 0, n2 is an integer of 1 to 3, n3 is an integer of 0 to 5, and 1≤(n2+n3)≤6 is satisfied; when m2 is 1, n2 is an integer of 1 to 3, n3 is an integer of 0 to 7, and 1≤(n2+n3)≤8 is satisfied; when m2 is 2, n2 is an integer of 1 to 3, n3 is an integer of 0 to 9, and 1≤(n2+n3)≤10 is satisfied; R⁵¹ is a halogen atom, or a hydrocarbyl group having 1 to 10 carbon atoms and optionally containing a heteroatom; R⁵² is a halogen atom, or a hydrocarbyl group having 1 to 40 carbon atoms and optionally containing a heteroatom; when n1 is 2 to 8, R⁵²s are the same as or different from each other, and plural R⁵²s are optionally bound to each other to form a ring together with carbon atoms in an aromatic ring to which these are bound; R⁵³ is a hydrocarbylene group having 1 to 10 carbon atoms and optionally containing a heteroatom; *3 and *4 each represent a point of attachment to a carbon atom in an aromatic ring in the formula, provided that *3 and *4 are bound to adjacent carbon atoms in an aromatic ring; R⁶¹ and R⁶² are each independently a halogen atom, or a hydrocarbyl group having 1 to 10 carbon atoms and optionally containing a heteroatom, and R⁶¹ and R⁶² are optionally bound to each other to form a ring together with carbon atoms to which these are bound and an atom between the carbon atoms; when n2 is 2 to 3, R⁶¹s and R⁶²s are the same as or different from each other; R⁶³ is a halogen atom, or a hydrocarbyl group having 1 to 40 carbon atoms and optionally containing a heteroatom; and when n3 is 2 to 9, R⁶³s are the same as or different from each other, and plural R⁶³s are optionally bound to each other to form a ring together with carbon atoms in an aromatic ring to which these are bound.

The hypervalent iodine compound further contained in the resist composition of the present invention is preferably a tricoordinate hypervalent iodine compound represented by the above formula. Such a tricoordinate iodine (III) compound having an aryl group and a carboxylate ligand is mixed with the carboxy group-containing compound to result in exchange of the compound and the carboxylate ligand in an equilibrium reaction, as in the hypervalent iodine compound represented by the formula (1). The original carboxylate ligand is removed from the reaction system to shift the equilibrium toward generation of a new hypervalent iodine compound having a ligand, thereby allowing ligand exchange to progress. Thus, a polymer is provided in which the carboxy group-containing compound is crosslinked by the hypervalent iodine compound. At least one of the hypervalent iodine compound represented by the formula (4) or (5) is further contained to allow polymerization to more preferably progress.

The present invention also provides a laminate comprising a substrate, and a resist film formed on the substrate, the resist film being a film made of the resist composition.

A laminate comprising a resist film obtained from the resist composition of the present invention can be widely used in a variety of applications and is highly useful for resist process techniques because a resist film which is a film made of the resist composition not only has high sensitivity and furthermore exhibits excellent limit resolvability and is effective for precise microfabrication, but also can be applied to both of positive type patterning and negative type patterning.

In this case, a resist underlayer film can be further provided between the substrate and the resist film. In addition, the resist film preferably contains a product of a ligand exchange reaction between the hypervalent iodine compound and a carboxy group-containing compound.

The laminate of the present invention can be, if necessary, according to such an aspect.

The present invention also provides a patterning process comprising the steps of: forming a resist film on a substrate or a resist underlayer film on a substrate on which the resist underlayer film is laminated, with the resist composition; exposing the resist film to a high energy line; and developing the exposed resist film with a developer.

The patterning process of the present invention, in which a resist composition excellent in sensitivity and resolvability in photolithography with a high energy line, in particular, electron beam (EB) lithography and EUV lithography is used, thus is useful for further fine patterning.

In this case, an i-line, a KrF excimer laser, an ArF excimer laser, an electron beam or an extreme-ultraviolet ray is preferably used as the high energy line.

The patterning process of the present invention can allow for finer patterning by use of such a high energy line.

In the patterning process of the present invention, a developer that dissolves an exposed area and that does not dissolve an unexposed area or a developer that dissolves an unexposed area and that does not dissolve an exposed area can be used as the developer.

The patterning process of the present invention can form a positive type or negative type pattern by appropriately selecting the developer, and therefore can be widely applied to various kinds of fine patterning.

### Advantageous Effects of Invention

The resist composition of the present invention exhibits both high sensitivity and high resolvability, in particular, in EB lithography and EUV lithography, and is extremely effective for formation of a fine pattern.

### DESCRIPTION OF EMBODIMENTS

The present inventors have made intensive studies in order to achieve the above objects, and as a result, have found that a resist composition mainly containing predetermined hypervalent iodine compound and carboxy group-containing compound (polymer or monomolecular compound) has extremely high sensitivity, provides a resist film exhibiting excellent resolving power, and is extremely effective for precise microfabrication, and thus the present invention has been completed.

Specifically, the present invention relates to a resist composition containing a hypervalent iodine compound represented by the following formula (1), a carboxy group-containing compound, and a solvent:

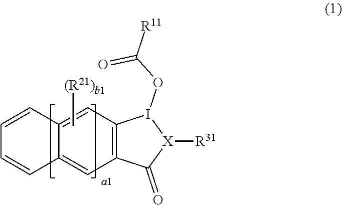

wherein a1 is 0, 1 or 2; when a1 is 0, b1 is 0, 1, 2, 3 or 4; when a1 is 1, b1 is 0, 1, 2, 3, 4, 5 or 6; when a1 is 2, b1 is 0, 1, 2, 3, 4, 5, 6, 7 or 8; R¹¹ is each independently a halogen atom, or a hydrocarbyl group having 1 to 10 carbon atoms and optionally containing a heteroatom; R²¹ is each independently a halogen atom, or a hydrocarbyl group having 1 to 40 carbon atoms and optionally containing a heteroatom; when b1 is 2 or more, R²¹s are the same as or different from each other, and plural R²¹s are optionally bound to each other to form a ring together with carbon atoms in an aromatic ring to which these are bound; “X” is a nitrogen atom or a sulfur atom, and optionally has R³¹ in the case of being a nitrogen atom; and R³¹ is a hydrogen atom, a halogen atom, or a hydrocarbyl group having 1 to 20 carbon atoms and optionally containing a heteroatom.

Hereinafter, the present invention is described in detail, but the present invention is not limited thereto. It is noted that the designation with end points of a numerical value range herein encompasses all values included in the range (for example, “0 to 3” includes 0, 1, 2 and 3).

### [Resist Composition]

The resist composition of the present invention mainly contains predetermined hypervalent iodine compound, carboxy group-containing compound and solvent. Herein, the carboxy group is an atomic group (functional group) having a structure of “—C(═O)OH”.

### [Hypervalent Iodine Compound]

A hypervalent iodine compound essential in the present invention is a tricoordinate hypervalent iodine compound represented by the following formula (1):

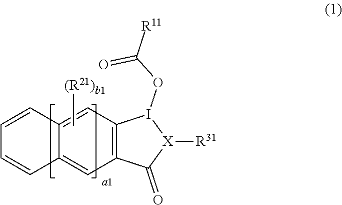

wherein a1 is 0, 1 or 2; when a1 is 0, b1 is 0, 1, 2, 3 or 4; when a1 is 1, b1 is 0, 1, 2, 3, 4, 5 or 6; when a1 is 2, b1 is 0, 1, 2, 3, 4, 5, 6, 7 or 8; R¹¹ is each independently a halogen atom, or a hydrocarbyl group having 1 to 10 carbon atoms and optionally containing a heteroatom; R²¹ is each independently a halogen atom, or a hydrocarbyl group having 1 to 40 carbon atoms and optionally containing a heteroatom; when b1 is 2 or more, R²¹s are the same as or different from each other, and plural R²¹s are optionally bound to each other to form a ring together with carbon atoms in an aromatic ring to which these are bound; “X” is a nitrogen atom or a sulfur atom, and optionally has R³¹ in the case of being a nitrogen atom; and R³¹ is a hydrogen atom, a halogen atom, or a hydrocarbyl group having 1 to 20 carbon atoms and optionally containing a heteroatom.

In the formula (1), a1 is an integer of 0 to 2, when a1 is 0, b1 is an integer of 0 to 4, when a1 is 1, b1 is an integer of 0 to 6, and when a1 is 2, b1 is an integer of 0 to 8. b1 is preferably 0 to 8, more preferably 0 to 6, further preferably 0 to 4, still further preferably 0 to 2, most preferably 0 or 1. Herein, when a1 is 0, the aromatic ring is a benzene ring.

In the formula (1), R¹¹ is a halogen atom, or a hydrocarbyl group having 1 to 10 carbon atoms and optionally containing a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be any of straight, branched or cyclic. Specific examples thereof include alkyl groups each having 1 to 10 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group and an adamantyl group; alkenyl groups each having 2 to 10 carbon atoms, such as a vinyl group and an allyl group; aryl groups each having 6 to 10 carbon atoms, such as a phenyl group and a naphthyl group; and any group obtained by combination thereof. In addition, some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R¹¹ is preferably a hydrocarbyl group having 1 to 4 carbon atoms or a fluorinated hydrocarbyl group having 1 to 4 carbon atoms, more preferably a hydrocarbyl group having 1 to 4 carbon atoms.

In the formula (1), R²¹ is a halogen atom, or a hydrocarbyl group having 1 to 40 carbon atoms and optionally containing a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be any of straight, branched or cyclic. Specific examples thereof include alkyl groups each having 1 to 40 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. In addition, some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. When b1 is 2 or more, R²¹s are the same as or different from each other. In addition, plural R²¹s are optionally bound to each other to form a ring together with carbon atoms in an aromatic ring to which these are bound. In addition, R²¹ can be a substituent at any position on the aromatic ring in the above formula.

In the formula (1), R³¹ is a hydrogen atom, a halogen atom, or a hydrocarbyl group having 1 to 20 carbon atoms and optionally containing a heteroatom. The hydrocarbyl group having 1 to 20 carbon atoms may be saturated or unsaturated, and may be any of straight, branched or cyclic. Specific examples thereof include alkyl groups each having 1 to 20 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 20 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; alkenyl groups each having 2 to 20 carbon atoms, such as a vinyl group and a propenyl group; aryl groups each having 6 to 20 carbon atoms, such as a phenyl group, a methylphenyl group, an ethylphenyl group, a n-propylphenyl group, an isopropylphenyl group, a n-butylphenyl group and a naphthyl group; and any group obtained by combination thereof. In addition, some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, an alkyl halide group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R³¹ is preferably a hydrogen atom, a hydrocarbyl group having 1 to 10 carbon atoms, such as a methyl group, a phenyl group, or a naphthyl group, or a fluorinated hydrocarbyl group having 1 to 10 carbon atoms.

Specific examples of the hypervalent iodine compound represented by the formula (1) include the following hypervalent iodine compounds, but not limited thereto. Herein, in the following formulae, Me is a methyl group.

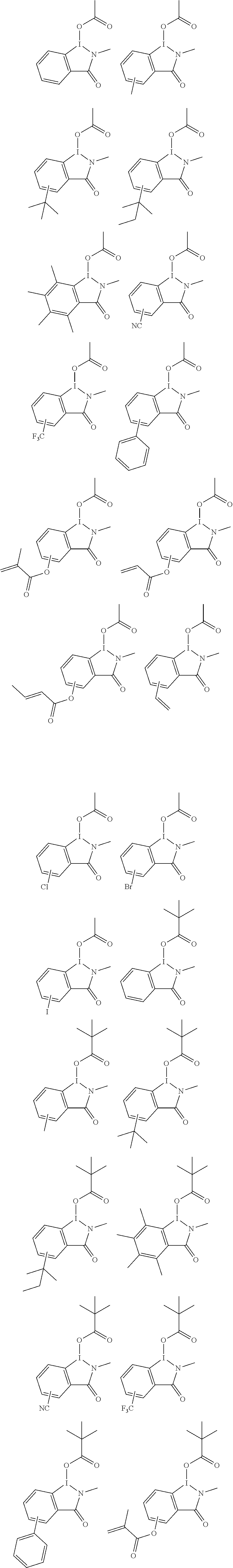

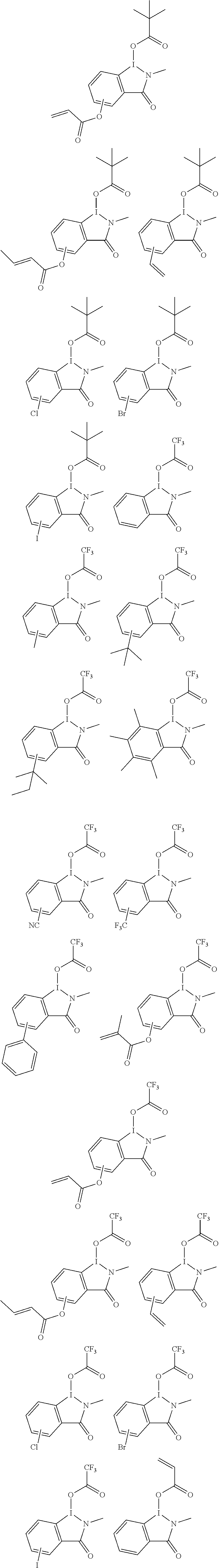

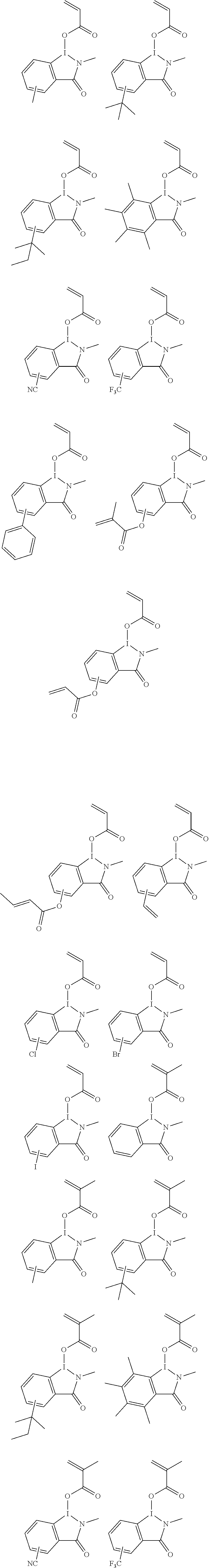

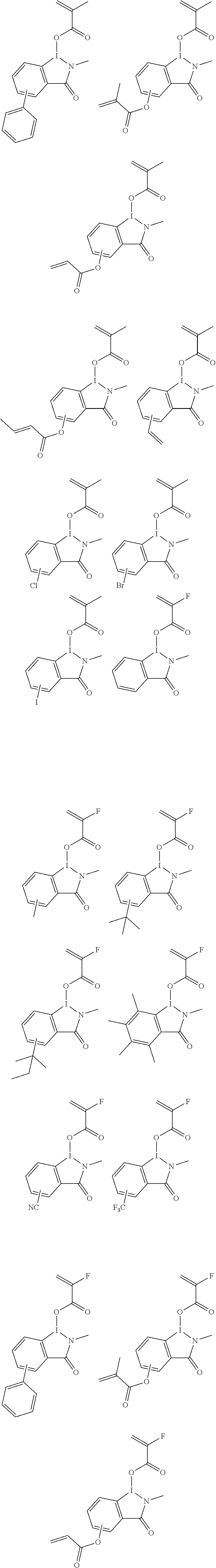

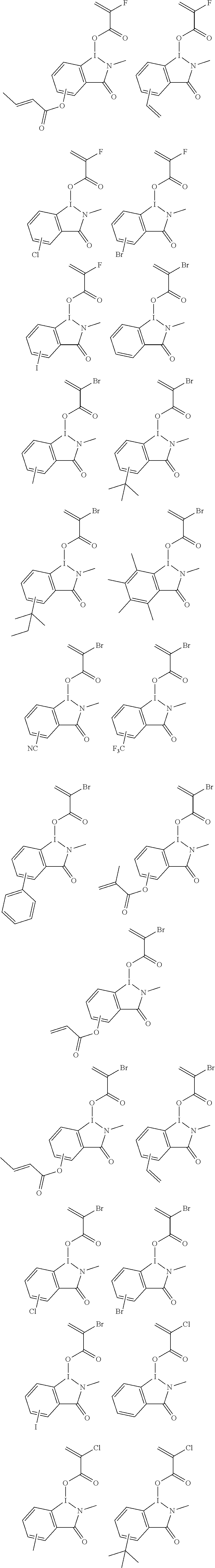

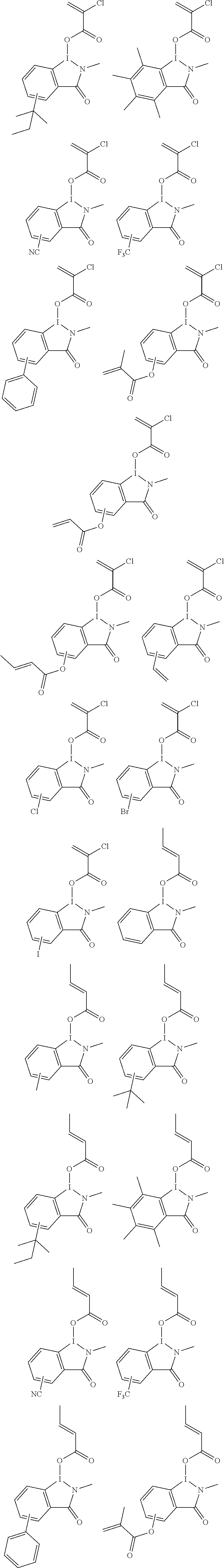

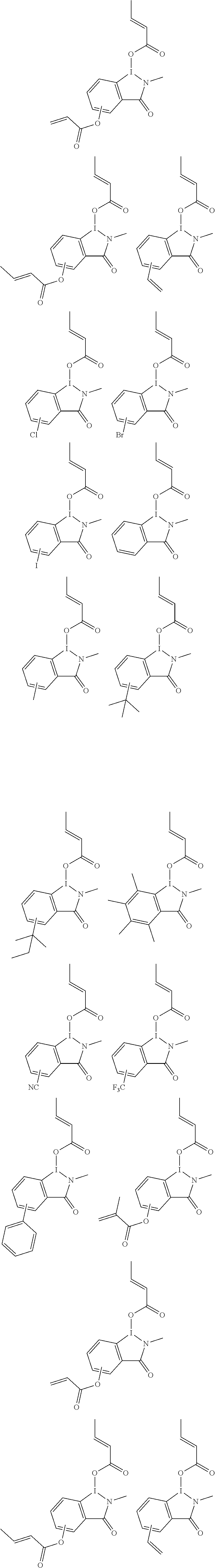

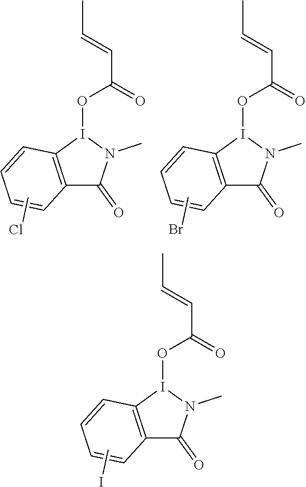

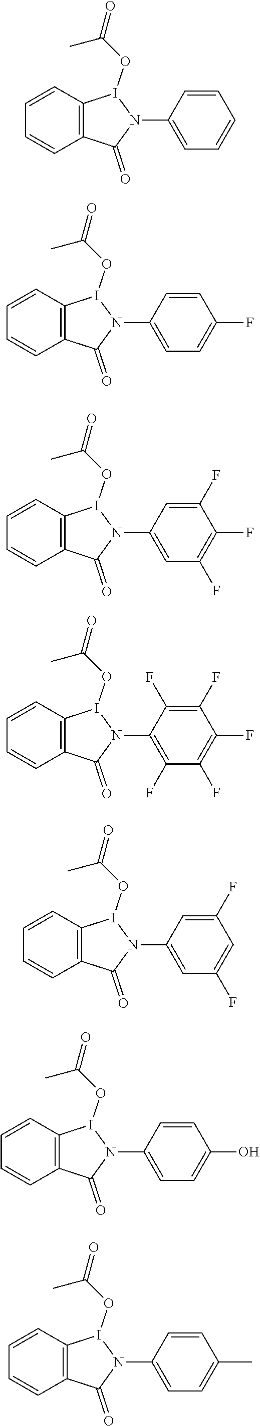

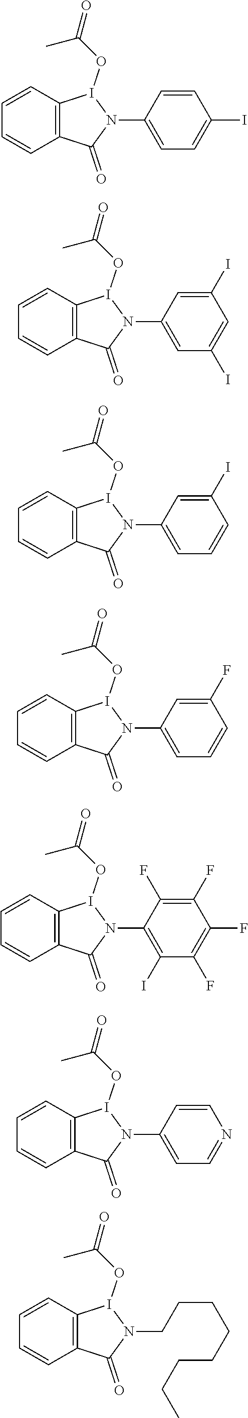

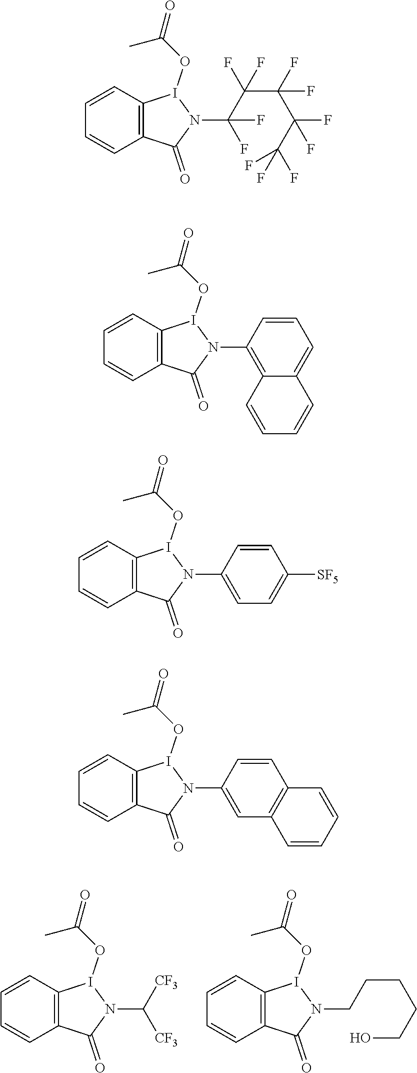

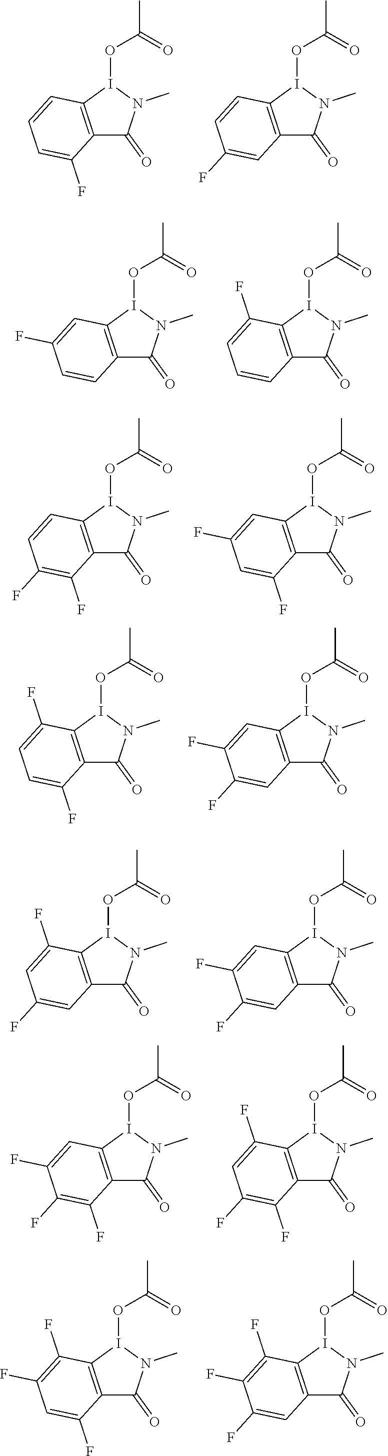

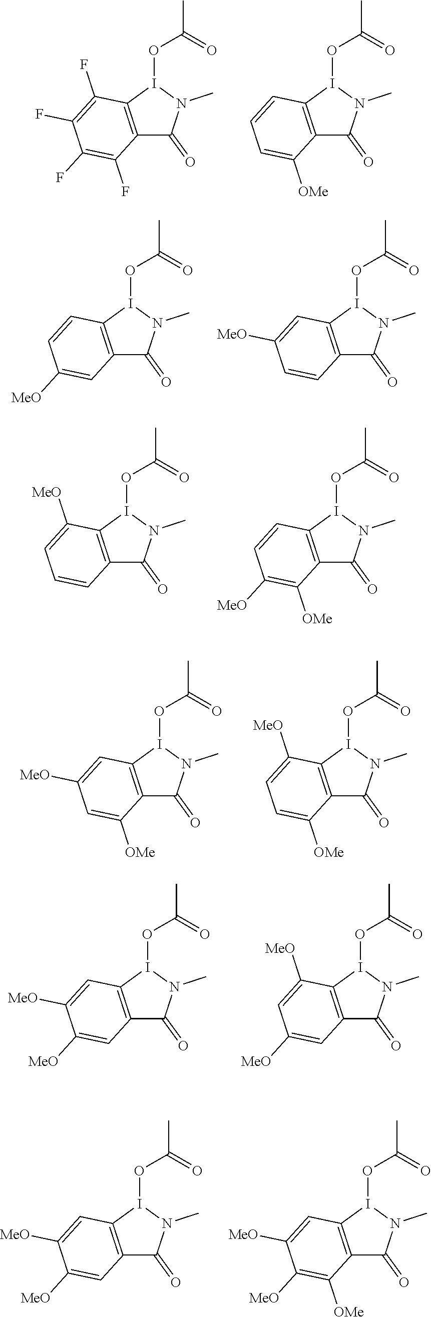

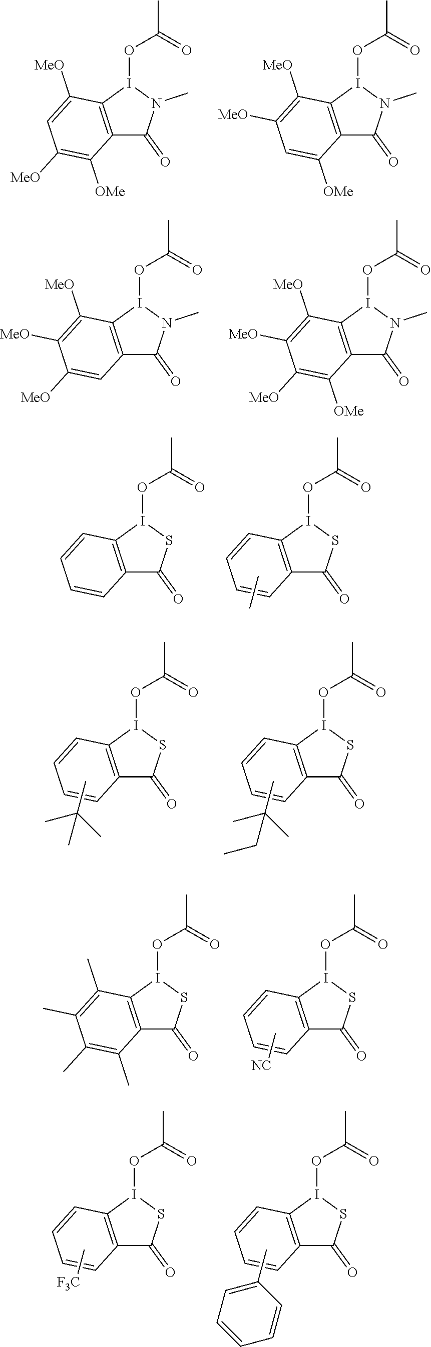

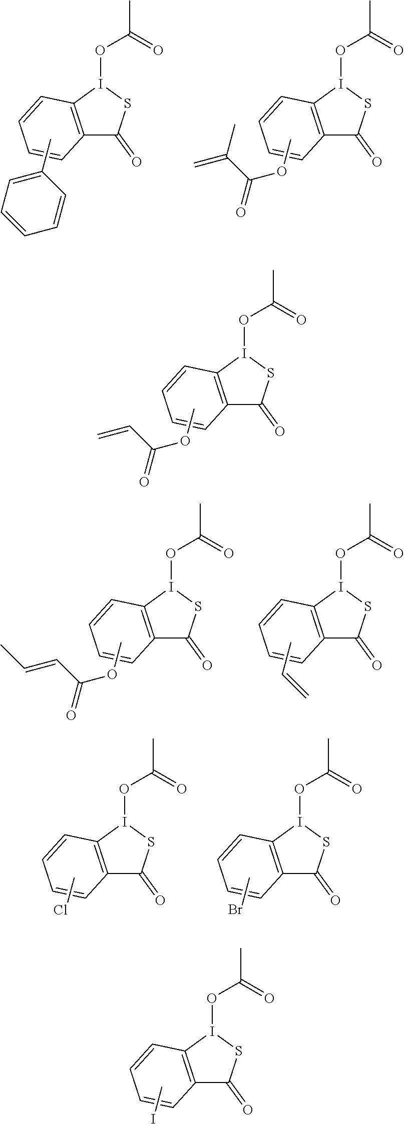

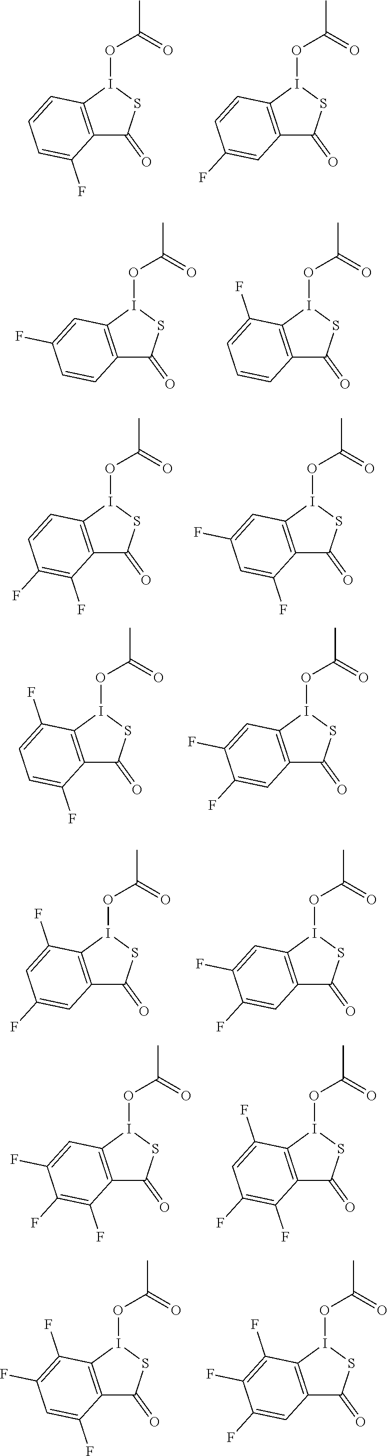

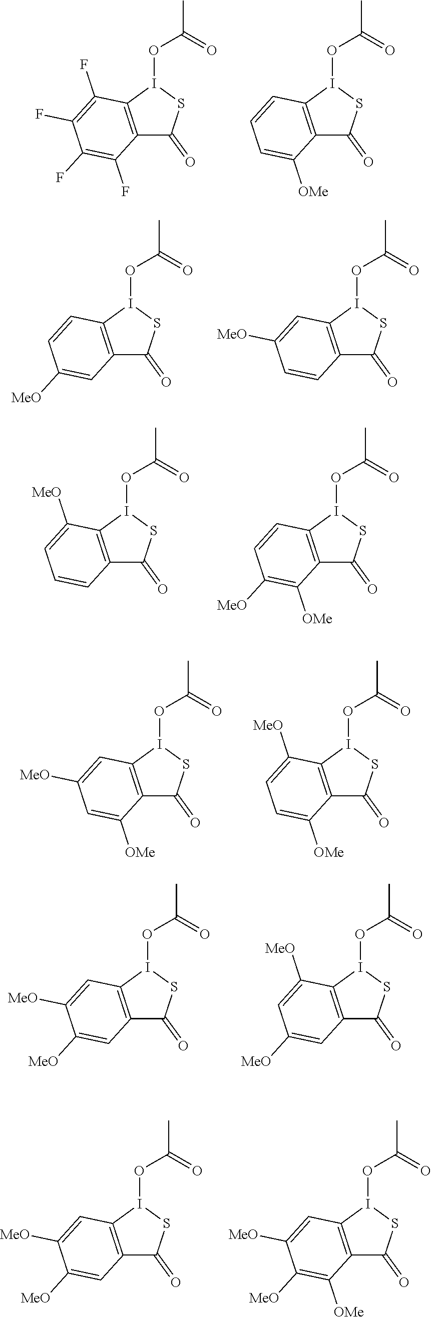

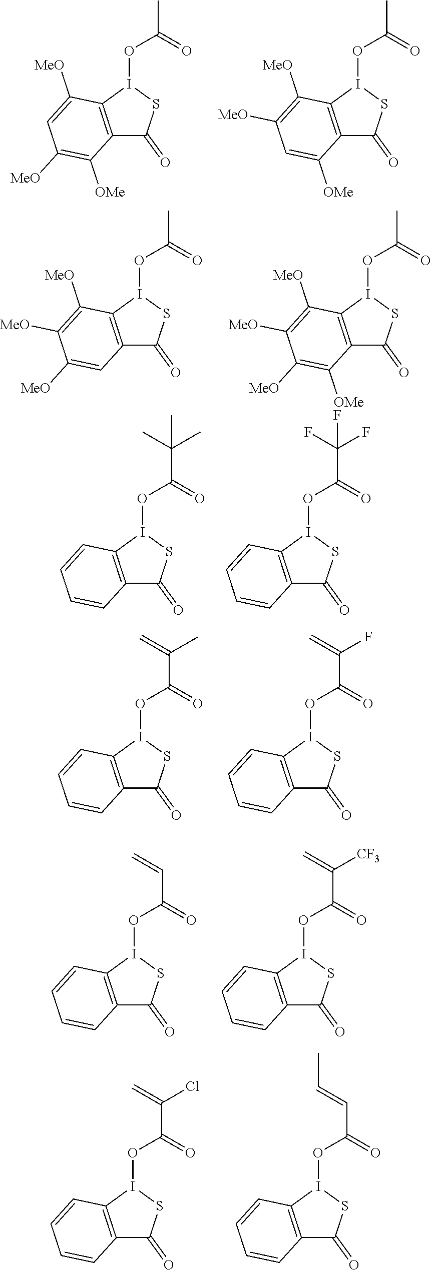

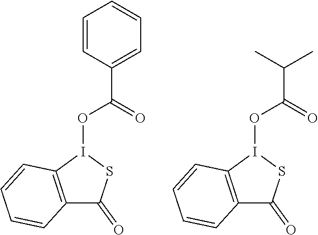 [SMILES: O=C(OI1SC(=O)c2ccccc21)c1ccccc1 ; CC(C)C(=O)OI1SC(=O)c2ccccc21]

### [Method for Producing Hypervalent Iodine Compound]

The hypervalent iodine compound used in the present invention can be obtained by a known method. For example, when an objective hypervalent iodine compound is a 5-membered heterocycle containing iodine (III) and nitrogen, the compound can be obtained by oxidatively ring-closing 2-iodobenzamide with an oxidant such as peracetic acid and then acetylating an OH group or an NH group with acetic anhydride or the like. A compound with a 5-membered heterocycle containing sulfur instead of nitrogen can also be obtained in the same manner. In the formula (1), when “X” is a nitrogen atom and R³¹ is one other than a hydrogen atom, 2-iodobenzamide substituted with R³¹ may be used as a raw material or R³¹ may be introduced by an appropriate substitution reaction after formation of a 5-membered heterocycle. The synthetic method can be seen in, for example, J. Am. Chem. Soc., 1997, vol. 119, No. 31, p. 7408-7409, or JP 2015-186792 A.

### [Carboxy Group-Containing Compound]

The carboxy group-containing compound is preferably a polymer containing a repeating unit represented by the following formula (2) or a compound represented by the following formula (3):

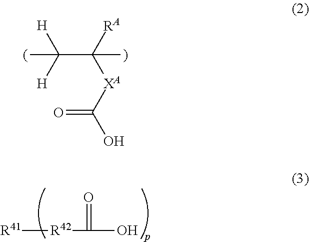

wherein R^{A} is a hydrogen atom, a halogen atom, a methyl group or a trifluoromethyl group; X^{A} is a single bond, a phenylene group, a naphthylene group, or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; * represents a point of attachment to a carbon atom in a backbone; “p” is 1, 2, 3 or 4; R⁴¹ is a p-valent hydrocarbon group having 1 to 40 carbon atoms or a p-valent heterocyclic group having 2 to 40 carbon atoms, and when “p” is 2, R⁴¹ is optionally an ether bond, a carbonyl group, an azo group, a thioether bond, a carbonate bond, a carbamate bond, a sulfinyl group or a sulfonyl group; some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; R⁴² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when “p” is 2, 3 or 4, R⁴²s are the same as or different from each other.

In the formula (2), R^{A} is a hydrogen atom, a halogen atom, a methyl group or a trifluoromethyl group; X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a backbone.

In the formula (3), p is 1, 2, 3 or 4.

In the formula (3), R⁴¹ is a p-valent hydrocarbon group having 1 to 40 carbon atoms or a p-valent heterocyclic group having 2 to 40 carbon atoms, and when “p” is 2, R⁴¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom.

In the formula (3), R⁴² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when “p” is 2, 3 or 4, R⁴²s are the same as or different from each other.

The p-valent hydrocarbon group represented by R⁴¹ may be saturated or unsaturated, and may be any of straight, branched or cyclic. The p-valent hydrocarbon group is a hydrocarbon group from which “p” hydrogen atoms of this group are removed. Examples of the hydrocarbon include alkane having 1 to 40 carbon atoms, alkene having 2 to 40 carbon atoms, alkyne having 2 to 40 carbon atoms, cyclic saturated hydrocarbon having 3 to 40 carbon atoms, cyclic unsaturated hydrocarbon having 3 to 40 carbon atoms, and aromatic hydrocarbon having 6 to 40 carbon atoms.

Examples of the alkane having 1 to 40 carbon atoms include methane, ethane, propane, butane, pentane, hexane, heptane, octane, nonane, decane, and any structural isomer thereof.

Examples of the alkene having 2 to 40 carbon atoms include ethylene, propylene, butene, pentene, hexene, heptene, octene, nonene, decene, and any structural isomer thereof.

Examples of the alkyne having 2 to 40 carbon atoms include acetylene, propyne, butyne, pentyne, hexyne, heptyne, octyne, nonyne, decyne, and any structural isomer thereof.

Examples of the cyclic saturated hydrocarbon having 3 to 40 carbon atoms include cyclopropane, cyclobutane, cyclohexane, cycloheptane, cyclooctane, adamantane, and norbornane.

Examples of the cyclic unsaturated hydrocarbon having 3 to 40 carbon atoms include cyclopropene, cyclobutene, cyclopentene, cyclohexene, cycloheptene, cyclooctene, and norbornene.

Examples of the aromatic hydrocarbon having 6 to 40 carbon atoms include benzene, naphthalene, and biphenyl.

The p-valent heterocyclic group represented by R⁴¹ is a heterocyclic group from which “p” hydrogen atoms of this group are removed. Examples of the heterocyclic compound include furan, pyridine, pyrazole, and thiazolidine.

Some or all of hydrogen atoms in the p-valent hydrocarbon group or p-valent heterocyclic group are each optionally substituted by a group containing a heteroatom such as an oxygen atom, a sulfur atom, a nitrogen atom, or a halogen atom, and as a result, a hydroxy group, a cyano group, a fluorine atom, a chlorine atom, a bromine atom, an iodine atom, or the like is optionally contained. Some of —CH₂— constituting the p-valent hydrocarbon group are each optionally substituted by a group containing a heteroatom such as an oxygen atom, a sulfur atom, or a nitrogen atom, and as a result, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained.

The hydrocarbylene group represented by R⁴² may be saturated or unsaturated, and may be any of straight, branched or cyclic. Specific examples thereof include alkanediyl groups each having 1 to 20 carbon atoms, such as a methanediyl group, an ethane-1,1-diyl group, an ethane-1,2-diyl group, a propane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group and a dodecane-1,12-diyl group; cyclic saturated hydrocarbylene groups each having 3 to 20 carbon atoms, such as a cyclopentanediyl group, a cyclohexanediyl group, a norbornanediyl group and an adamantanediyl group; unsaturated aliphatic hydrocarbylene groups each having 2 to 20 carbon atoms, such as a vinylene group and a propene-1,3-diyl group; arylene groups each having 6 to 20 carbon atoms, such as a phenylene group and a naphthylene group; and any group obtained by combination thereof. Some or all of hydrogen atoms in the hydrocarbylene group are each optionally substituted by a group containing a heteroatom such as an oxygen atom, a sulfur atom, a nitrogen atom, or a halogen atom, some of —CH₂— in the hydrocarbylene group are each optionally substituted by a group containing a heteroatom such as an oxygen atom, a sulfur atom, or a nitrogen atom, and as a result, a hydroxy group, a cyano group, a fluorine atom, a chlorine atom, a bromine atom, an iodine atom, a carbonyl group, an ether bond, a thioether bond, an ester bond, a sulfonic acid ester bond, a carbonate bond, a carbamate bond, a lactone ring, a sultone ring, a carboxylic anhydride, or the like is optionally contained.

The carboxylic acid compound represented by the formula (3) is preferably such a compound in which “p” is 2, 3 or 4. This case is preferred from the viewpoints of etching resistance and developer resistance because a stiff resist film in which the molecular weight is high is easily formed during mixing with the hypervalent iodine compound.

Specific examples of the carboxy group-containing repeating unit represented by the formula (2) include those represented below, but are not limited thereto. In the following formulae, R^{A} is the same as described above.

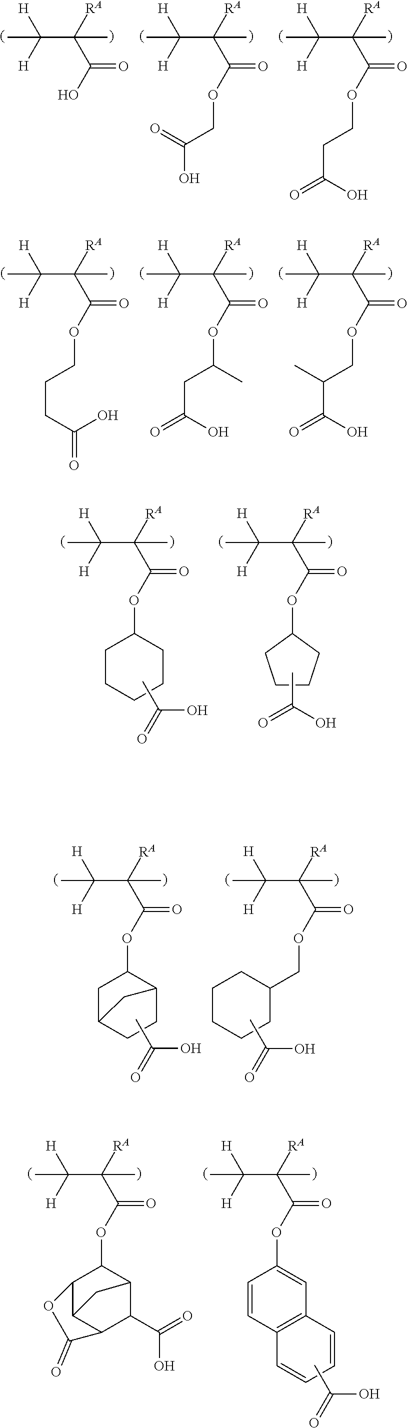

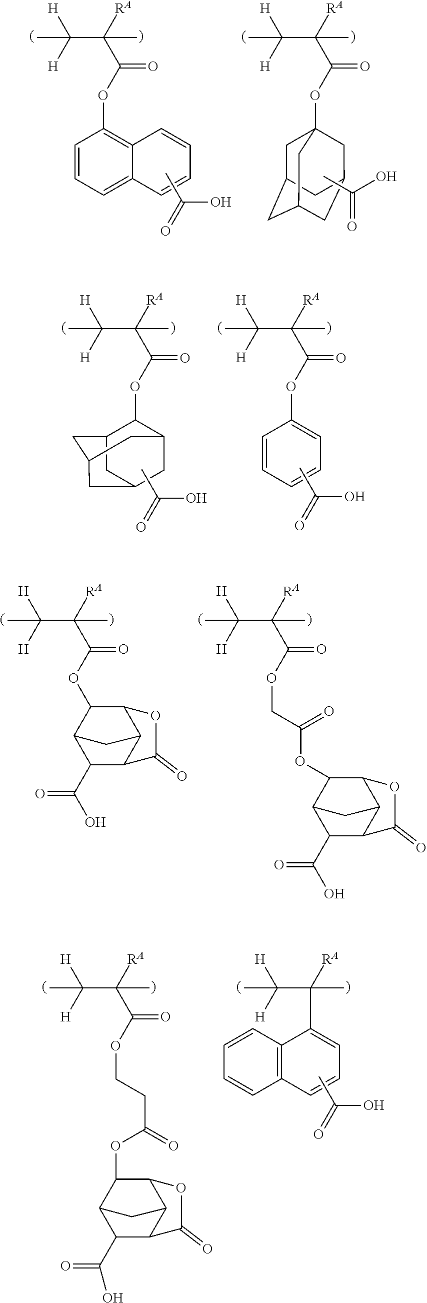

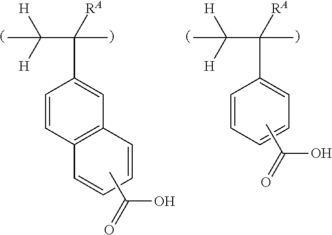

Examples of the carboxylic acid compound represented by the formula (3) include those represented below, but are not limited thereto. The carboxylic acid compound may be a commercially available product, or may be synthesized.

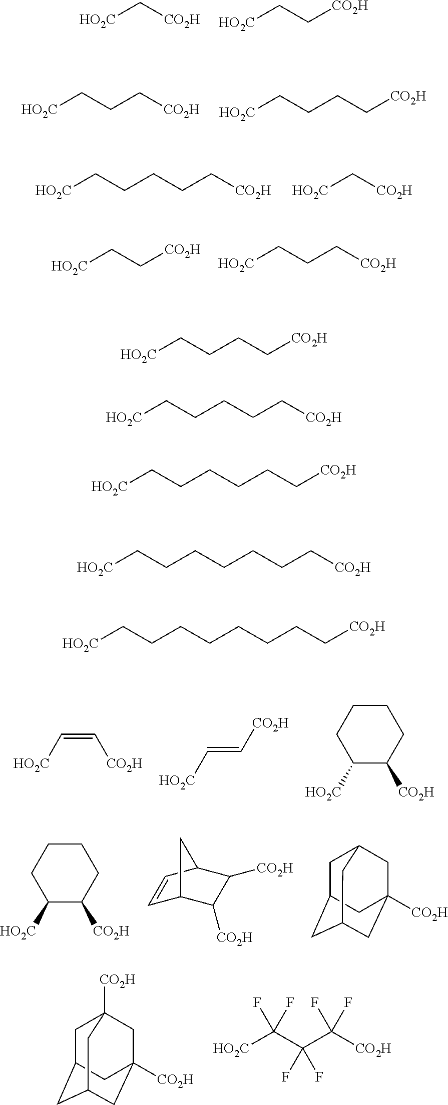

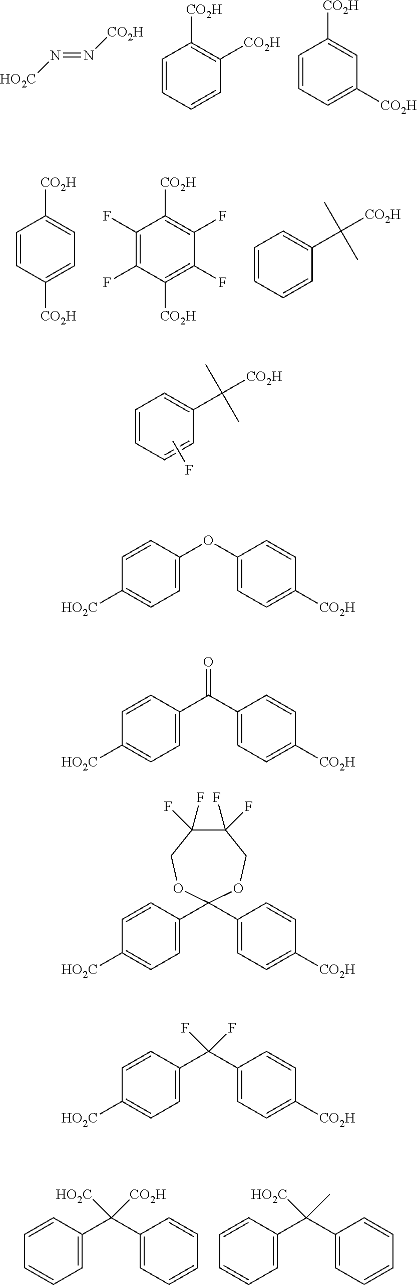

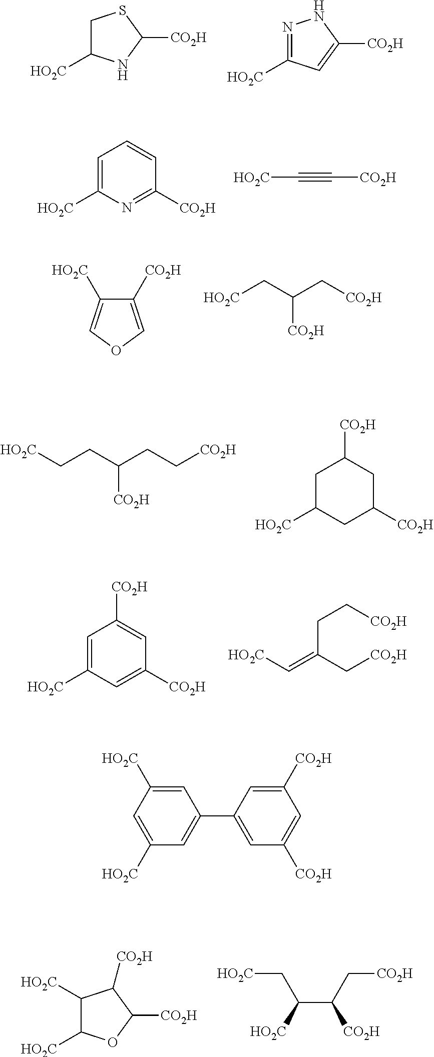

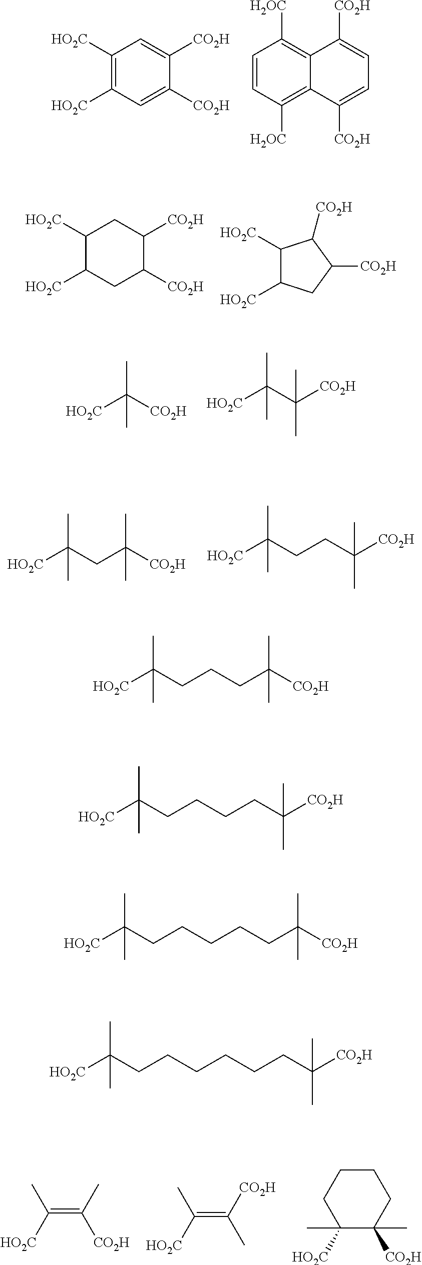

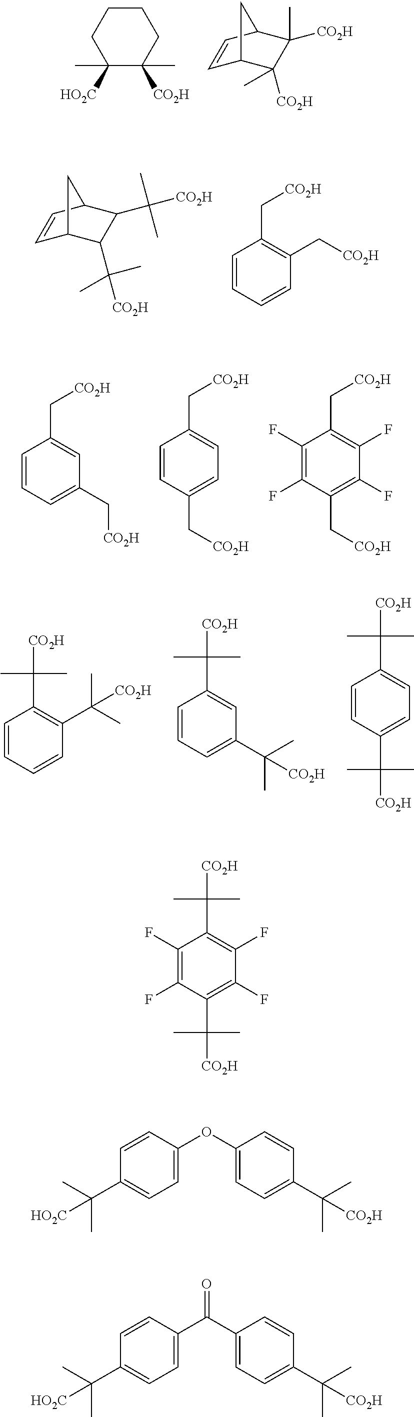

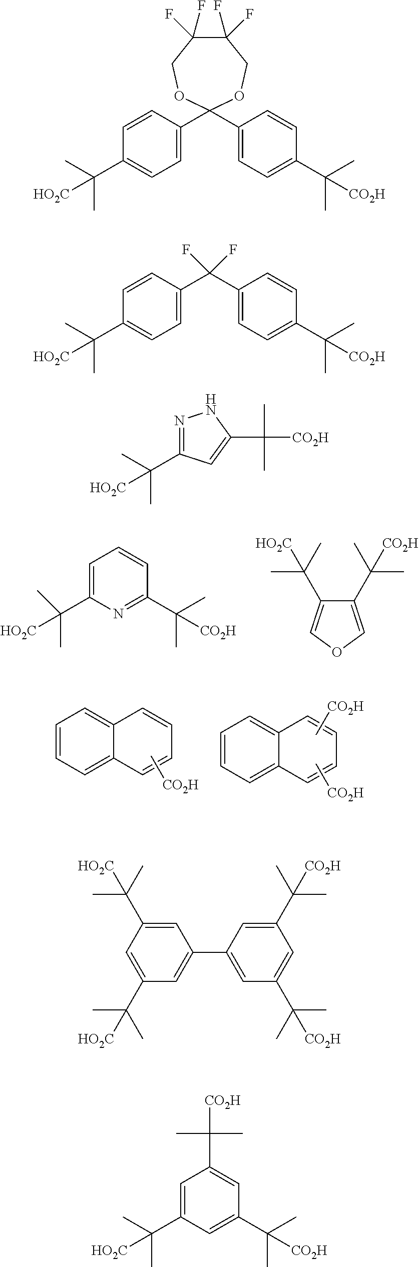

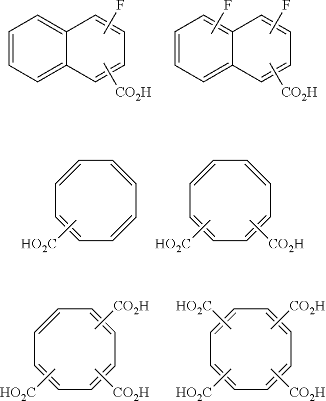

The carboxy group-containing polymer containing the repeating unit represented by the formula (2) further optionally contains any other repeating unit (hereinafter, also referred to as any other repeating unit.). Such any other repeating unit is not particularly limited, and is preferably a unit capable of enhancing the solubility of a polymer which is difficult to dissolve only by a repeating unit having a carboxy group, in a solvent. Such any other repeating unit is preferably a repeating unit having a rigid skeleton and having a cyclic structure expected to impart high etching resistance, or a repeating unit having a styrene skeleton.

Specific examples of such any other repeating unit described above include those represented below, but are not limited thereto. In the following formulae, R^{A} is the same as described above, and each X^{B} is independently —CH₂— or —O—.

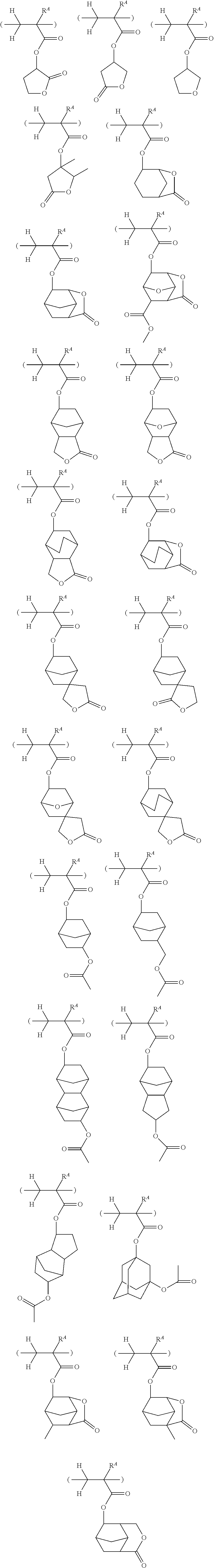

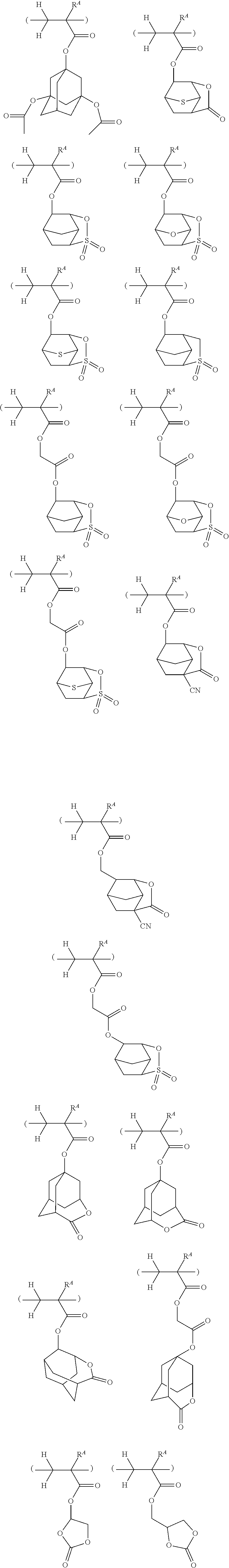

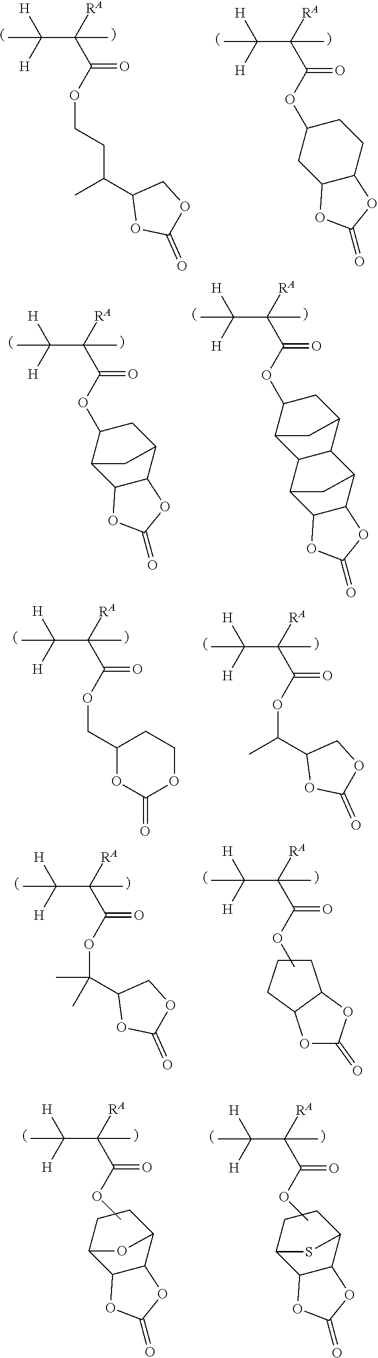

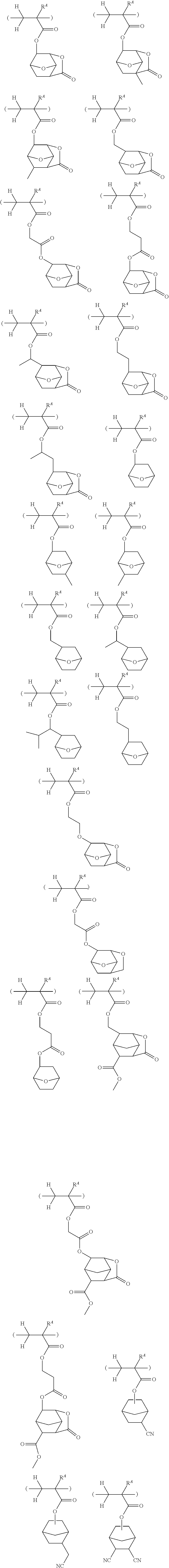

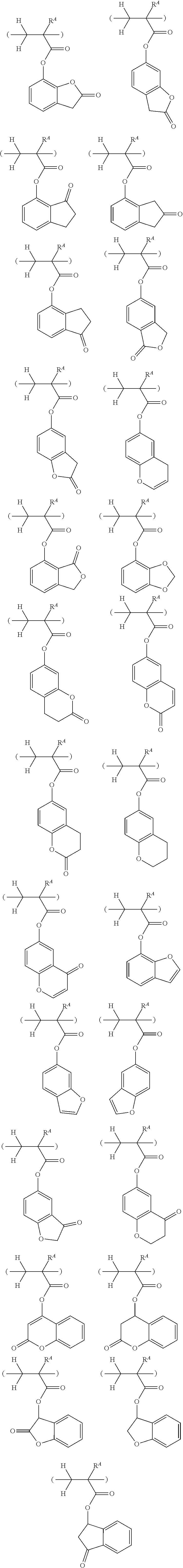

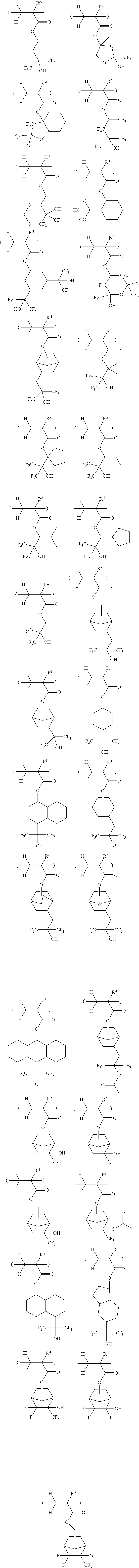

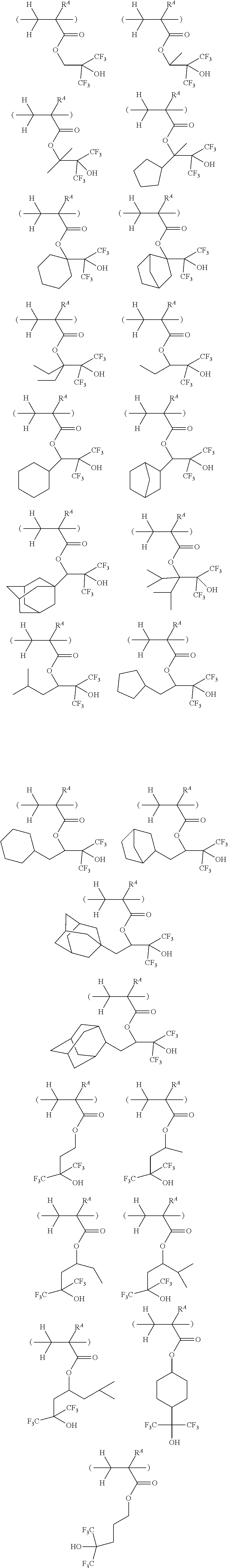

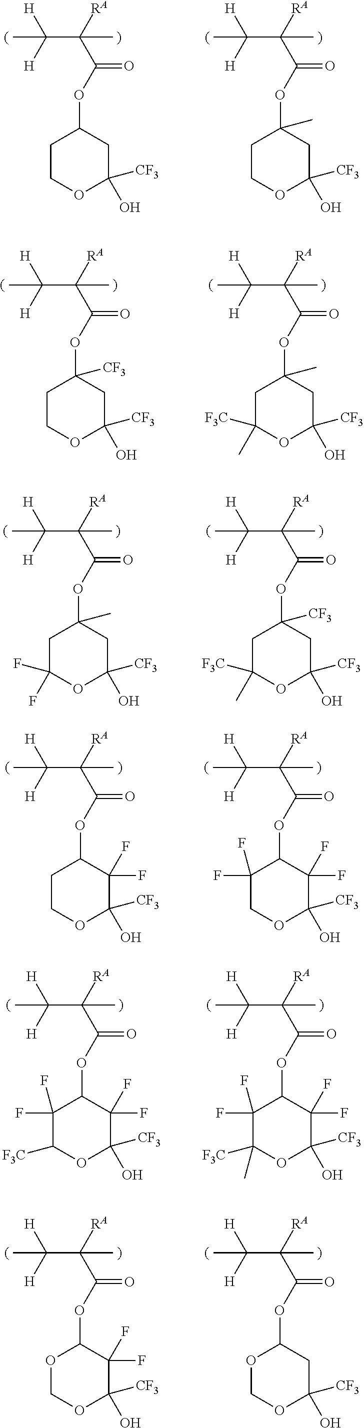

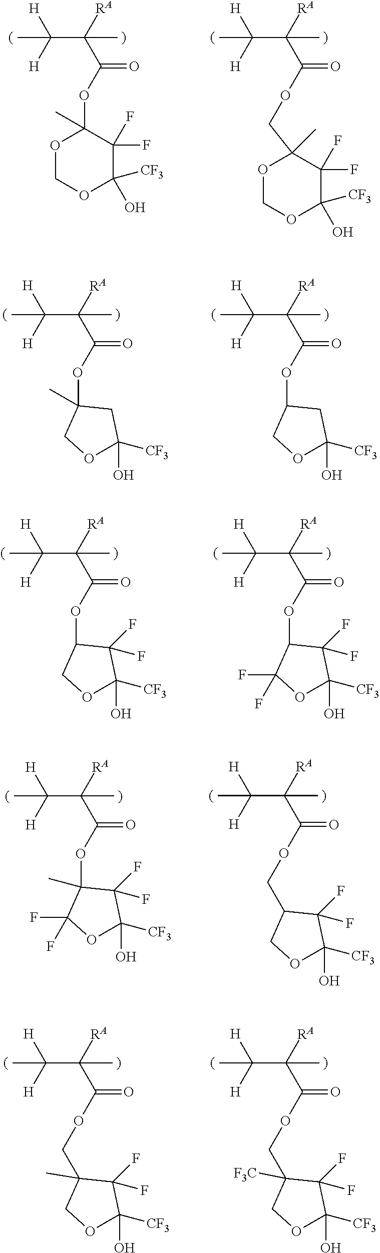

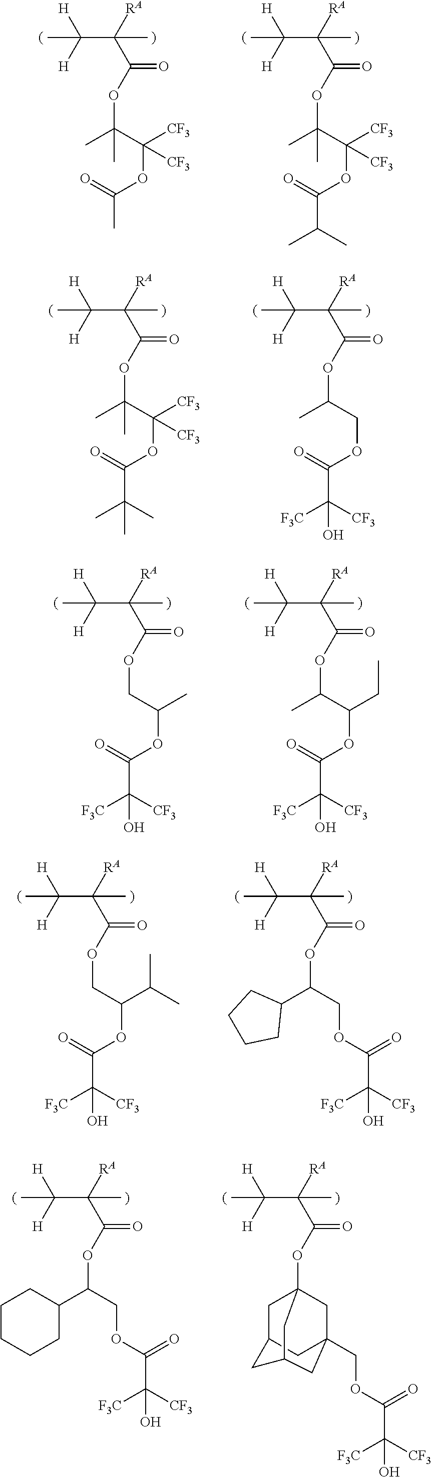

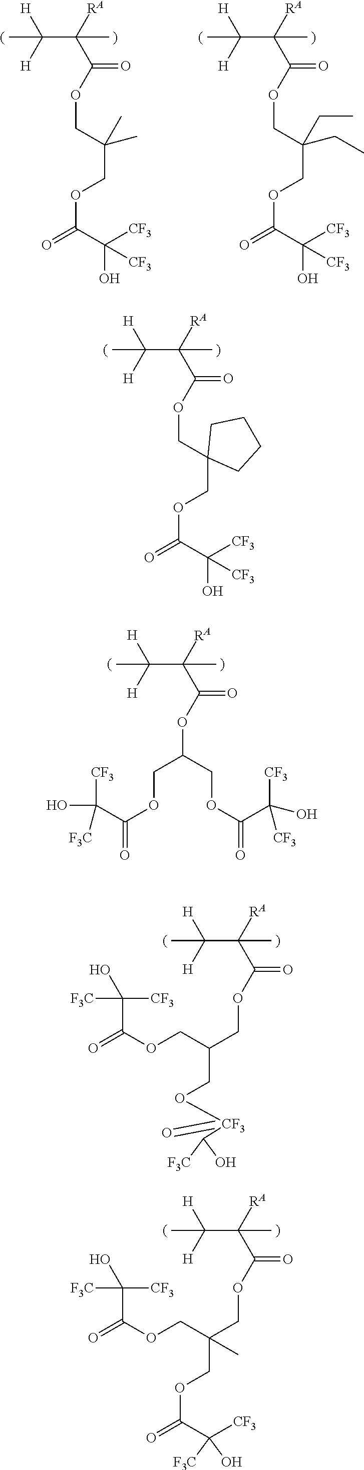

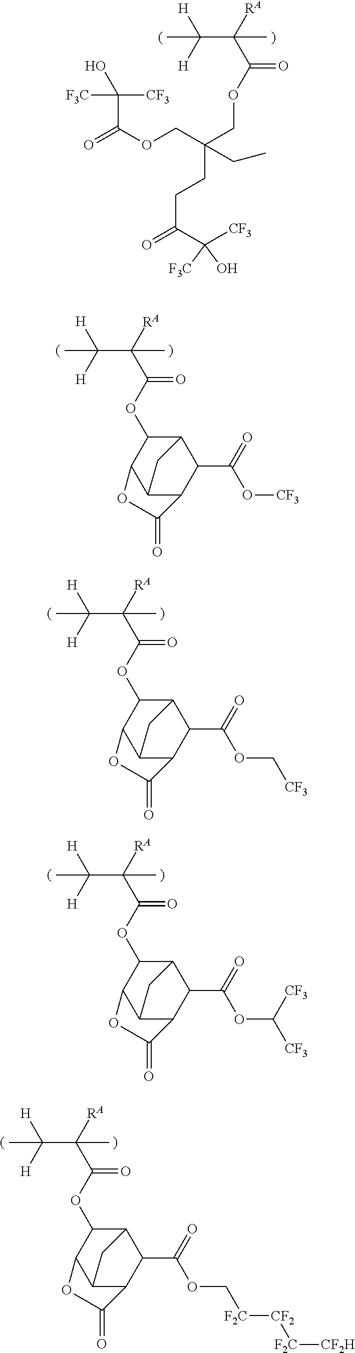

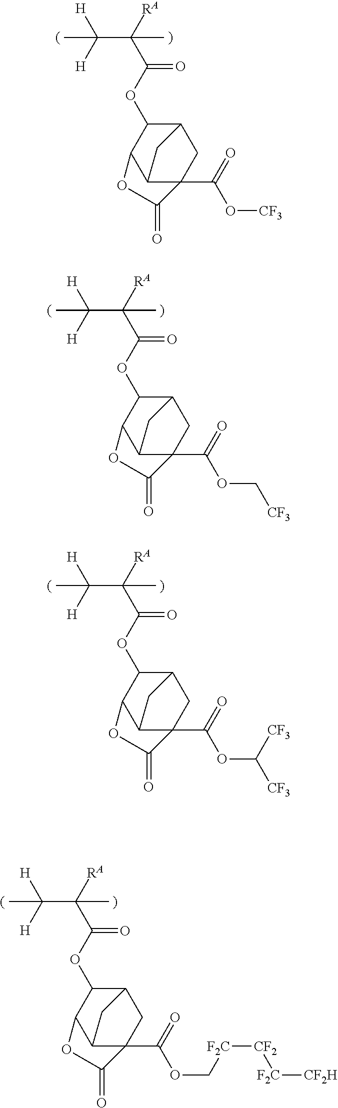

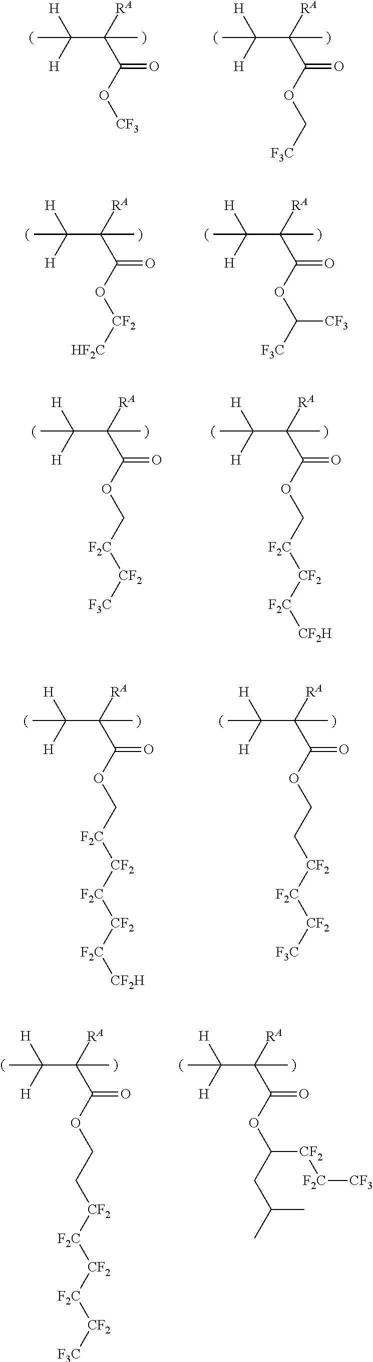

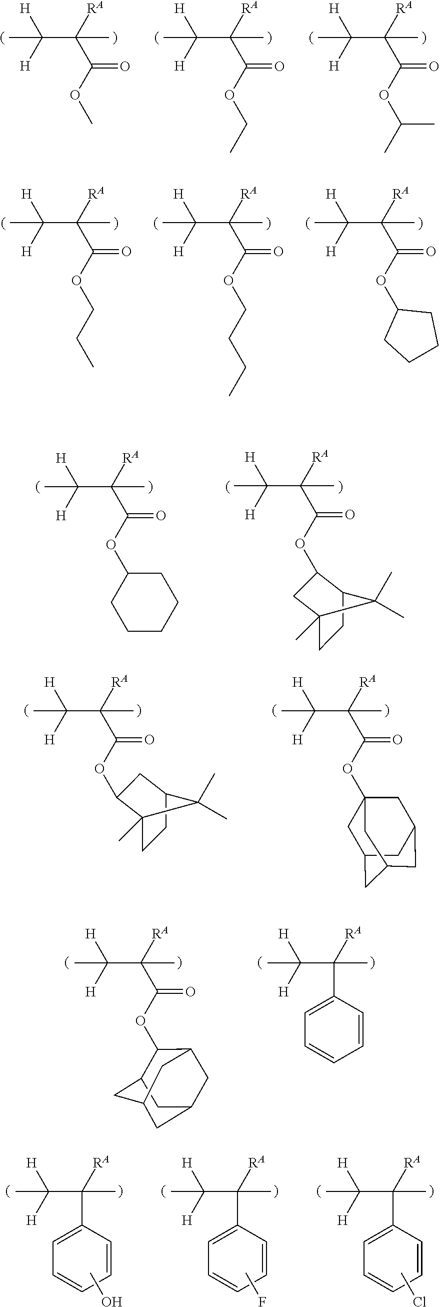

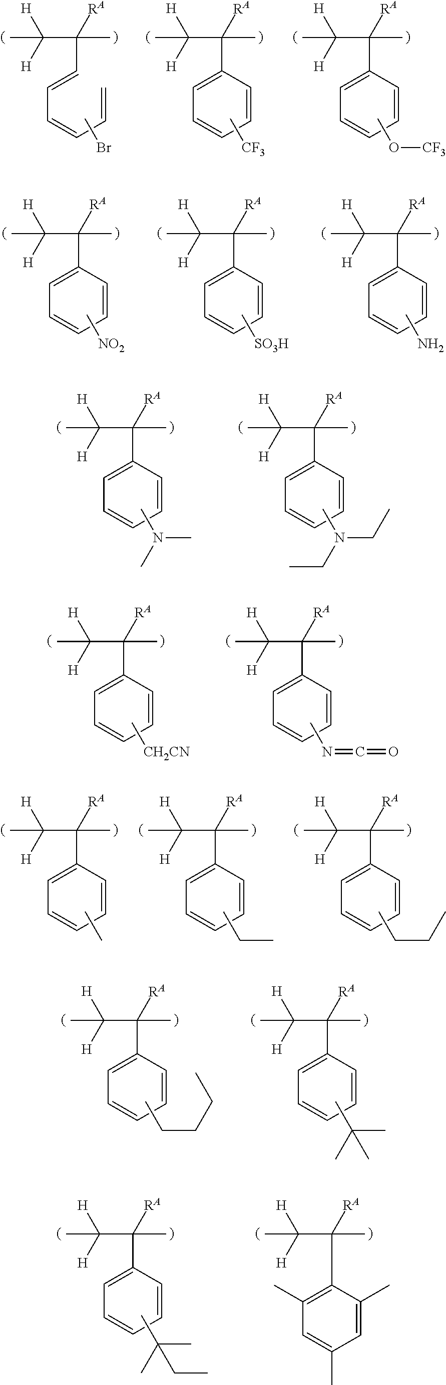

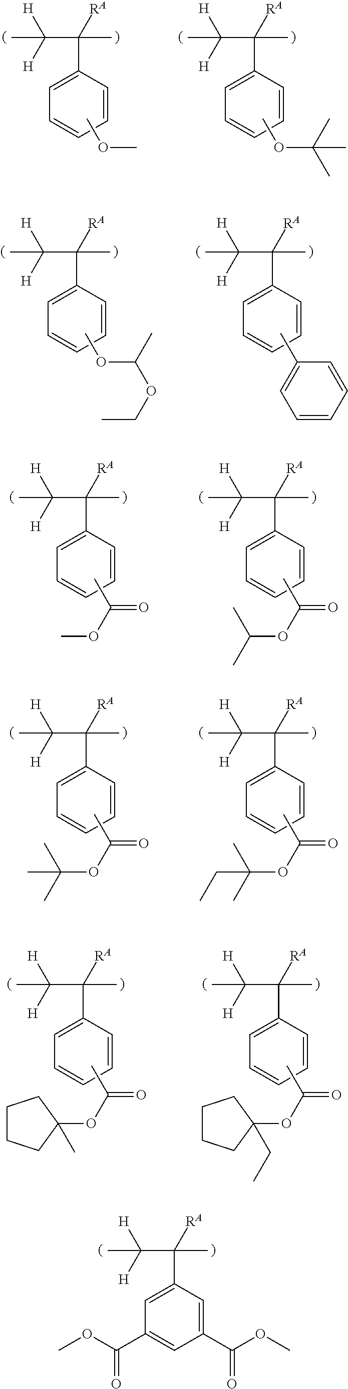

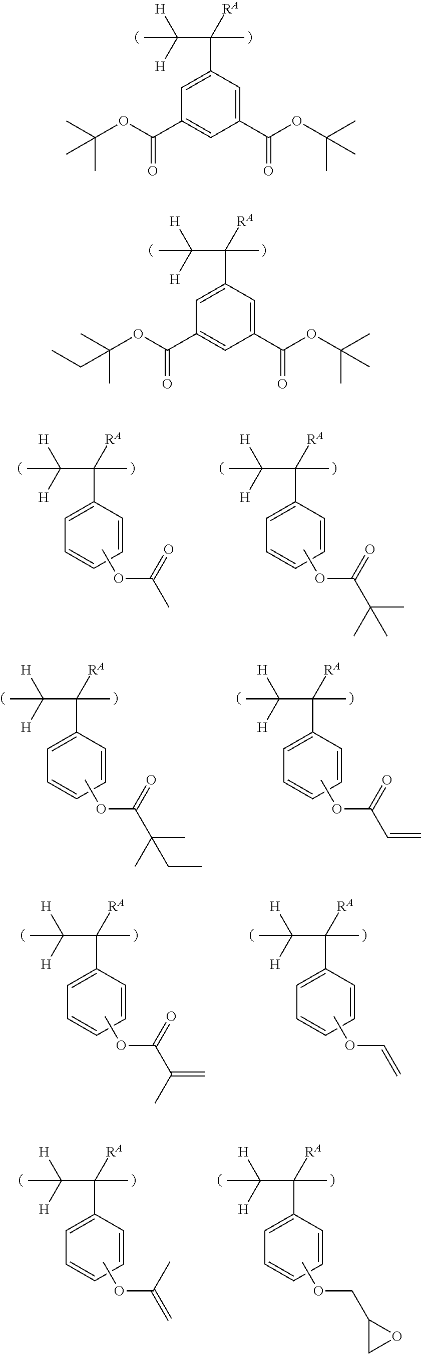

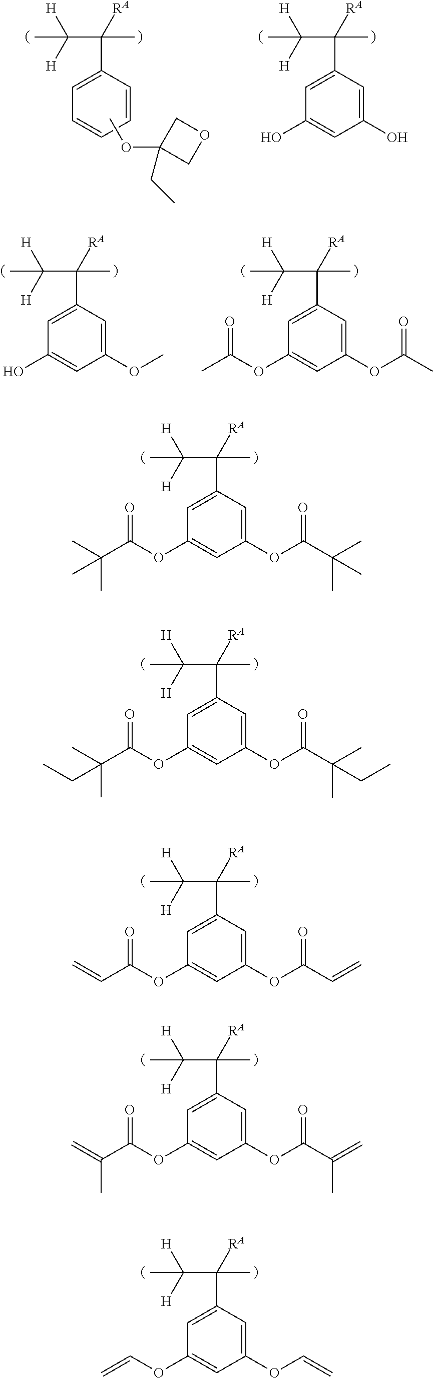

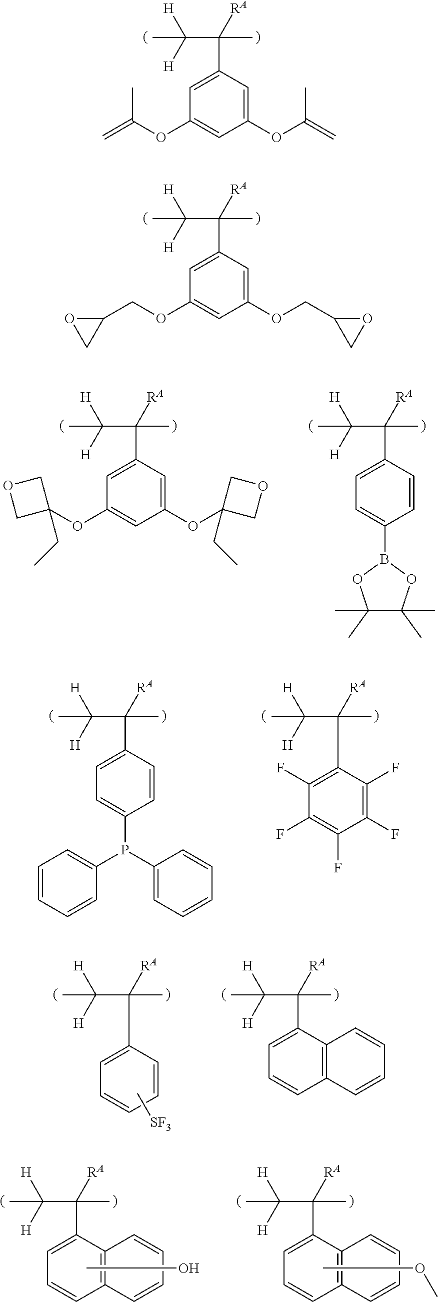

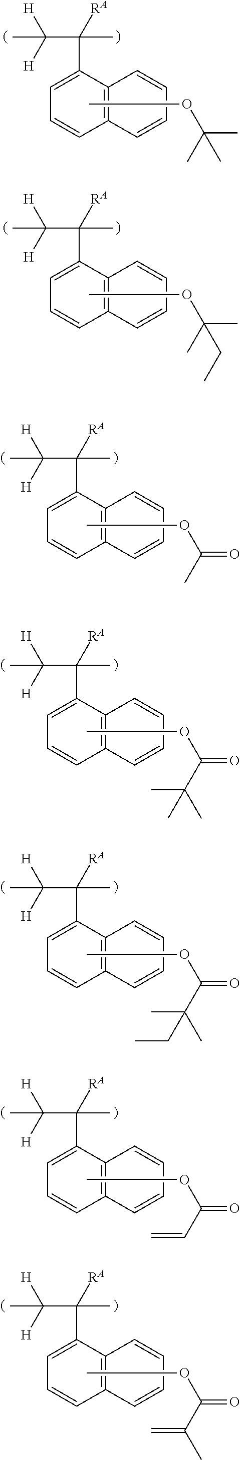

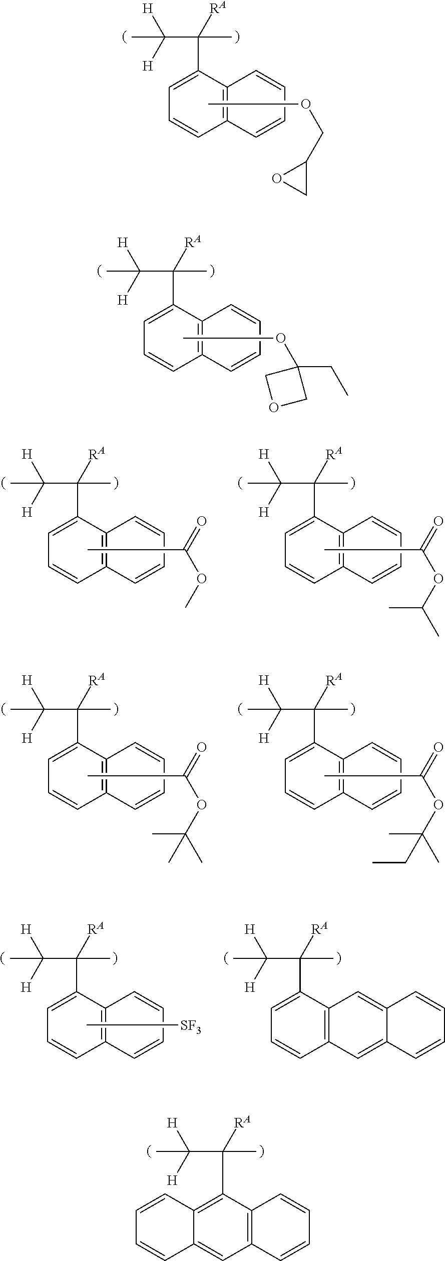

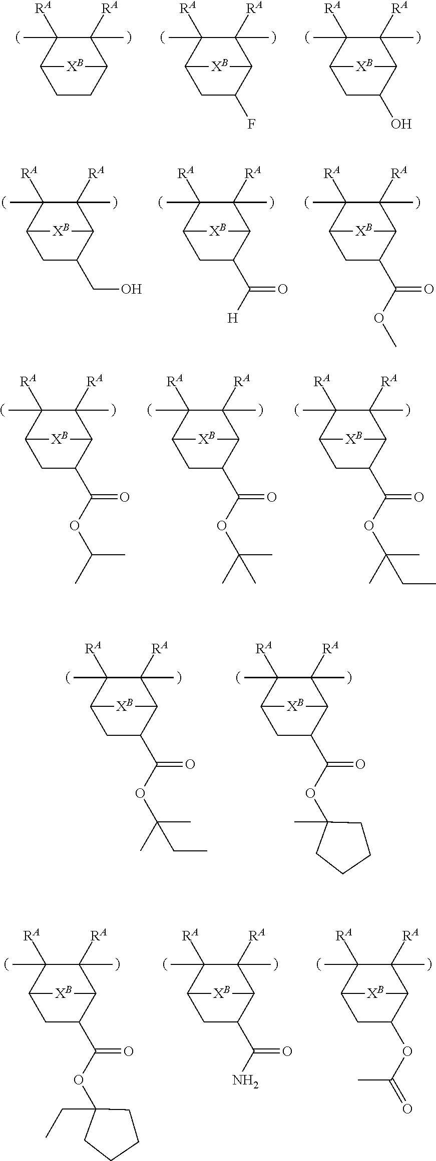

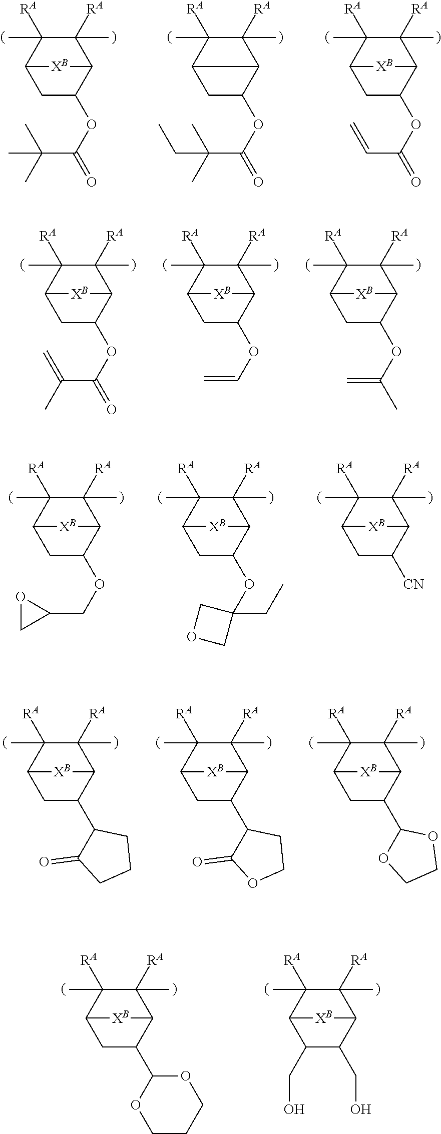

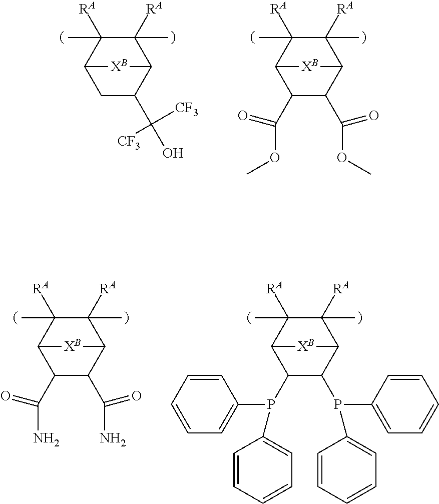

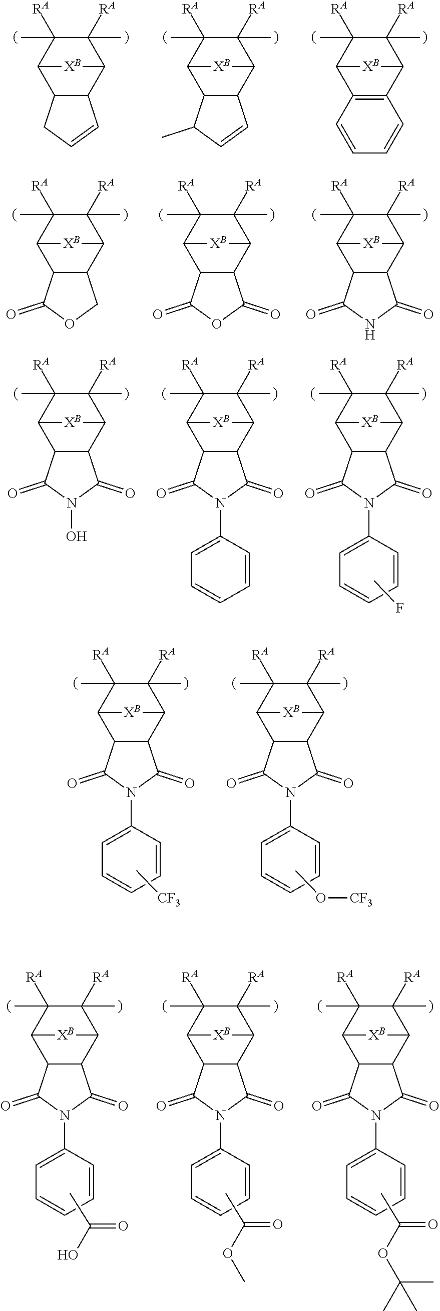

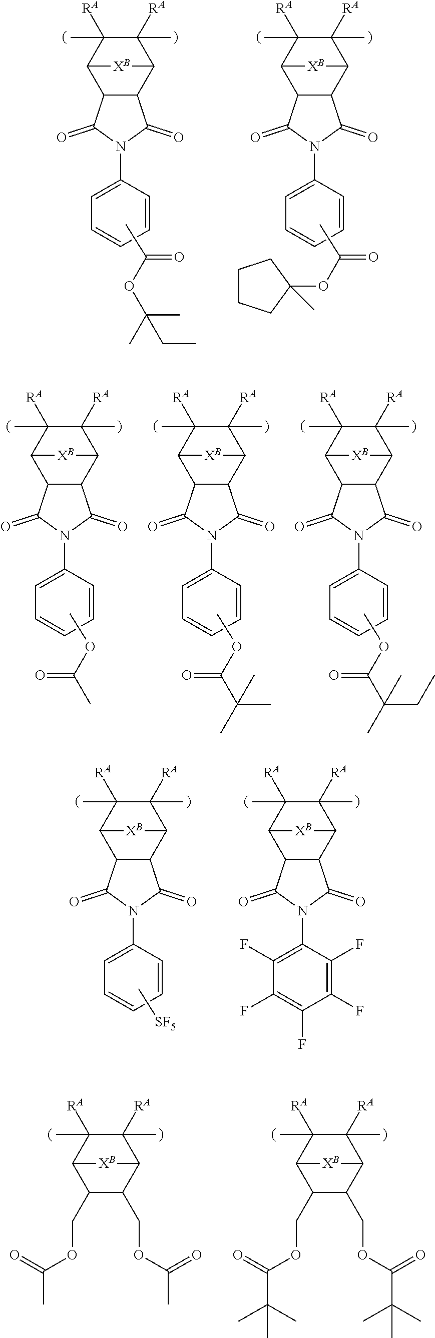

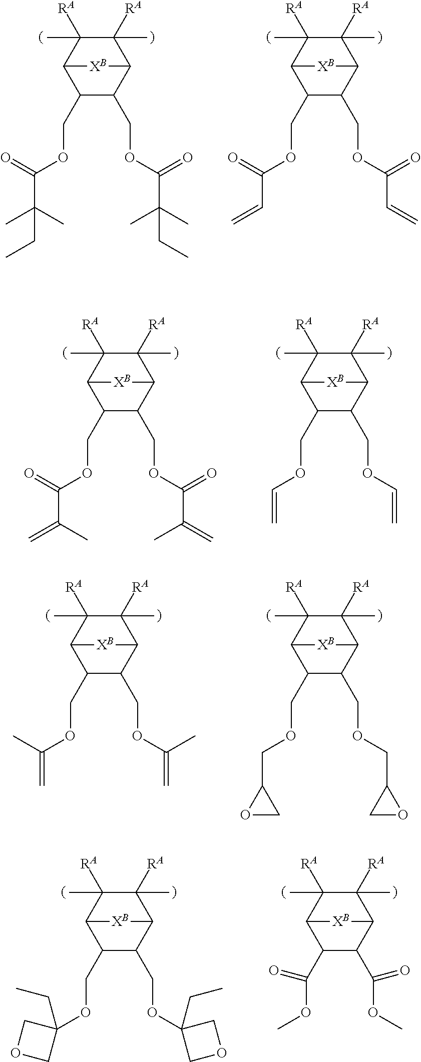

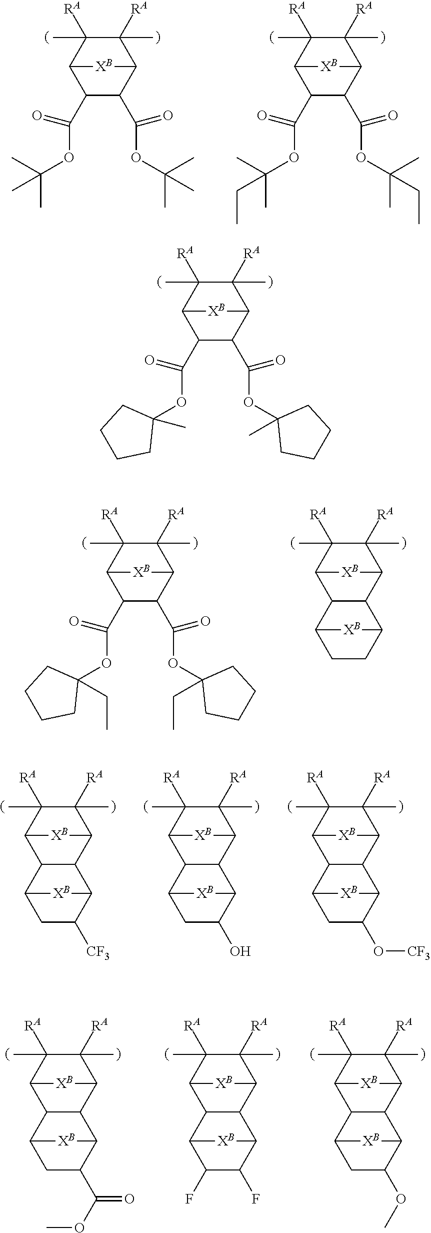

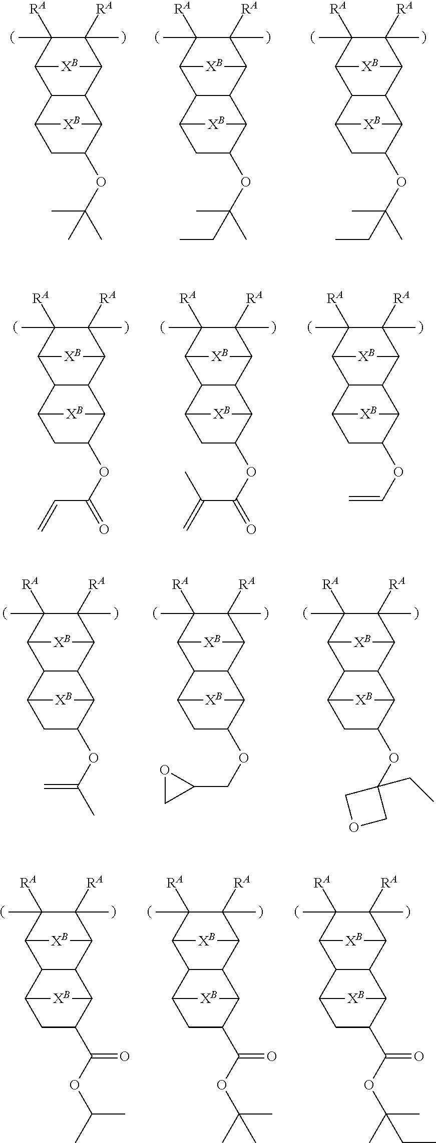

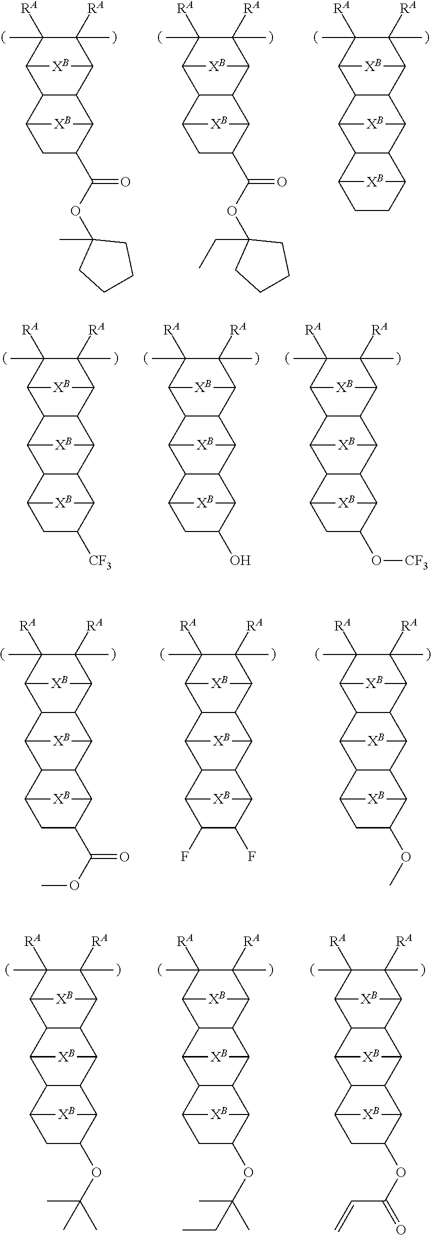

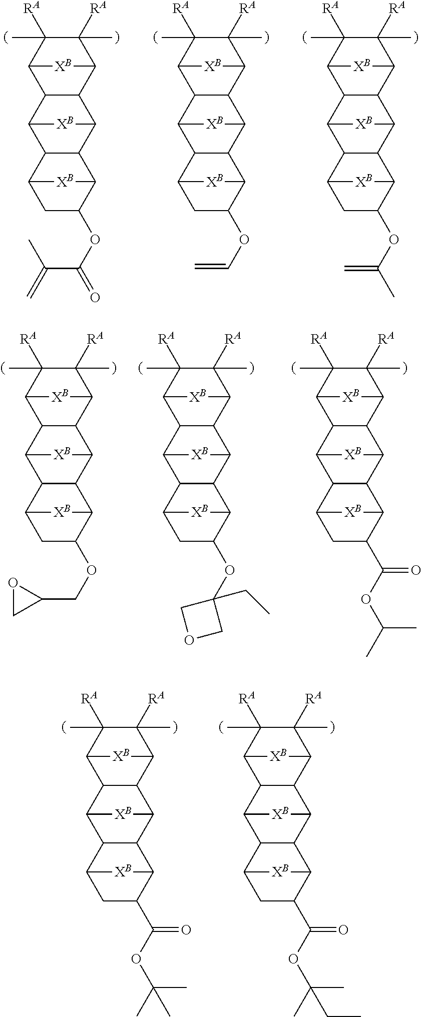

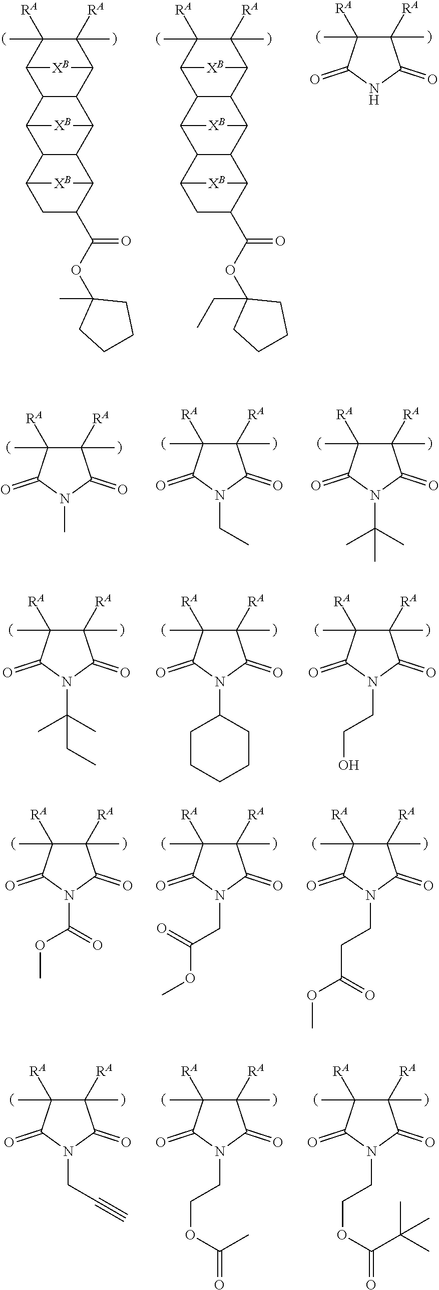

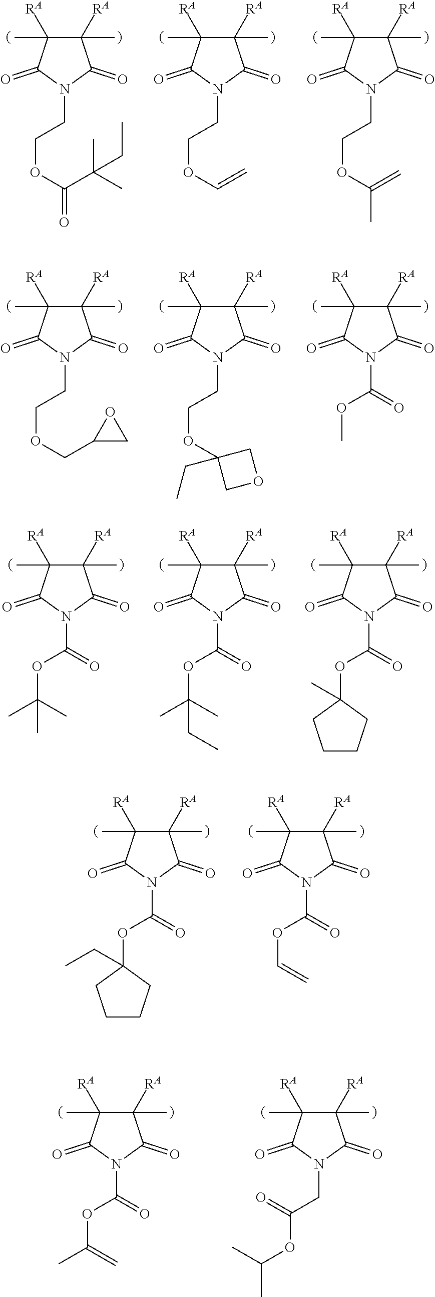

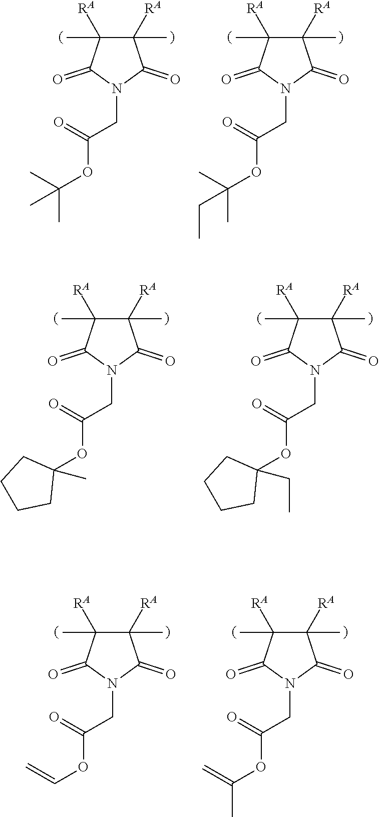

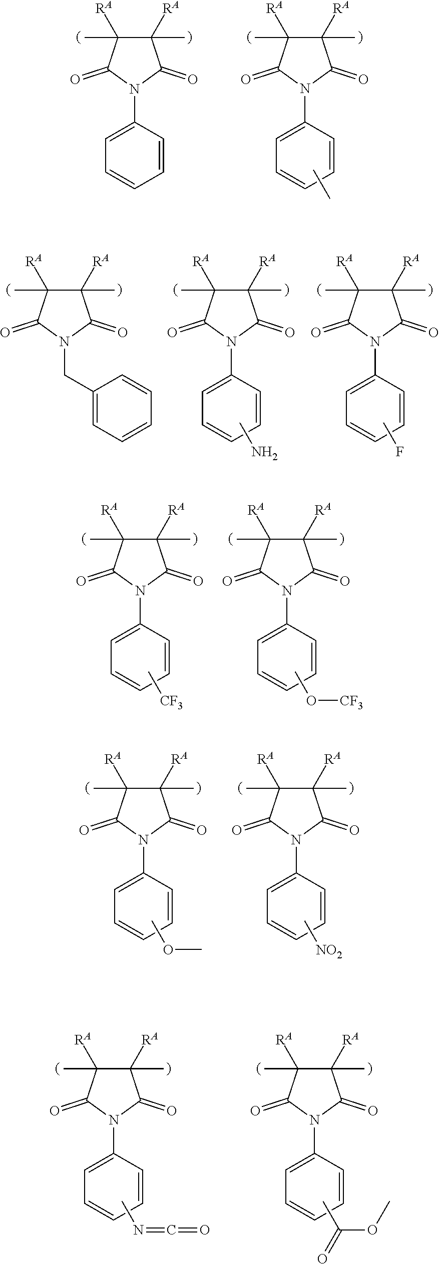

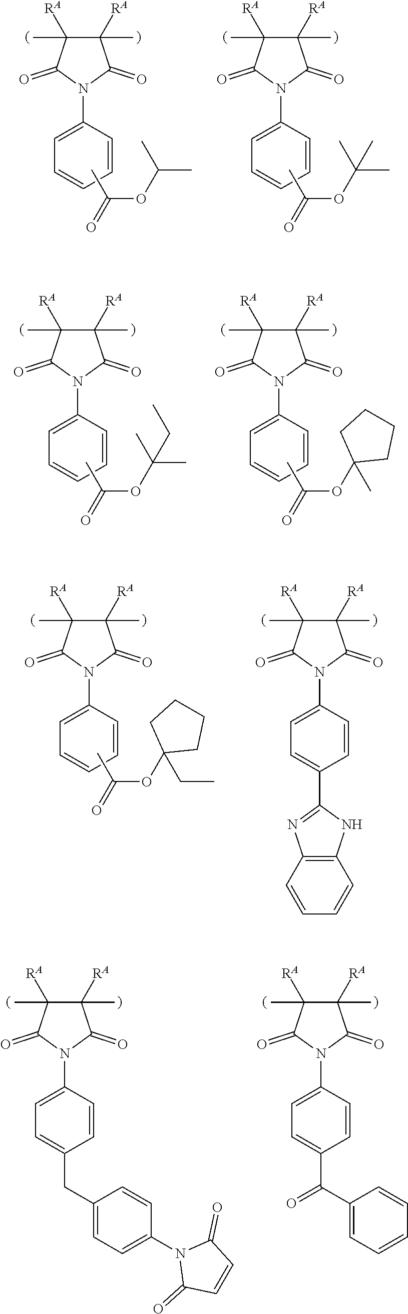

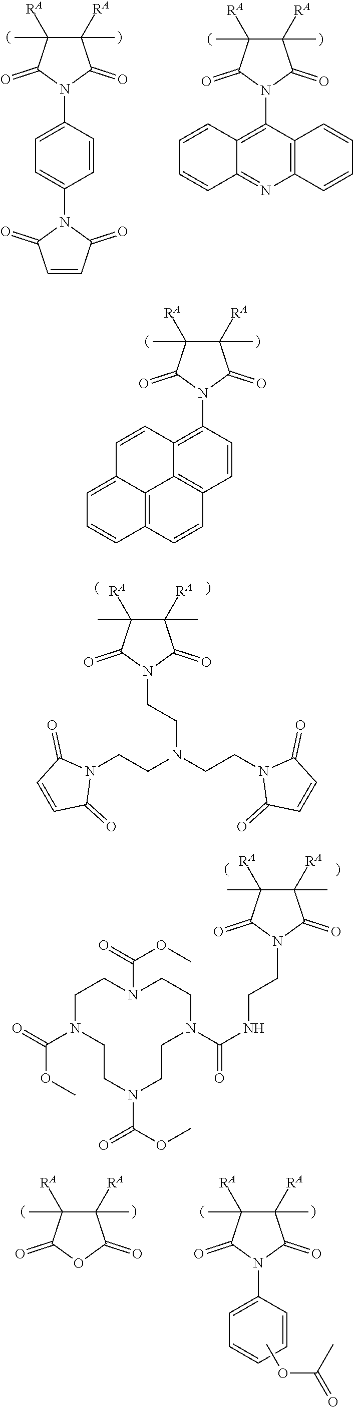

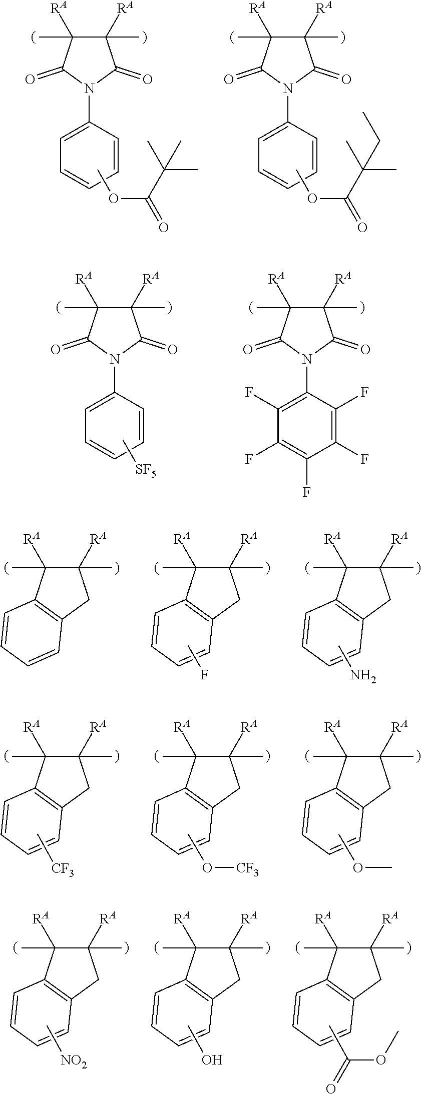

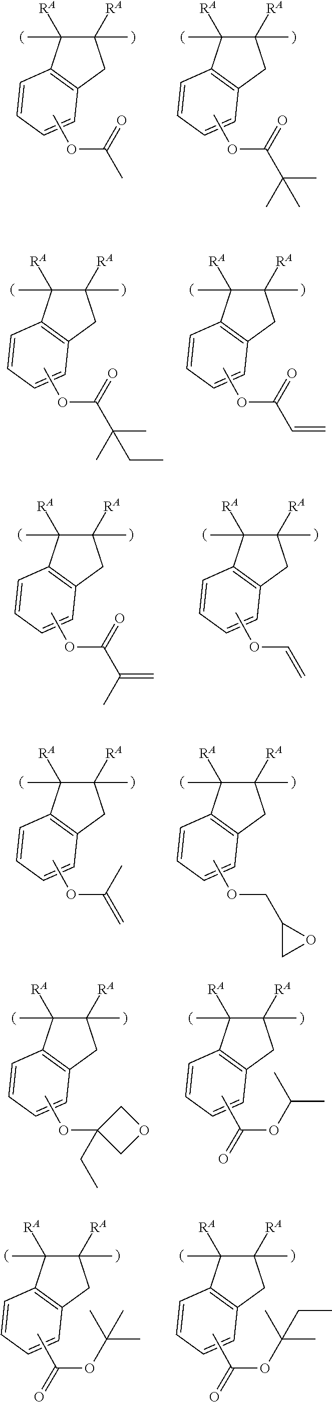

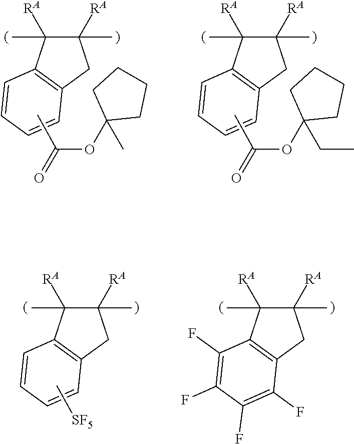

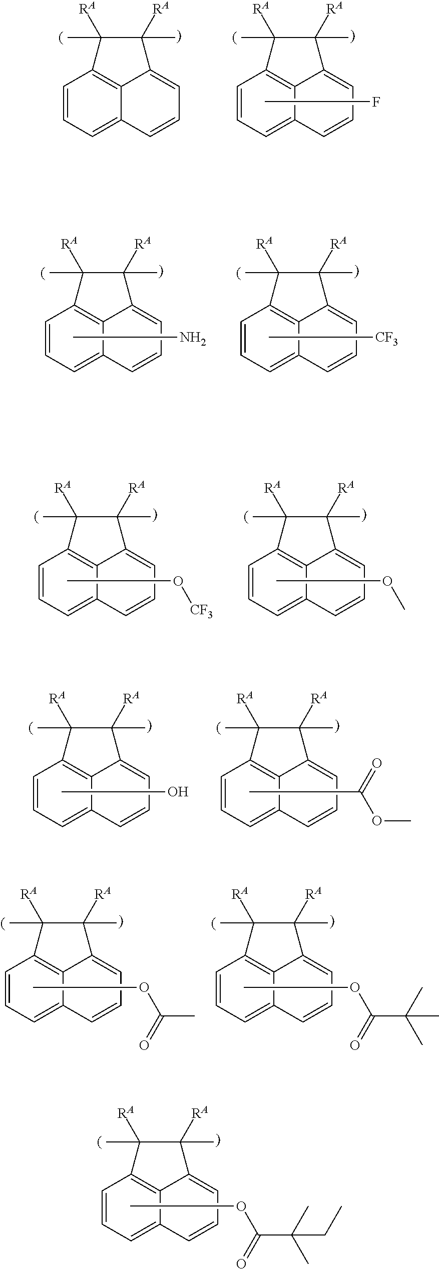

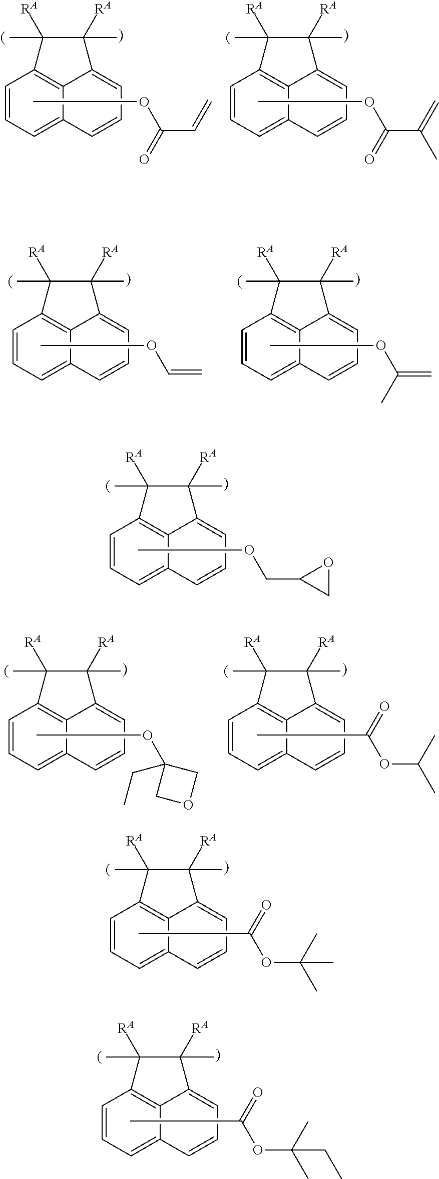

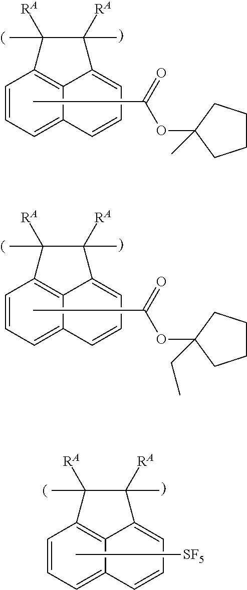

The content ratio of the hypervalent iodine compound to the carboxy group-containing compound (the polymer containing the repeating unit represented by the formula (2) and/or the compound represented by the formula (3)) in the resist composition (when the carboxy group-containing compound is a carboxy group-containing polymer, the content ratio of the hypervalent iodine compound (mol) to the carboxylic acid-containing repeating unit (mol) in the polymer, or when the carboxy group-containing compound is a monomolecular compound represented by the formula (3), the content ratio of the hypervalent iodine compound (mol) to the monomolecular compound (mol)) is preferably 1:99 to 99:1, more preferably 10:90 to 90:10, further preferably 20:80 to 80:20 in terms of the molar ratio of hypervalent iodine compound:carboxy group-containing compound. The hypervalent iodine compound may be used singly or in combinations of two or more kinds thereof. The carboxy group-containing polymer may be used singly or in combinations of two or more kinds of such compounds different in compositional ratio, weight average molecular weight (Mw) and/or molecular weight distribution (Mw/Mn). The monomolecular compound may be used singly or in combinations of two or more kinds thereof. Any or a combination of the carboxy group-containing polymer and the monomolecular compound may be used.

The content ratio (molar ratio) of the carboxy group-containing repeating unit and any other repeating unit in the carboxy group-containing polymer is preferably 10:90 to 90:10, more preferably 15:85 to 85:15, further preferably 20:80 to 80:20 in terms of carboxy group-containing repeating unit: any other repeating unit.

The weight average molecular weight (Mw) of the carboxy group-containing polymer is preferably 1000 to 500000, more preferably 3000 to 100000. Herein, the weight average molecular weight Mw and the number average molecular weight Mn in the present invention are each a value measured in terms of polystyrene by gel permeation chromatography (GPC) with tetrahydrofuran (THF) as a solvent, and the dispersity Mw/Mn is a value determined from these molecular weights.

When the molecular weight distribution (Mw/Mn) of the carboxy group-containing polymer is broad, a low-molecular-weight polymer and a high-molecular-weight polymer are present and therefore foreign substances may be found on a pattern after exposure and/or the shape of the pattern may deteriorate. Therefore, the influences by Mw and Mw/Mn are easily increased according to miniaturization of a pattern rule, and thus the Mw/Mn of the carboxy group-containing polymer is preferably 1.00 to 2.00 which corresponds to a narrow distribution, in order to obtain a resist composition suitably used for a fine pattern dimension. Mw/Mn is preferably more than 1.30, and the lower limit thereof may be 1.40, 1.50 or 1.60 and the upper limit thereof may be 1.70, 1.80 or 1.90.

Examples of the process for synthesizing the carboxy group-containing polymer include a process consisting steps of adding a radical polymerization initiator to a monomer imparting the repeating unit in an organic solvent and heating for polymerizing.

Specific examples of the organic solvent used in the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the polymerization initiator added is preferably 0.01 to 25% by mol relative to the total monomer to be polymerized. The reaction temperature is preferably 50 to 150° C., more preferably 60 to 100° C. The reaction time is preferably 2 to 24 hours, and is more preferably 2 to 12 hours from the viewpoint of production efficiency.

The polymerization initiator may be added to the monomer solution and these may be supplied to a reaction oven, or an initiator solution may be prepared separately from the monomer solution and these may be each independently supplied to a reaction oven. Since the polymerization reaction can progress due to radical generated from the initiator during a waiting time to generate an ultra-high molecular weight polymer, the monomer solution and the initiator solution are preferably each independently prepared and dropped from the viewpoint of quality control. A known chain transfer agent such as dodecylmercaptan or 2-mercaptoethanol may be used in combination for adjustment of the molecular weight. In this case, the amount of the chain transfer agent added is preferably 0.01 to 20% by mol based on the total monomer to be polymerized.

The amount of each monomer in the monomer solution may be appropriately set, for example, so that a preferred proportion of the repeating unit contained is achieved.

### [Other Hypervalent Iodine Compounds]

The resist composition of the present invention optionally contains a hypervalent iodine compound represented by the following formula (4) or (5) (hereinafter, also referred to as any other hypervalent iodine compound). Such any other hypervalent iodine compound can be added to control reactivity against light and adjust sensitivity.

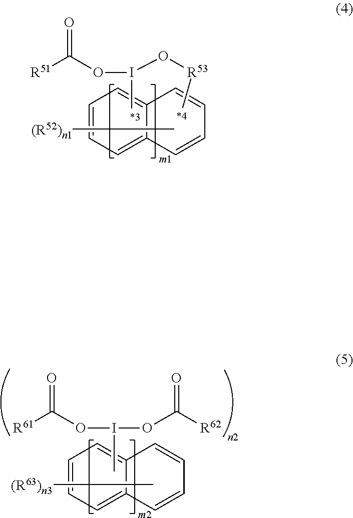

In the formulae, m1 and m2 are each an integer of 0 to 2, and n1 is an integer of 0 to 4 when m1 is 0, n1 is an integer of 0 to 6 when m1 is 1, and n1 is an integer of 0 to 8 when m1 is 2; when m2 is 0, n2 is an integer of 1 to 3, n3 is an integer of 0 to 5, and 1≤(n2+n3)≤6 is satisfied; when m2 is 1, n2 is an integer of 1 to 3, n3 is an integer of 0 to 7, and 1≤(n2+n3)≤8 is satisfied; when m2 is 2, n2 is an integer of 1 to 3, n3 is an integer of 0 to 9, and 1≤(n2+n3)≤10 is satisfied; R⁵¹ is a halogen atom, or a hydrocarbyl group having 1 to 10 carbon atoms and optionally containing a heteroatom; R⁵² is a halogen atom, or a hydrocarbyl group having 1 to 40 carbon atoms and optionally containing a heteroatom; when n1 is 2 to 8, R⁵²s are the same as or different from each other, and plural R⁵²s are optionally bound to each other to form a ring together with carbon atoms in an aromatic ring to which these are bound; R⁵³ is a hydrocarbylene group having 1 to 10 carbon atoms and optionally containing a heteroatom; *3 and *4 each represent a point of attachment to a carbon atom in an aromatic ring in the formula, provided that *3 and *4 are bound to adjacent carbon atoms in an aromatic ring; R⁶¹ and R⁶² are each independently a halogen atom, or a hydrocarbyl group having 1 to 10 carbon atoms and optionally containing a heteroatom, and R⁶¹ and R⁶² are optionally bound to each other to form a ring together with carbon atoms to which these are bound and an atom between the carbon atoms; when n2 is 2 to 3, R⁶¹s and R⁶²s are the same as or different from each other; R⁶³ is a halogen atom, or a hydrocarbyl group having 1 to 40 carbon atoms and optionally containing a heteroatom; and when n3 is 2 to 9, R⁶³s are the same as or different from each other, and plural R⁶³s are optionally bound to each other to form a ring together with carbon atoms in an aromatic ring to which these are bound.

In the formulae, m1 and m2 is an integer of 0 to 2.
n1 is an integer of 0 to 4 when m1 is 0, n1 is an integer of 0 to 6 when m1 is 1, and n1 is an integer of 0 to 8 when m1 is 2.
When m2 is 0, n2 is an integer of 1 to 3, n3 is an integer of 0 to 5, and 1≤(n2+n3)≤6 is satisfied.
When m2 is 1, n2 is an integer of 1 to 3, n3 is an integer of 0 to 7, and 1≤(n2+n3)≤8 is satisfied.
When m2 is 2, n2 is an integer of 1 to 3, n3 is an integer of 0 to 9, and 1≤(n2+n3)≤10 is satisfied.
R⁵¹ is a halogen atom, or a hydrocarbyl group having 1 to 10 carbon atoms and optionally containing a heteroatom.
R⁵² is a halogen atom, or a hydrocarbyl group having 1 to 40 carbon atoms and optionally containing a heteroatom. When n1 is 2 to 8, R⁵²s are the same as or different from each other. In addition, plural R⁵²s are optionally bound to each other to form a ring together with carbon atoms in an aromatic ring to which these are bound.
R⁵³ is a hydrocarbylene group having 1 to 10 carbon atoms and optionally containing a heteroatom.
*3 and *4 each represent a point of attachment to a carbon atom in an aromatic ring in the formula, provided that *3 and *4 are bound to adjacent carbon atoms in an aromatic ring.
R⁶¹ and R⁶² are each independently a halogen atom, or a hydrocarbyl group having 1 to 10 carbon atoms and optionally containing a heteroatom, and R⁶¹ and R⁶² are optionally bound to each other to form a ring together with carbon atoms to which these are bound and an atom between the carbon atoms.
R⁶³ is a halogen atom, or a hydrocarbyl group having 1 to 40 carbon atoms and optionally containing a heteroatom. When n3 is 2 to 9, R⁶³s are the same as or different from each other. In addition, plural R⁶³s are optionally bound to each other to form a ring together with carbon atoms in an aromatic ring to which these are bound.

In the general formula (4), m1 is an integer of 0 to 2. n1 is an integer of 0 to 4 when m1 is 0, n1 is an integer of 0 to 6 when m1 is 1, and n1 is an integer of 0 to 8 when m1 is 2. n1 is preferably 0, 1, 2, 3 or 4, more preferably 0, 1, 2 or 3, further preferably 0, 1 or 2, most preferably 0 or 1.

In the general formula (4), R⁵¹ is a halogen atom, or a hydrocarbyl group having 1 to 10 carbon atoms and optionally containing a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be any of straight, branched or cyclic. Specific examples thereof include alkyl groups each having 1 to 10 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group and an adamantyl group; alkenyl groups each having 2 to 10 carbon atoms, such as a vinyl group and an allyl group; aryl groups each having 6 to 10 carbon atoms, such as a phenyl group and a naphthyl group; and any group obtained by combination thereof. In addition, some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R⁵¹ is preferably a hydrocarbyl group having 1 to 4 carbon atoms or a fluorinated hydrocarbyl group having 1 to 4 carbon atoms, more preferably a hydrocarbyl group having 1 to 4 carbon atoms.

In the general formula (4), R⁵² is a halogen atom, or a hydrocarbyl group having 1 to 40 carbon atoms and optionally containing a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be any of straight, branched or cyclic. Specific examples thereof include alkyl groups each having 1 to 40 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. In addition, some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. When n is 2 to 8, R²s are the same as or different from each other. In addition, plural R⁵²s are optionally bound to each other to form a ring together with carbon atoms in an aromatic ring to which these are bound.

In the general formula (4), R⁵³ is a hydrocarbylene group having 1 to 10 carbon atoms and optionally containing a heteroatom. The hydrocarbylene group having 1 to 10 carbon atoms may be saturated or unsaturated, and may be any of straight, branched or cyclic. Specific examples thereof include alkylene groups each having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group and a decane-1,10-diyl group; cyclic saturated hydrocarbylene groups each having 3 to 10 carbon atoms, such as a cyclopentanediyl group, a cyclohexanediyl group, a norbornanediyl group, an adamantanediyl group and a tricyclo[5.2.1.0^{2,6}]decanediyl group; alkenylene groups each having 2 to 10 carbon atoms, such as a vinylene group and a propynylene group; arylene groups each having 6 to 10 carbon atoms, such as a phenylene group, a methyl phenylene group, an ethyl phenylene group, a n-propyl phenylene group, an isopropyl phenylene group, a n-butyl phenylene group and a naphthylene group; and any group obtained by combination thereof. In addition, some or all of hydrogen atoms in the hydrocarbylene group are each optionally substituted by a group containing a heteroatom such as an oxygen atom, a sulfur atom, a nitrogen atom, or a halogen atom, some of —CH₂— in the hydrocarbylene group are each optionally substituted by a group containing a heteroatom such as an oxygen atom, a sulfur atom, or a nitrogen atom, and as a result, a hydroxy group, a cyano group, an alkyl halide group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R⁵³ is preferably a carbonyl group, a hydrocarbylene group having 1 to 4 carbon atoms, or a fluorinated hydrocarbylene group having 1 to 4 carbon atoms.

In the general formula (4), *3 and *4 each represent a point of attachment to a carbon atom in an aromatic ring in the formula, provided that *3 and *4 are bound to adjacent carbon atoms in an aromatic ring. Such a combination of *3, *4 and m1 is considered to have seven patterns shown below:

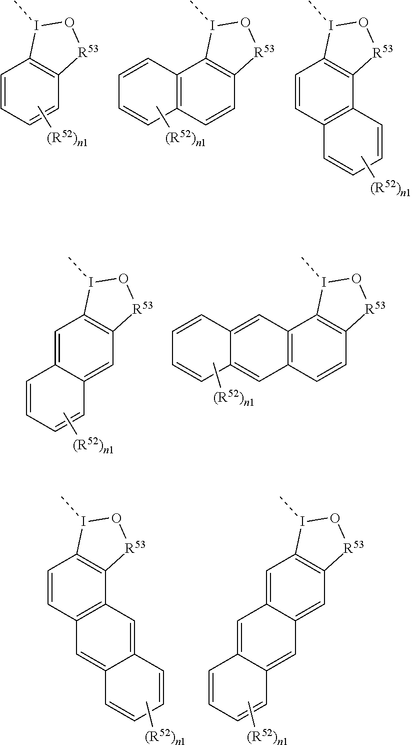

wherein n1, R⁵² and R⁵³ are each the same as described above; and a broken line represents a point of attachment to R⁵¹—C(═O)—O—.

Herein, R⁵² and R¹³ can be each a substituent at any position on the aromatic ring in each of the above formulae.

Specific examples of the hypervalent iodine compound represented by the general formula (4) include the following, but not limited thereto. Herein, in the following formulae, Me is a methyl group.

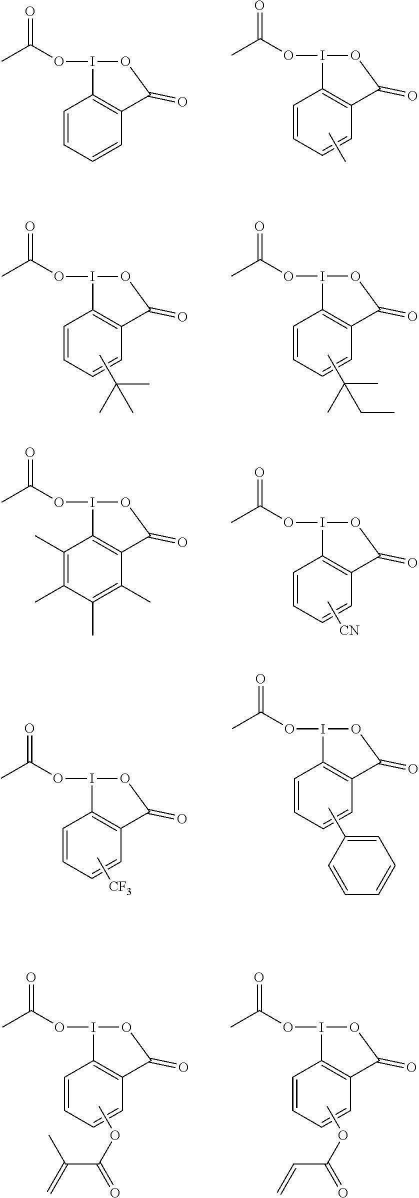

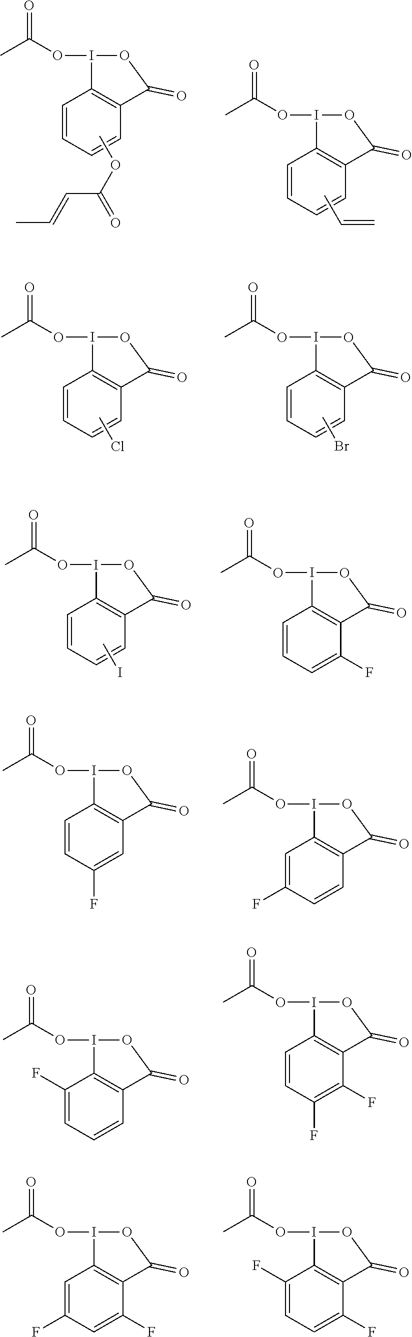

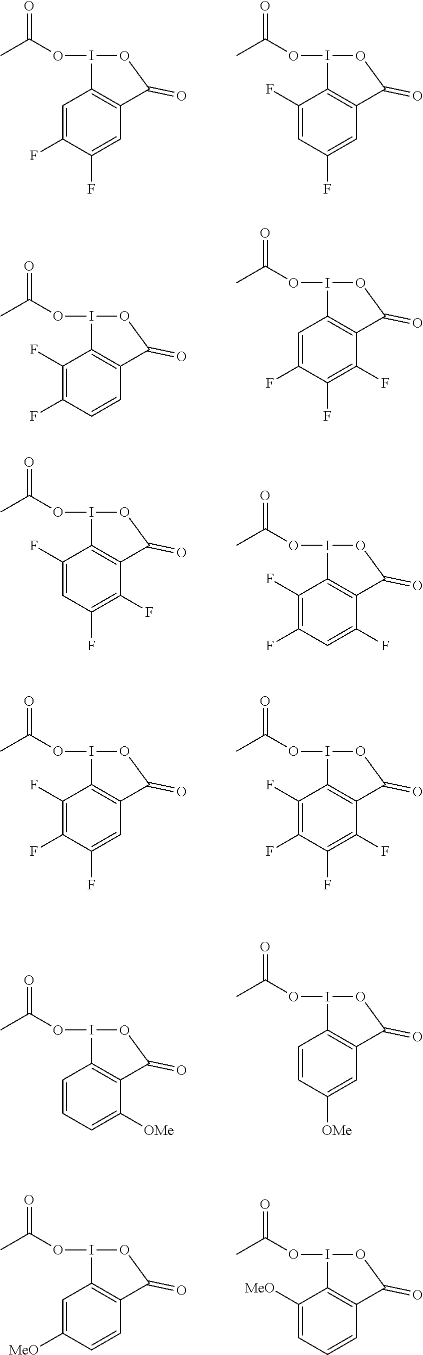

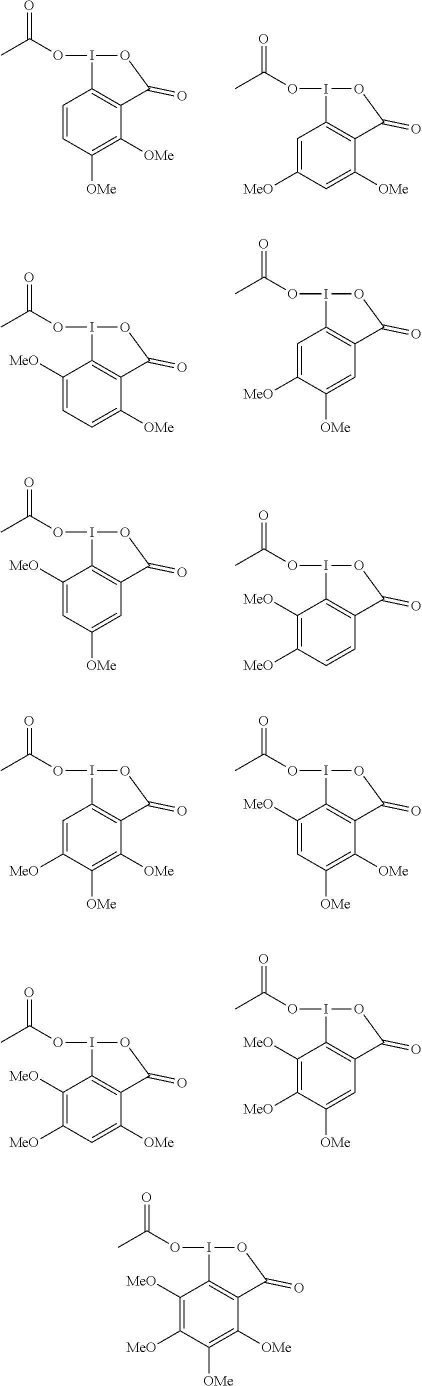

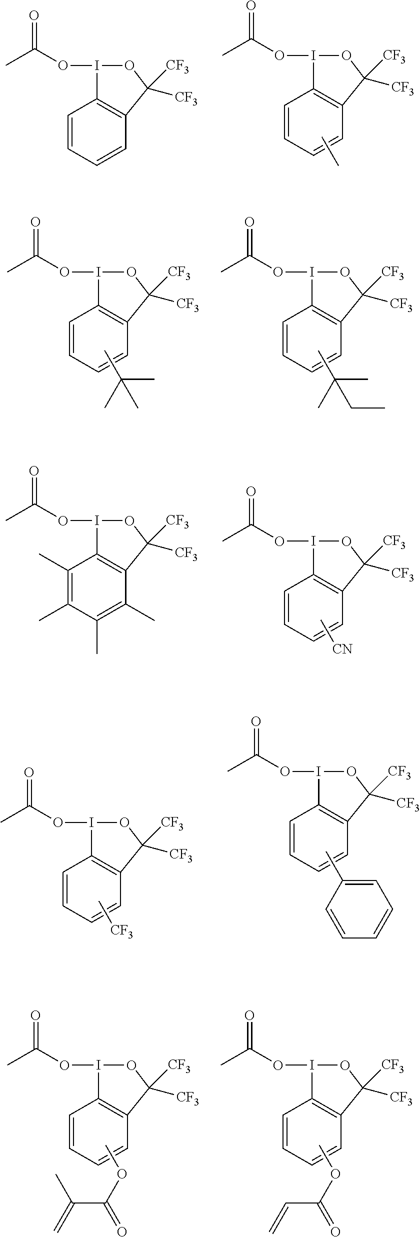

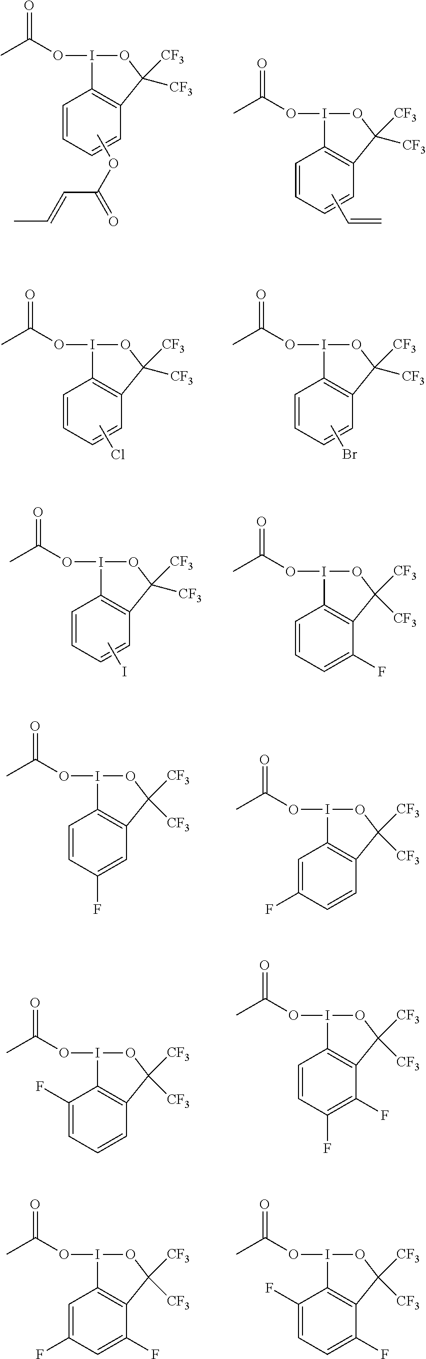

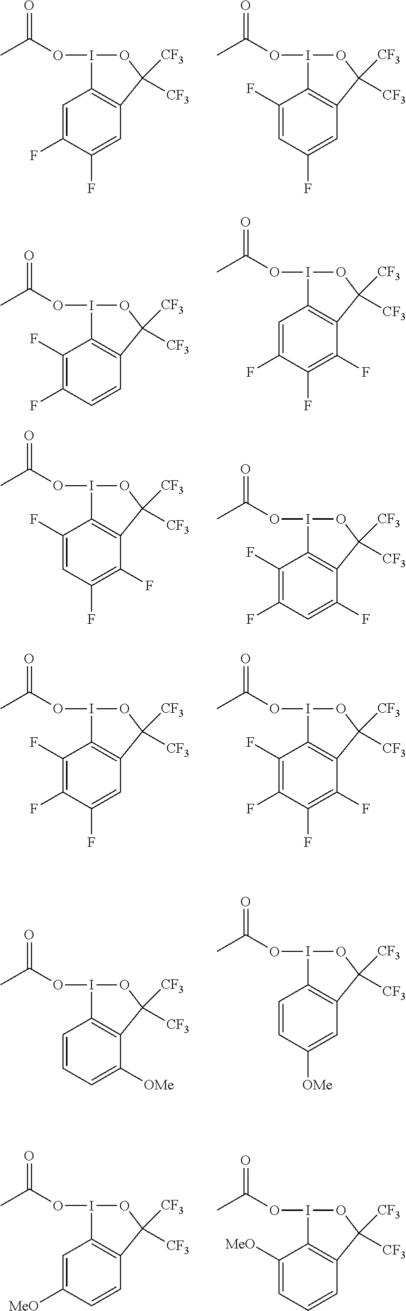

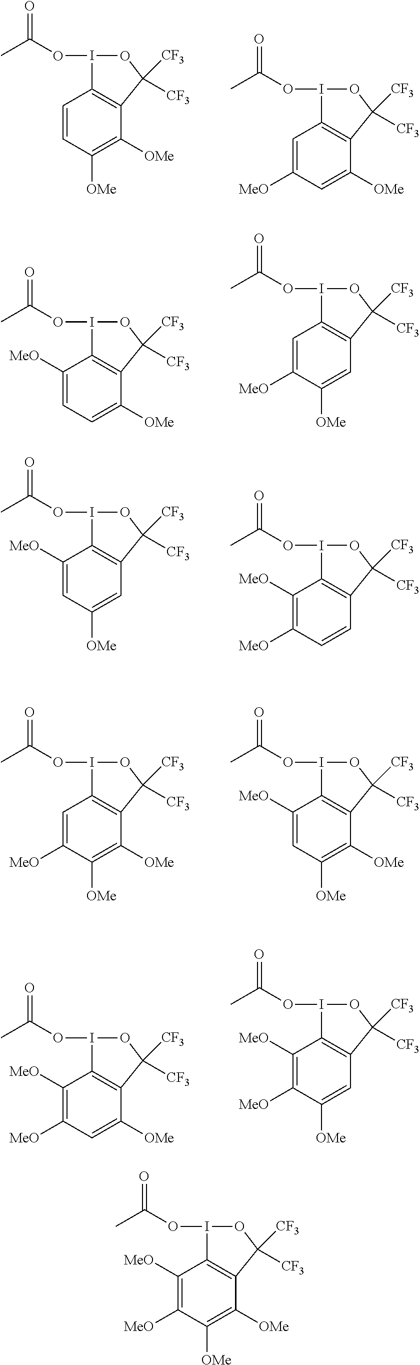

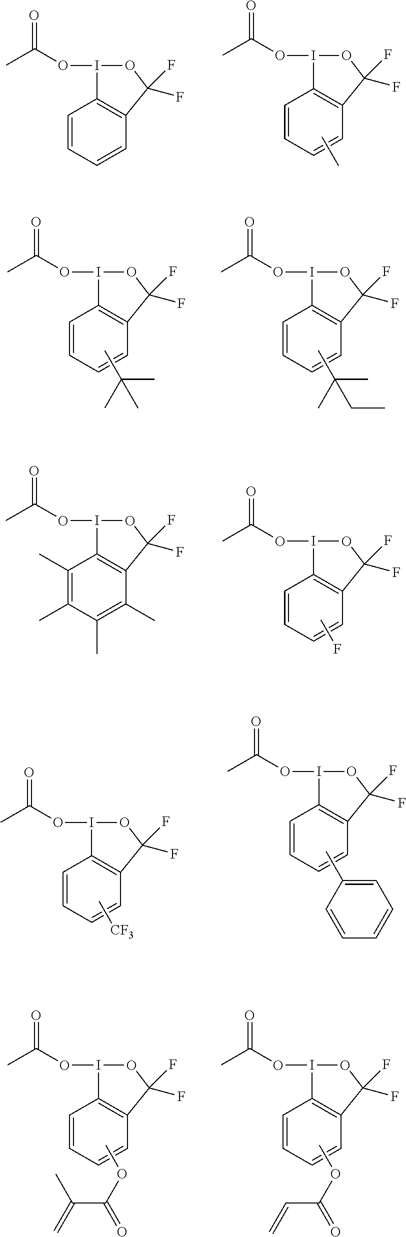

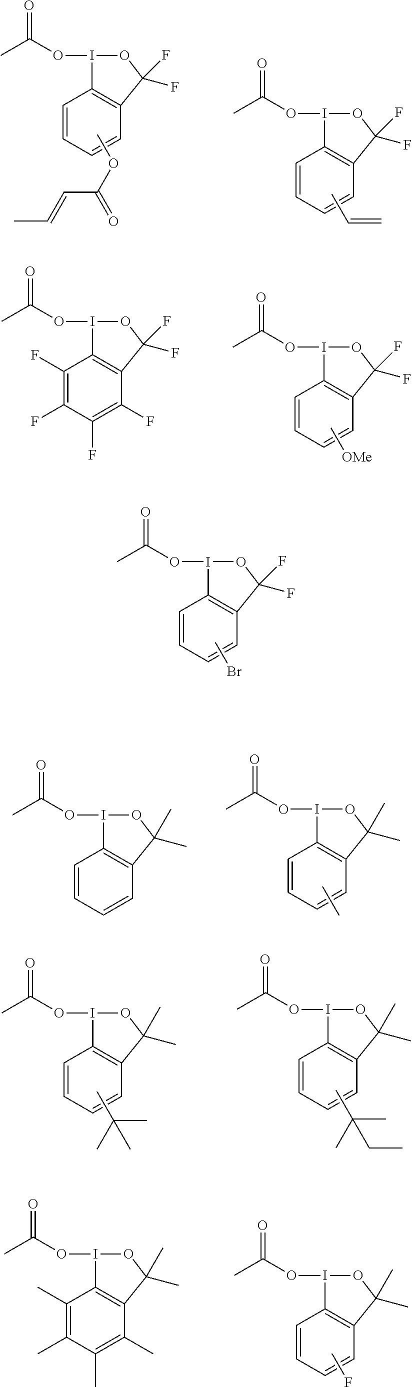

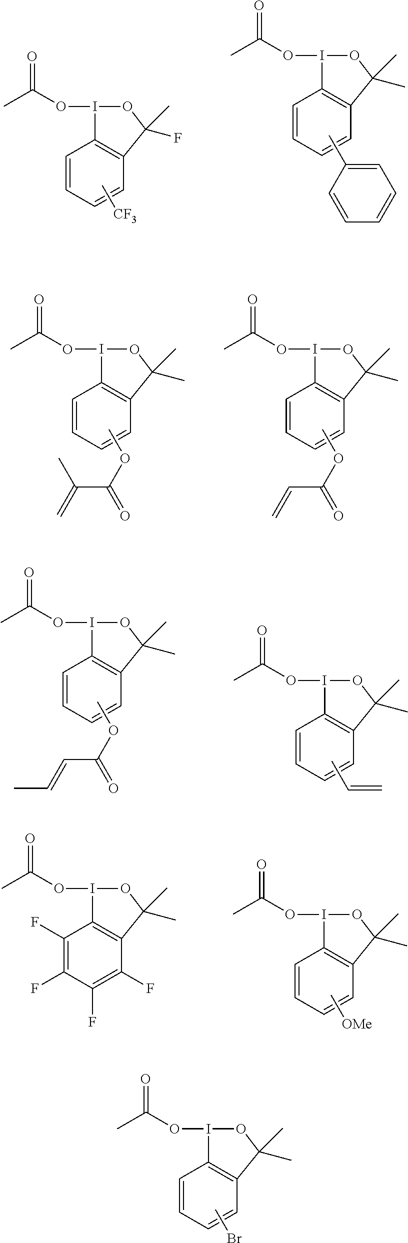

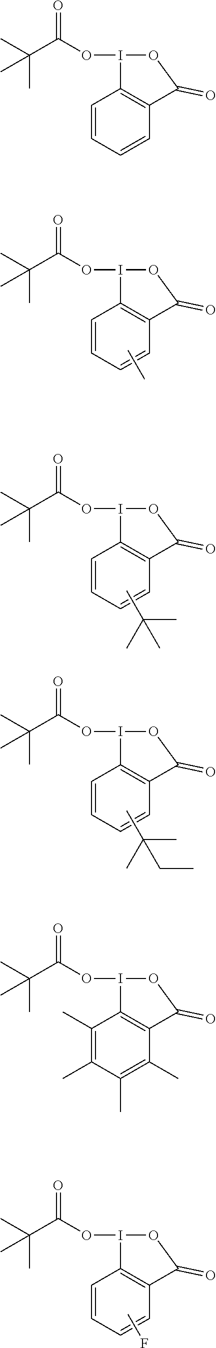

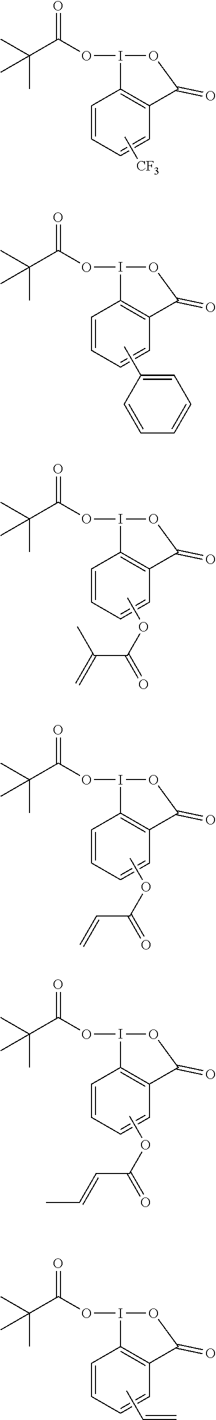

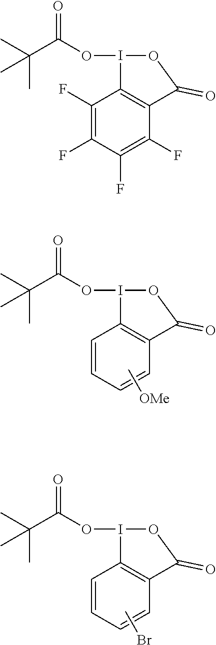

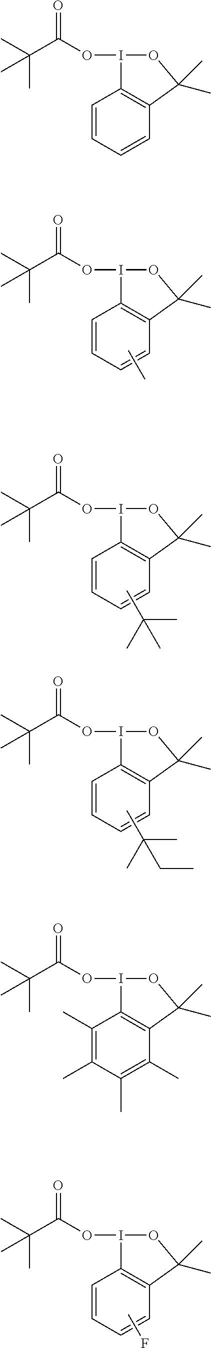

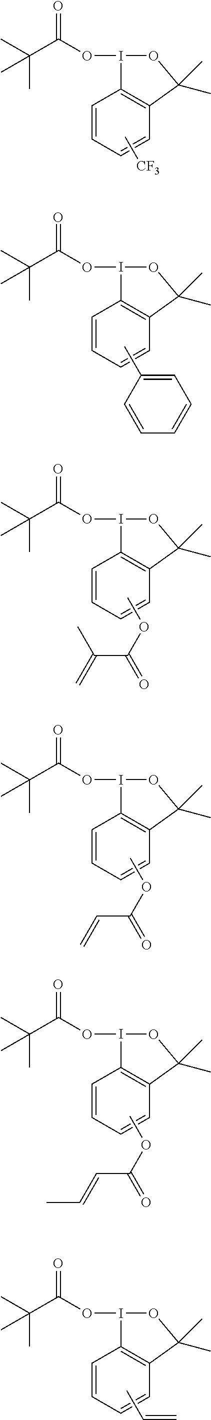

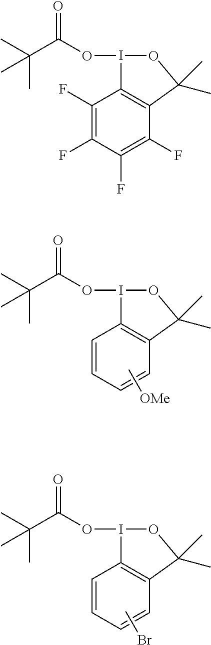

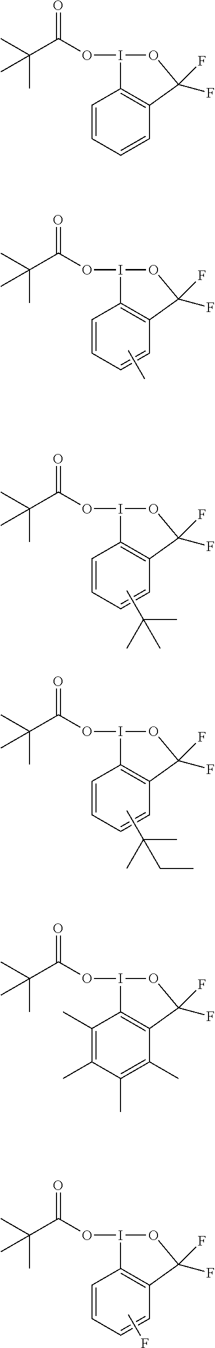

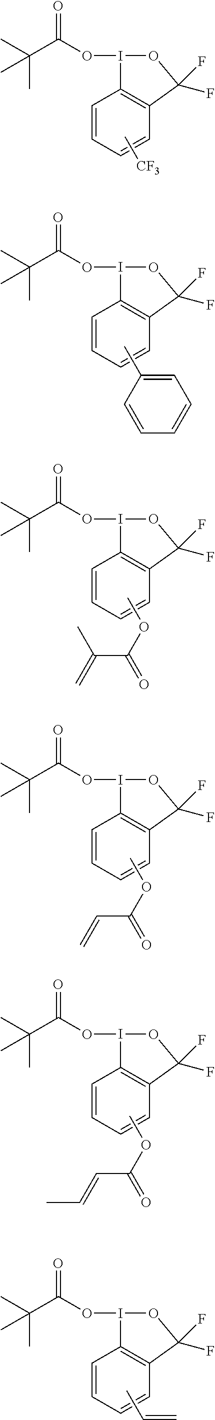

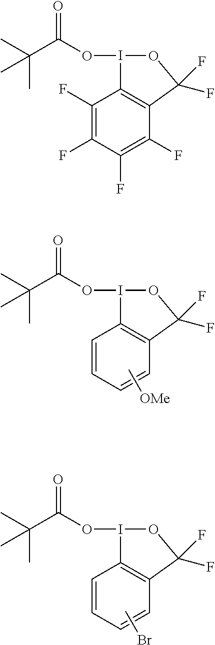

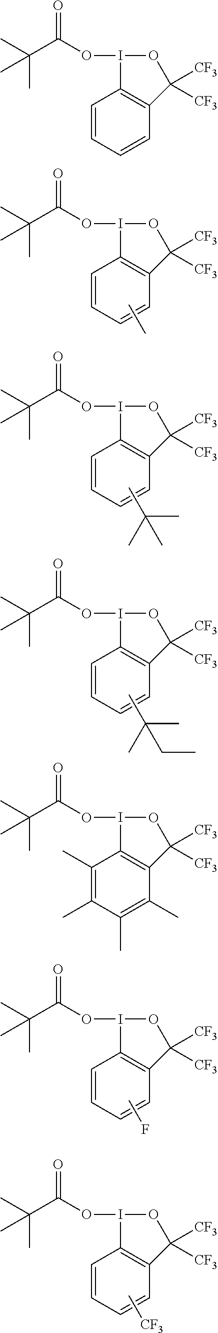

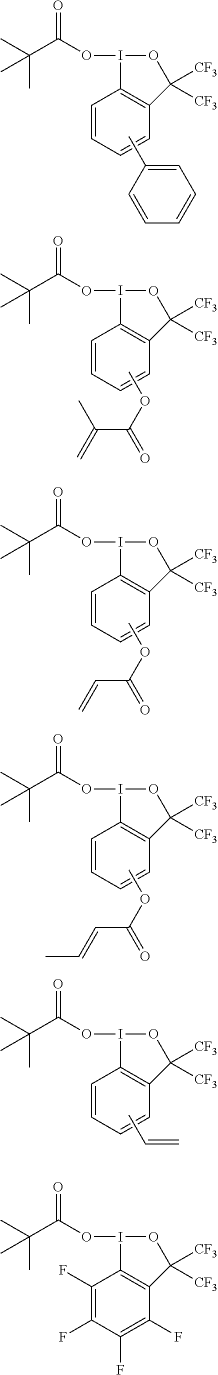

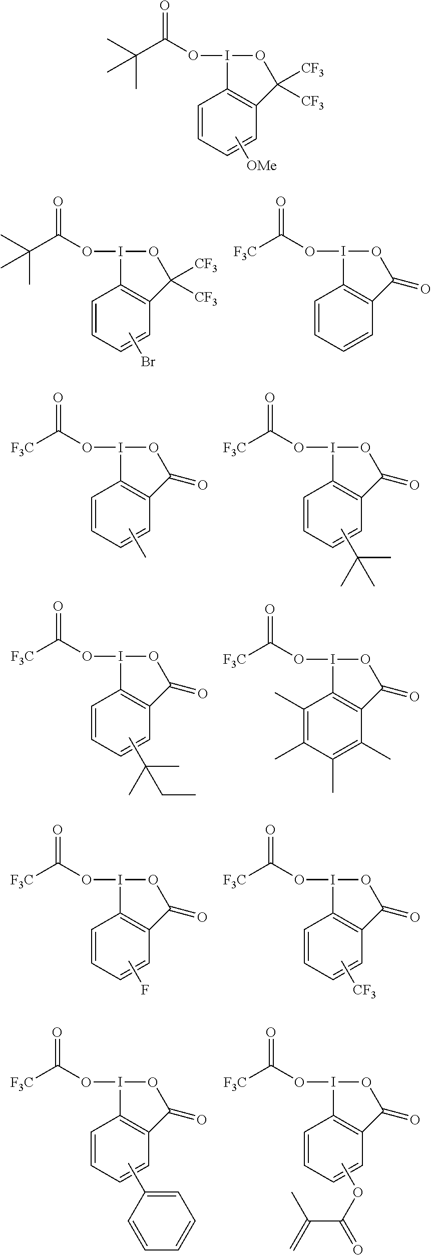

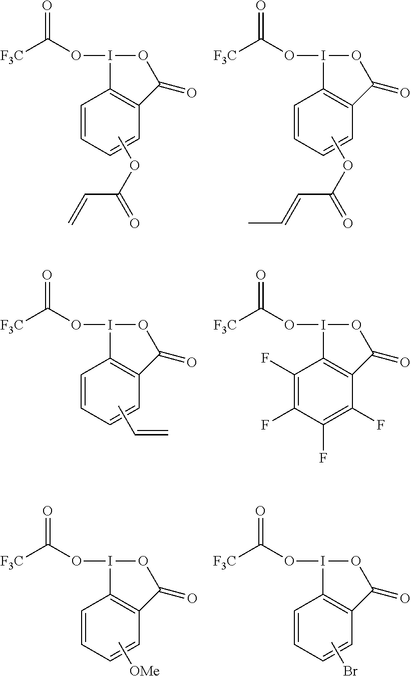

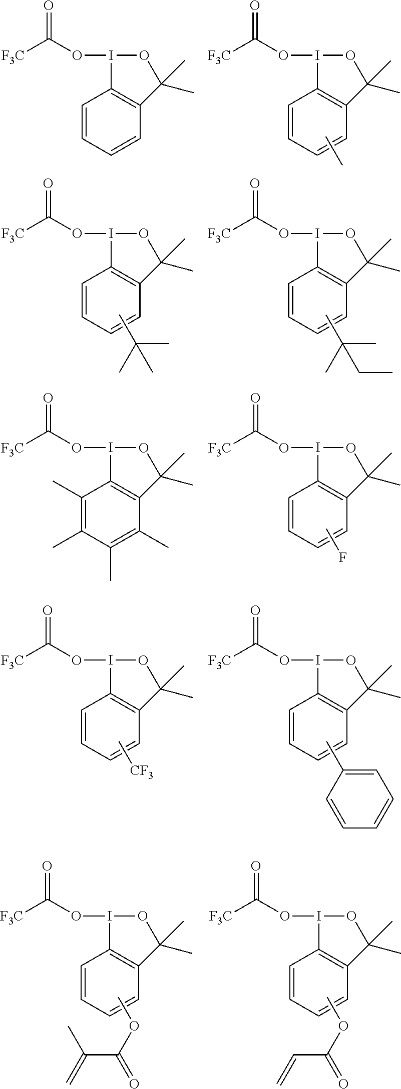

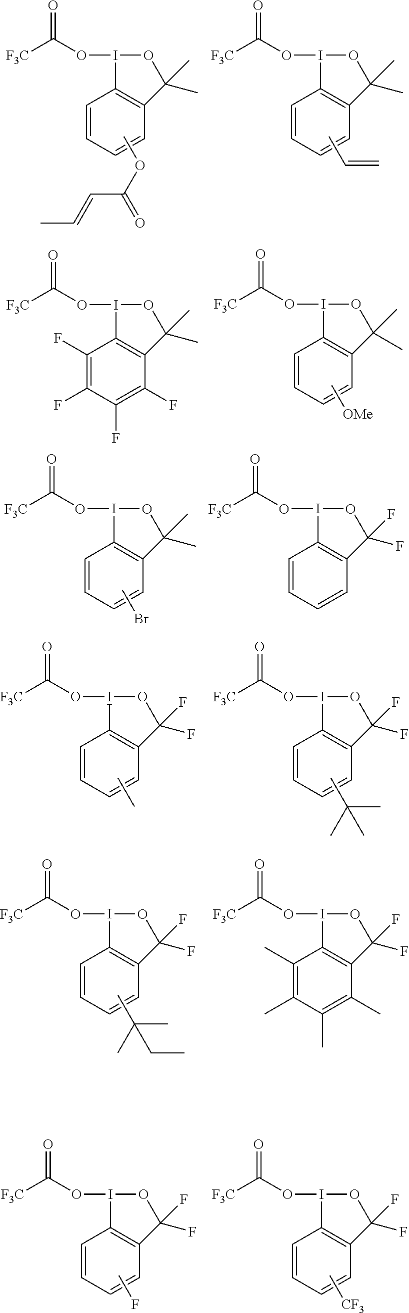

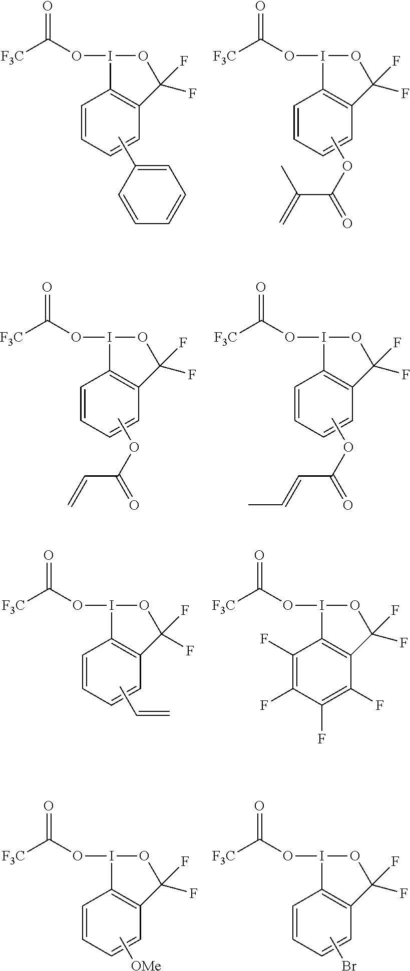

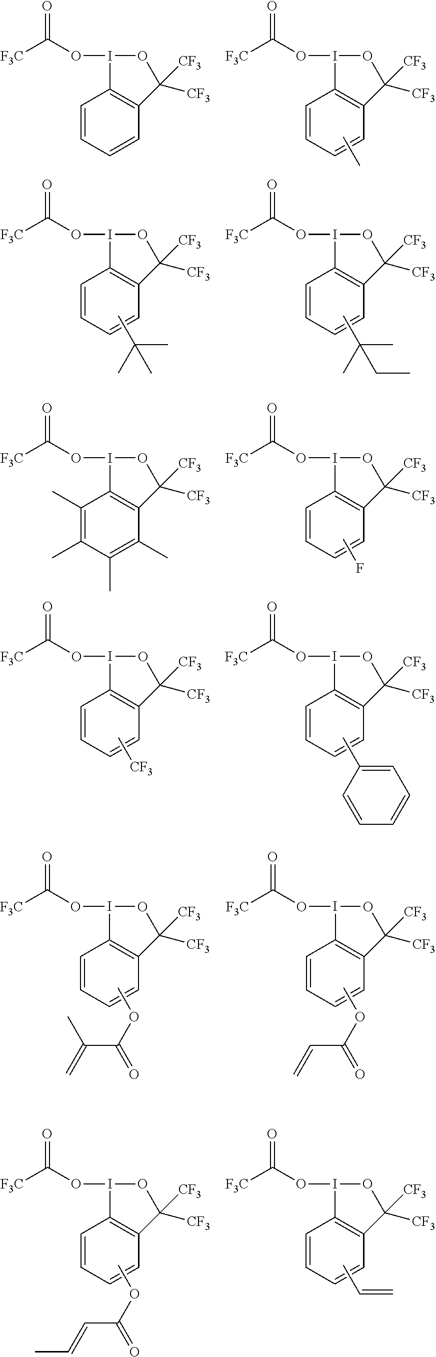

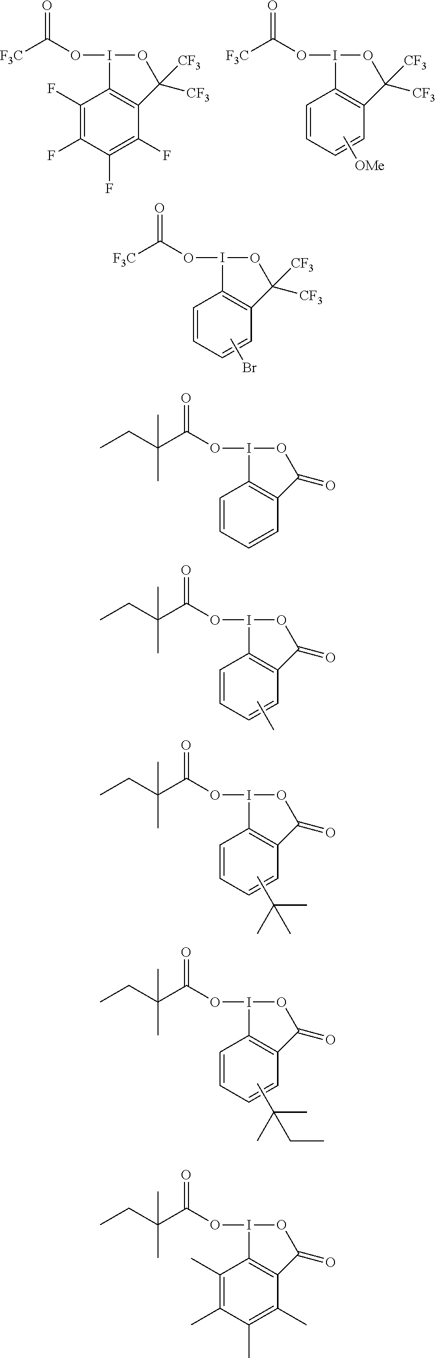

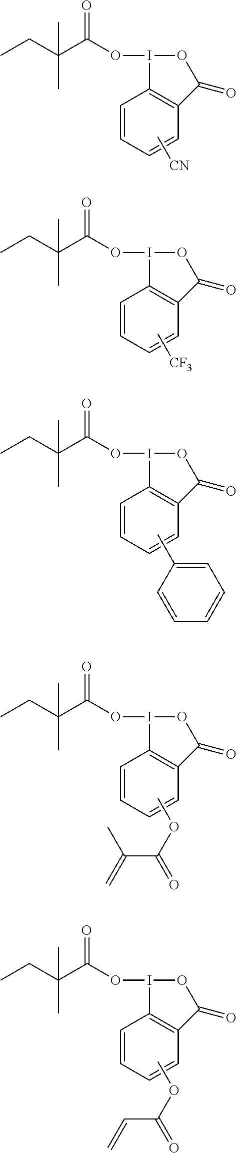

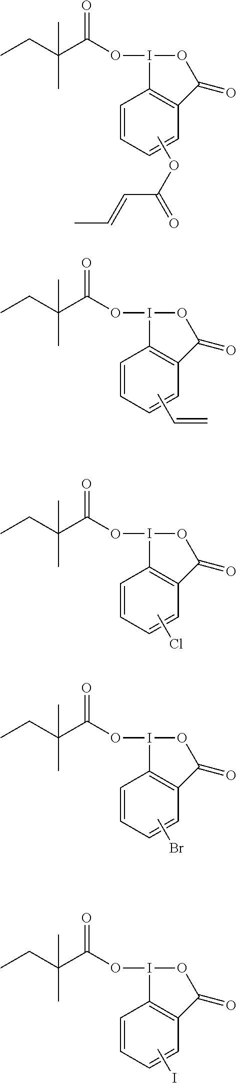

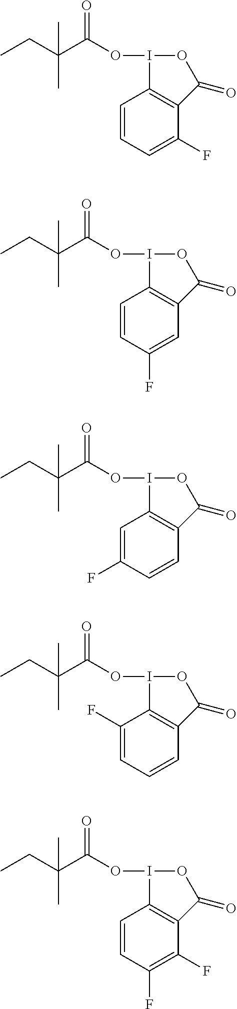

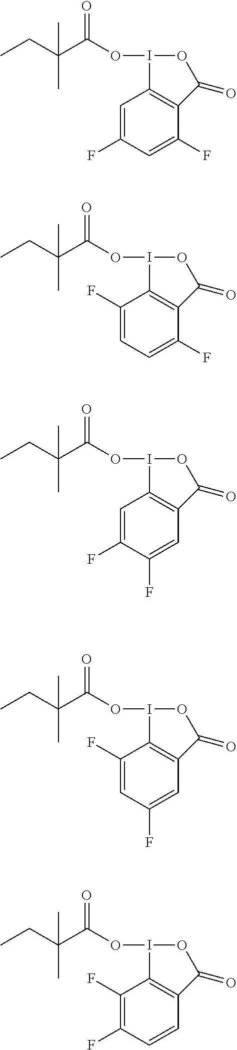

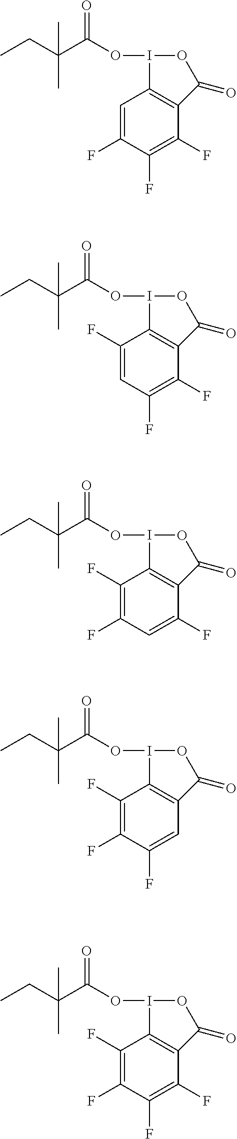

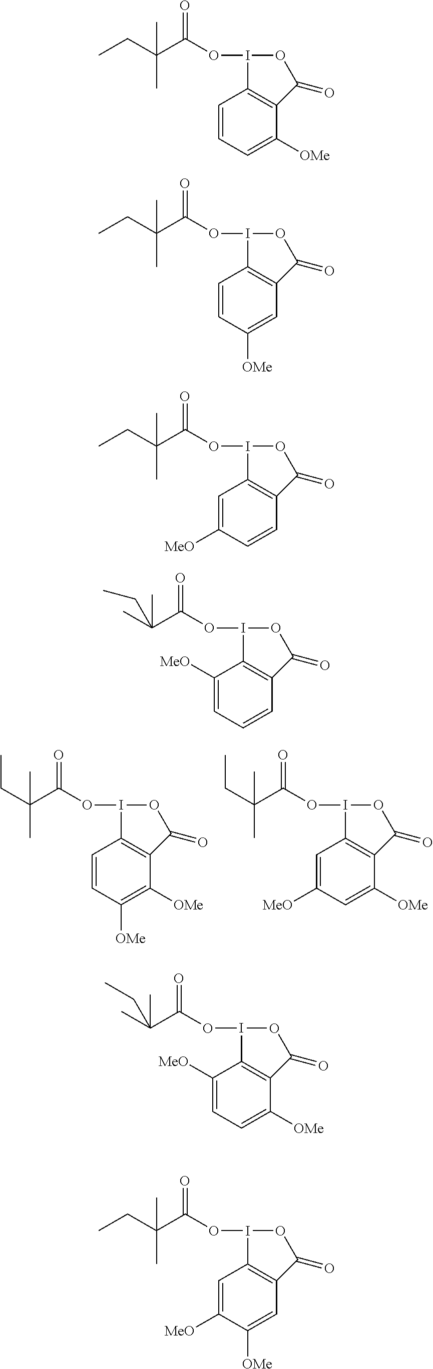

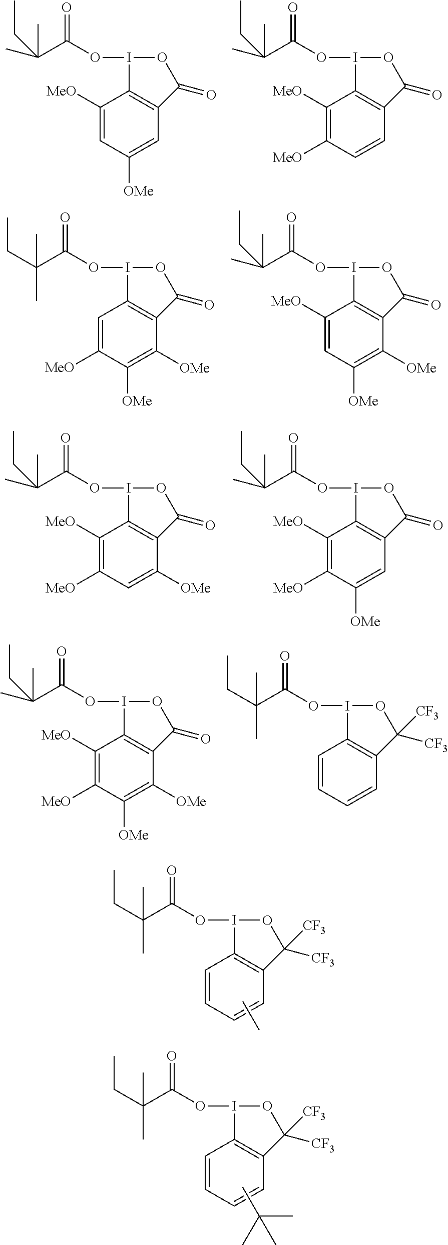

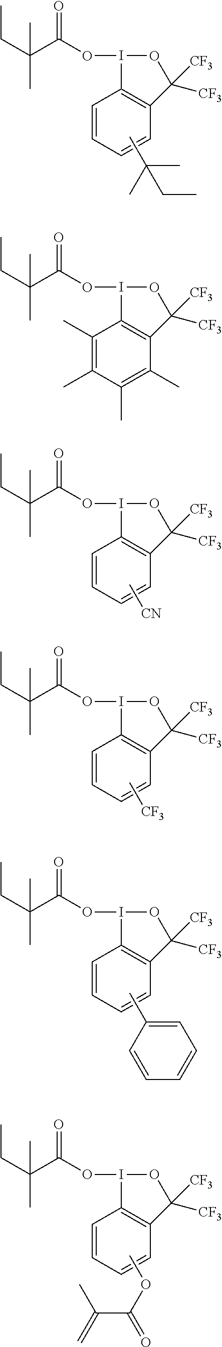

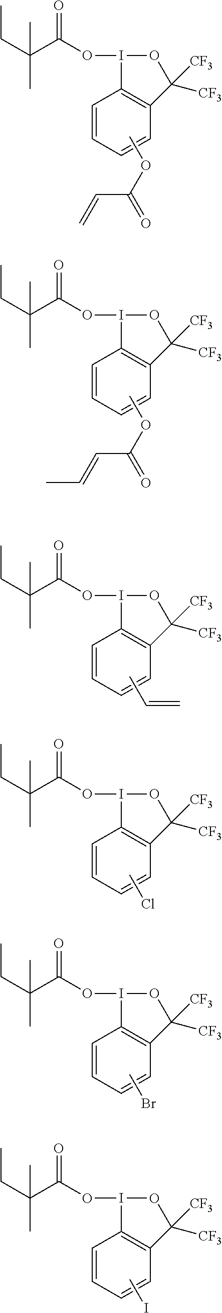

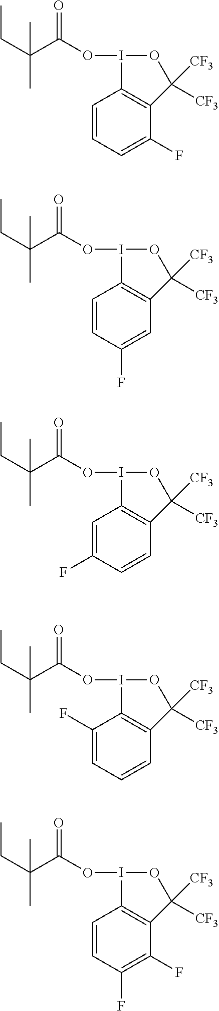

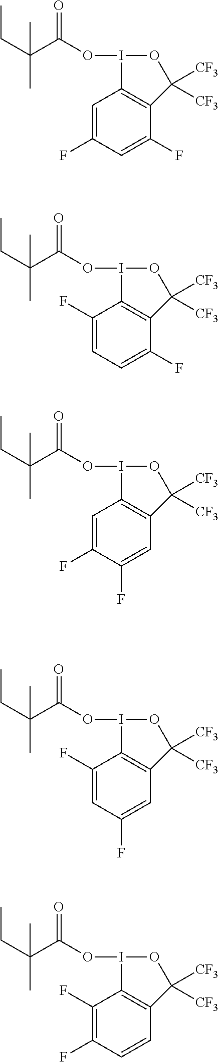

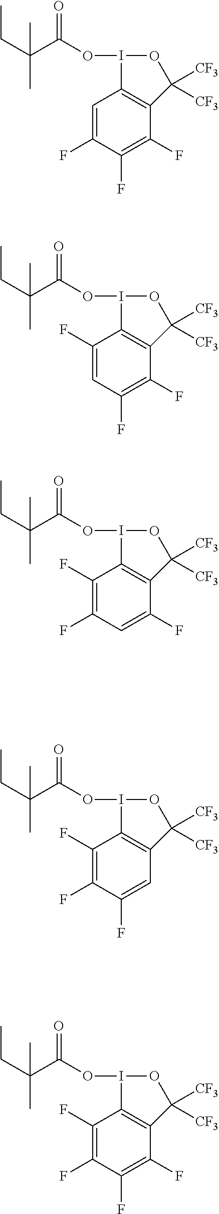

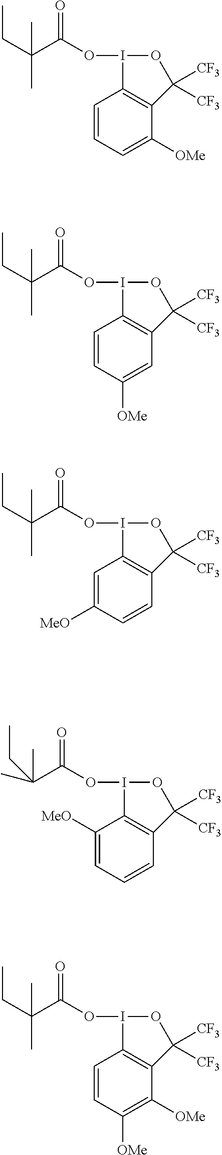

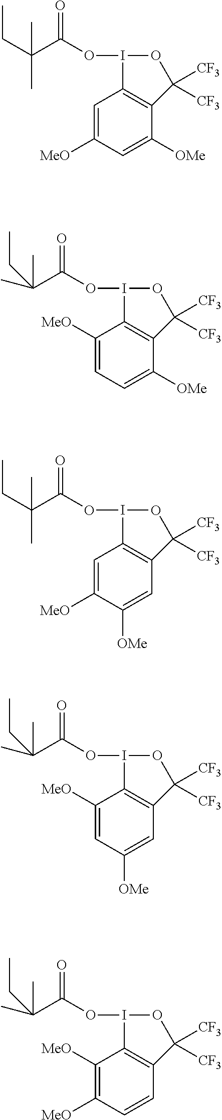

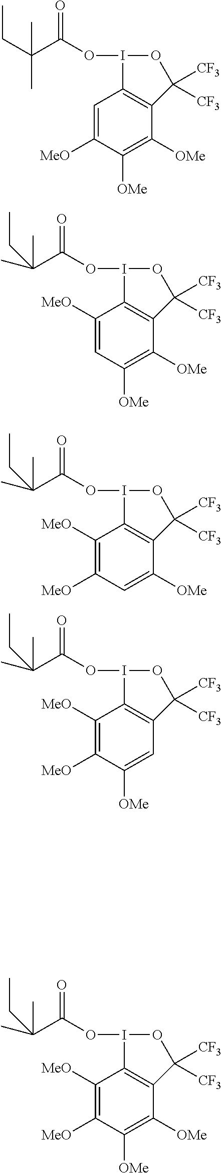

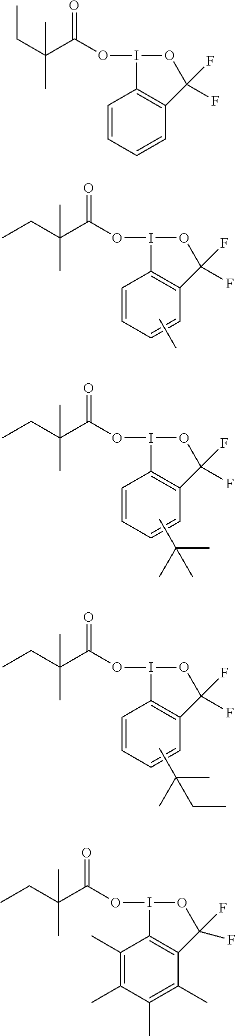

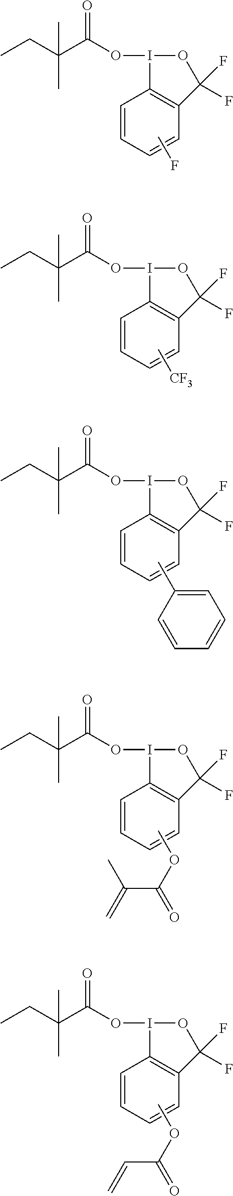

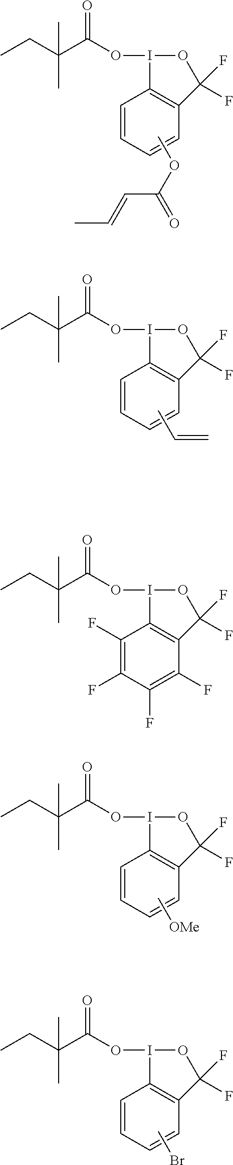

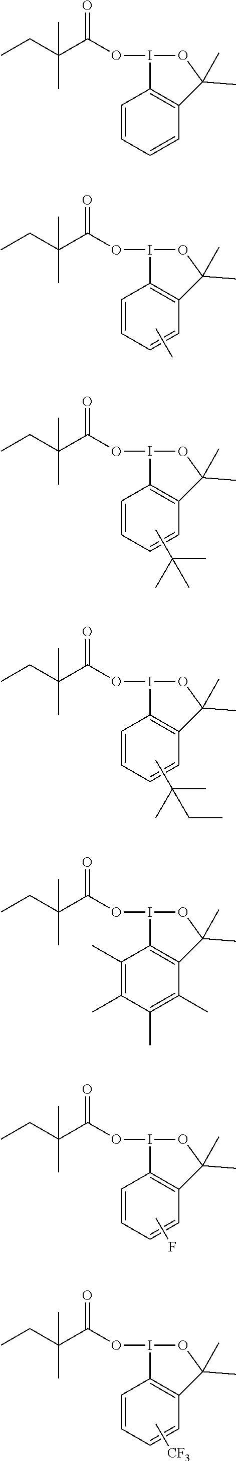

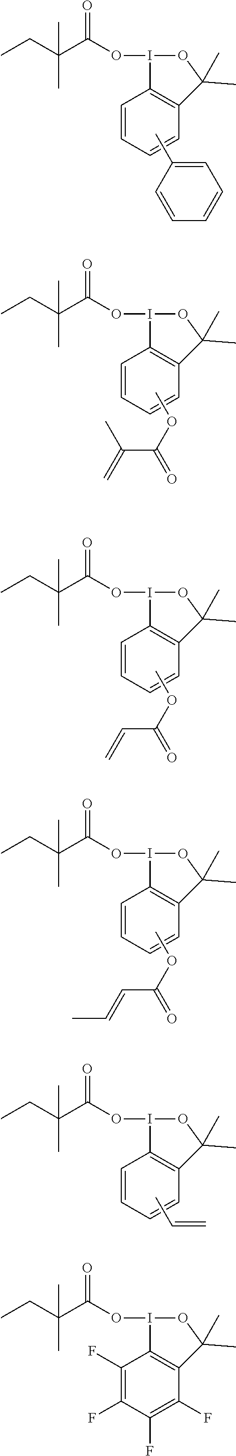

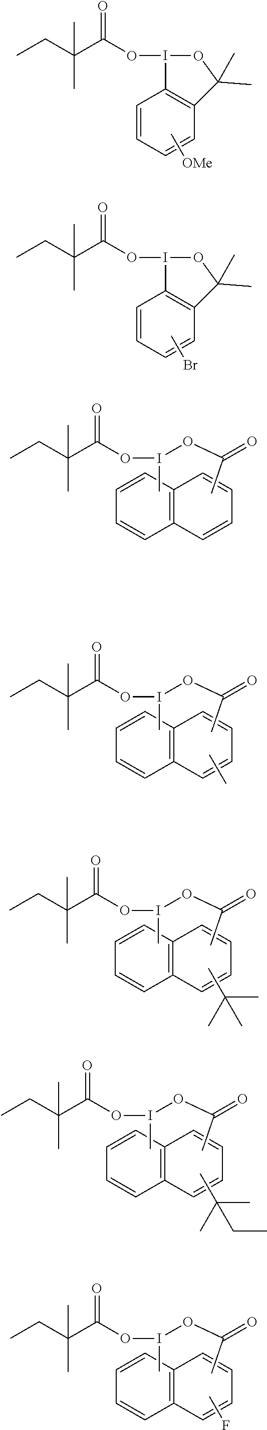

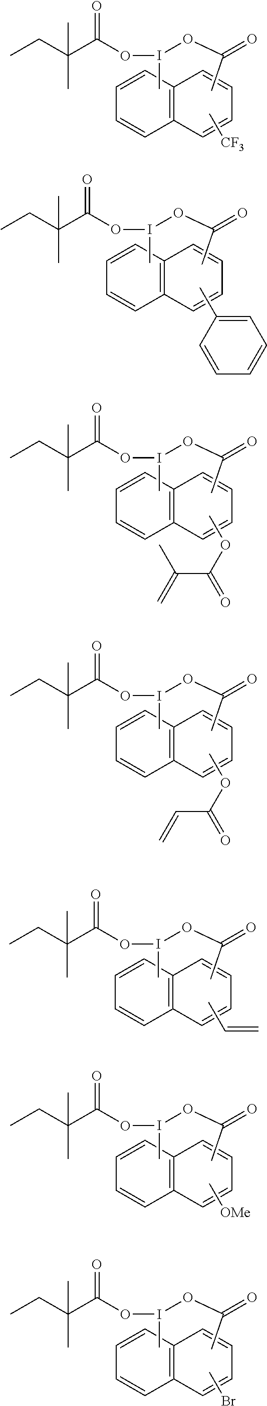

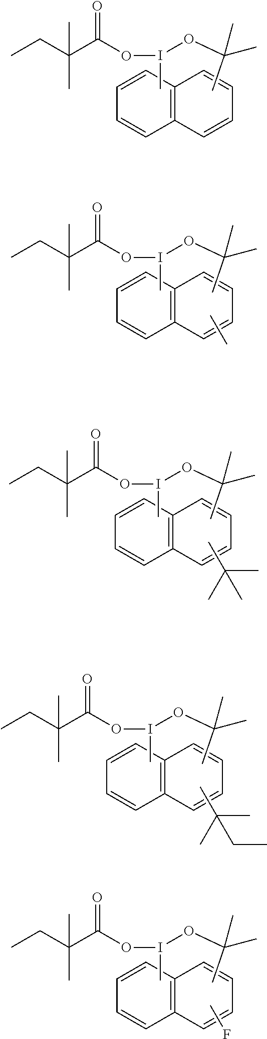

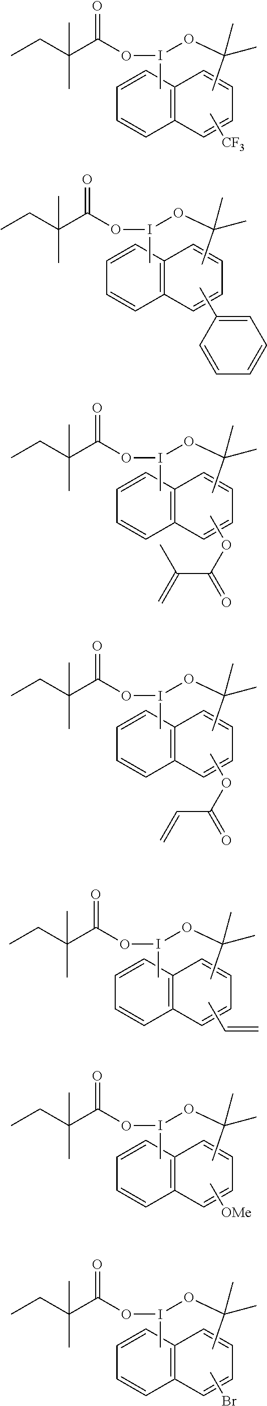

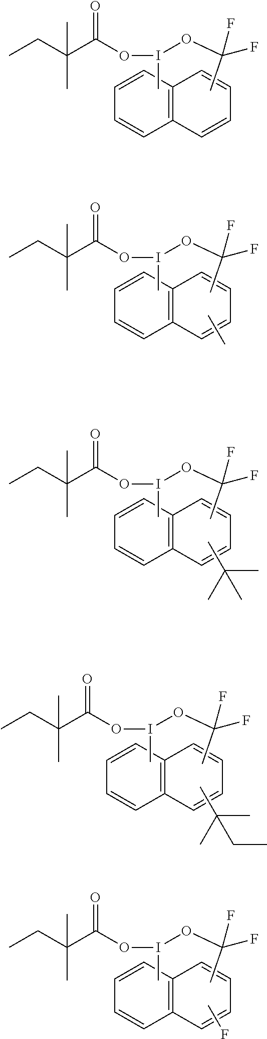

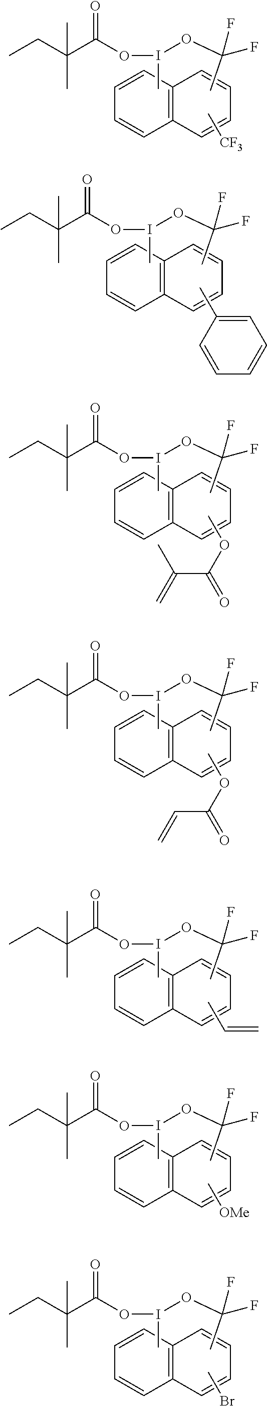

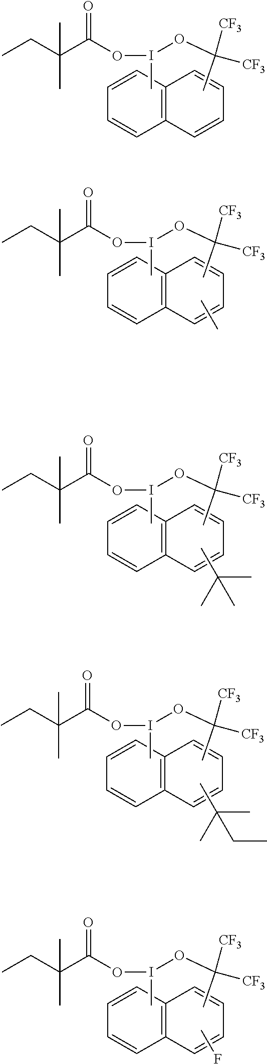

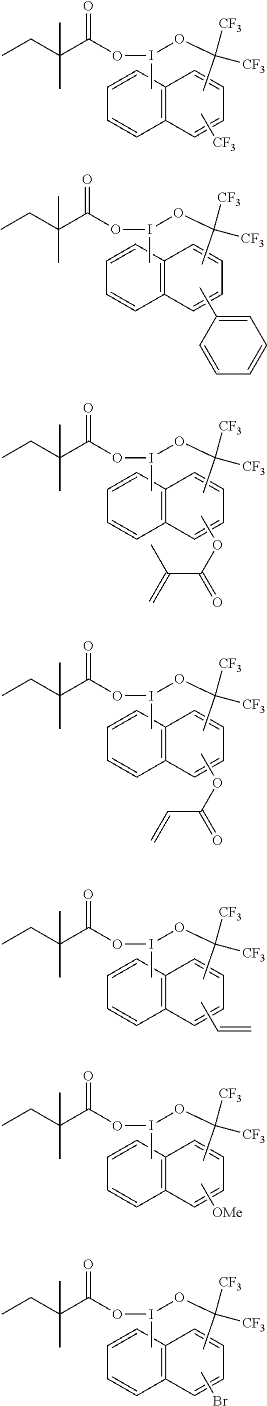

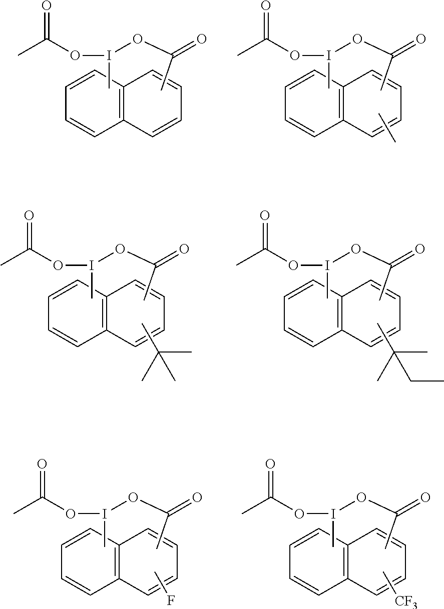

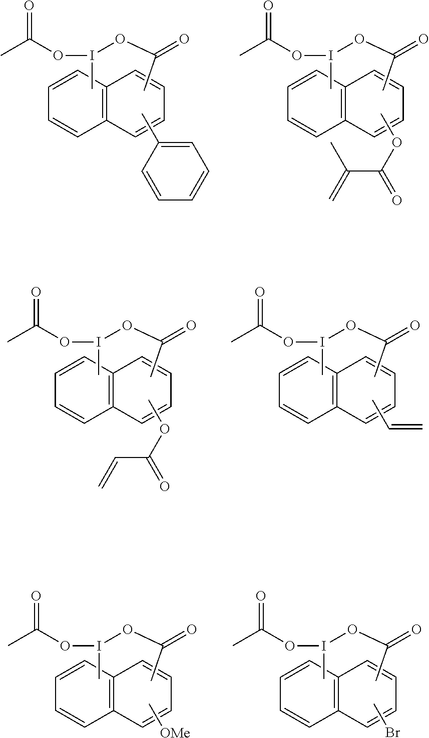

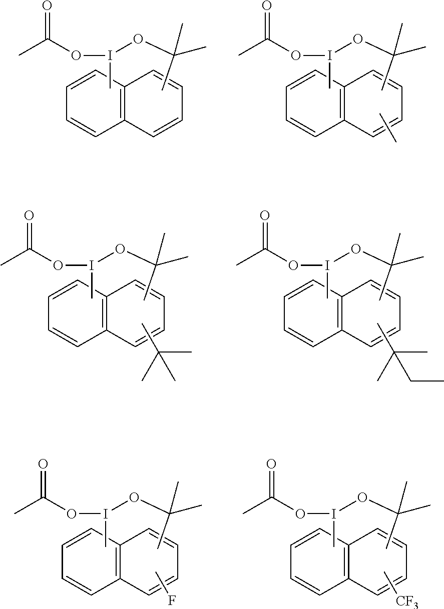

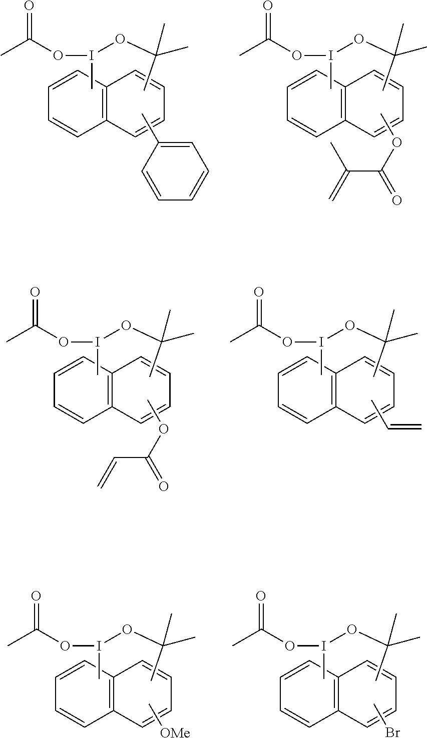

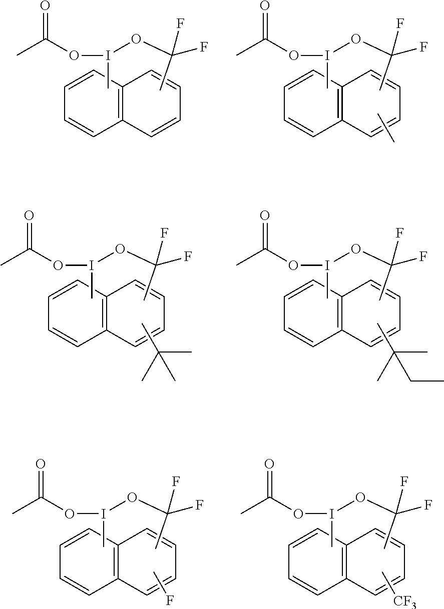

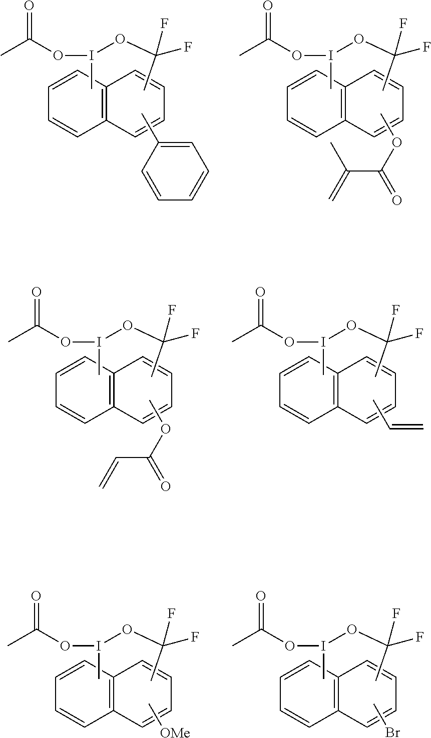

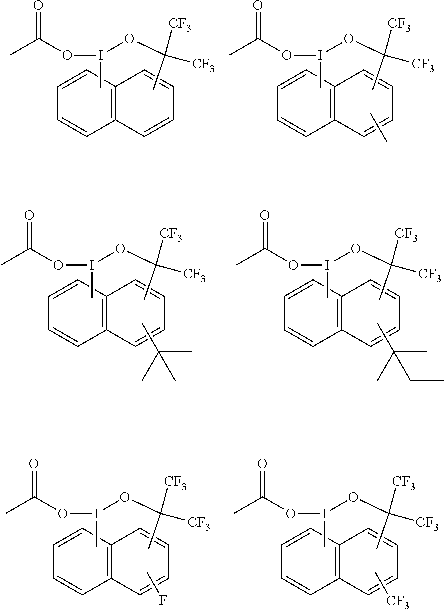

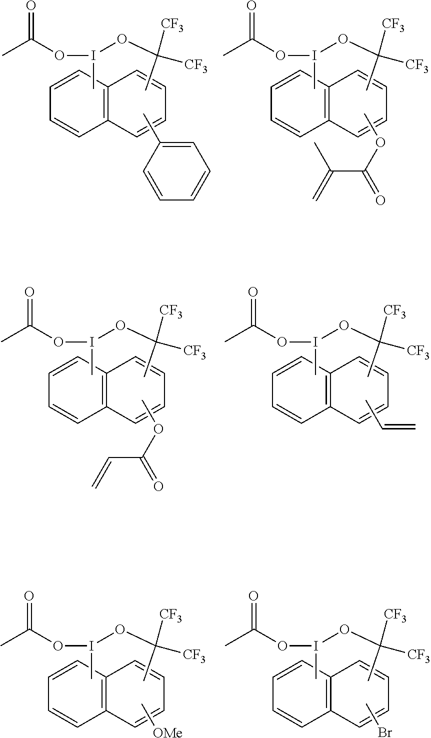

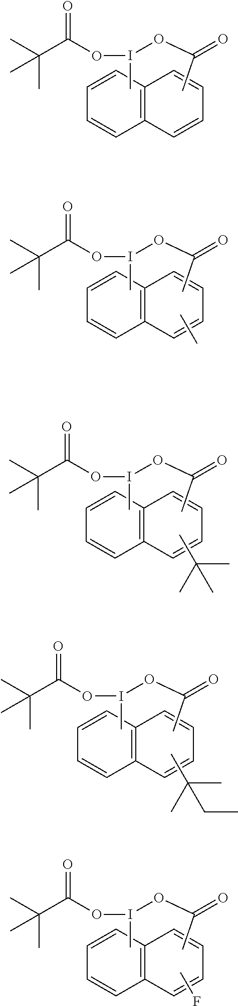

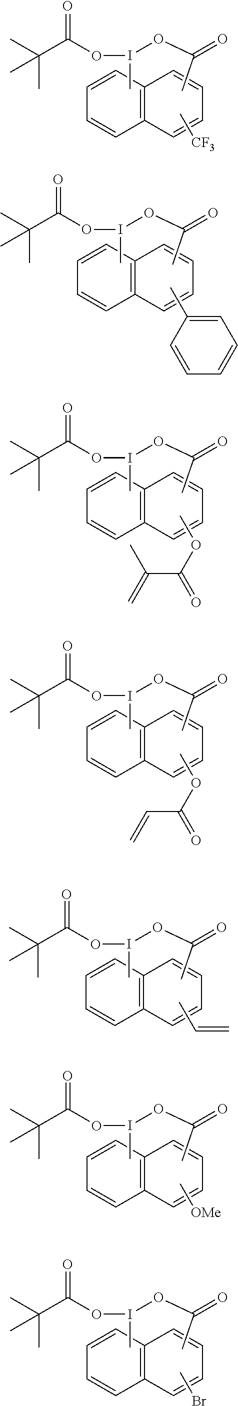

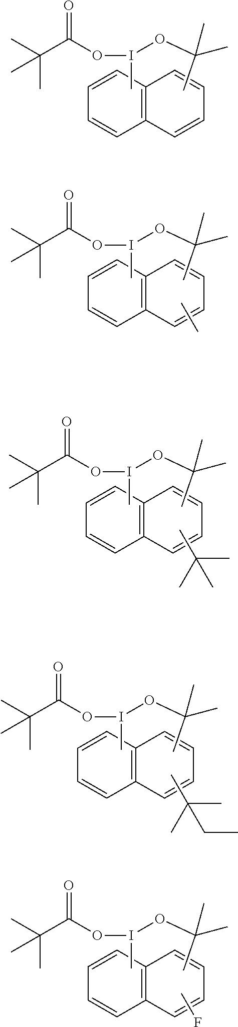

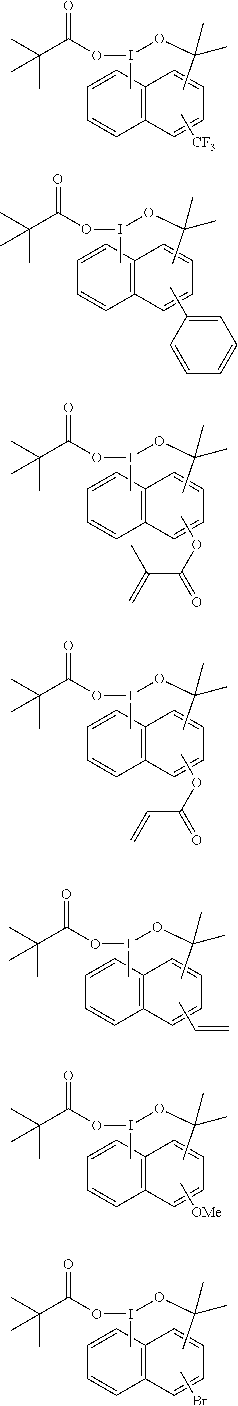

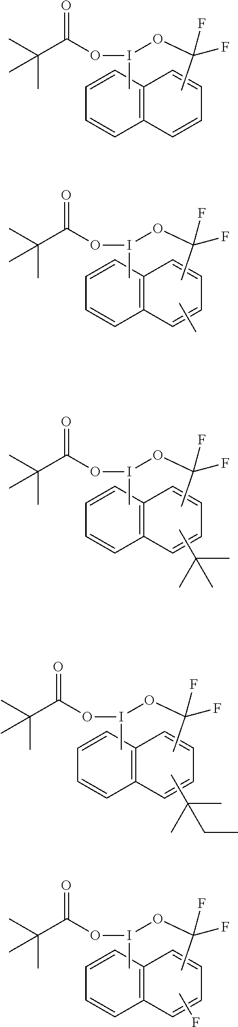

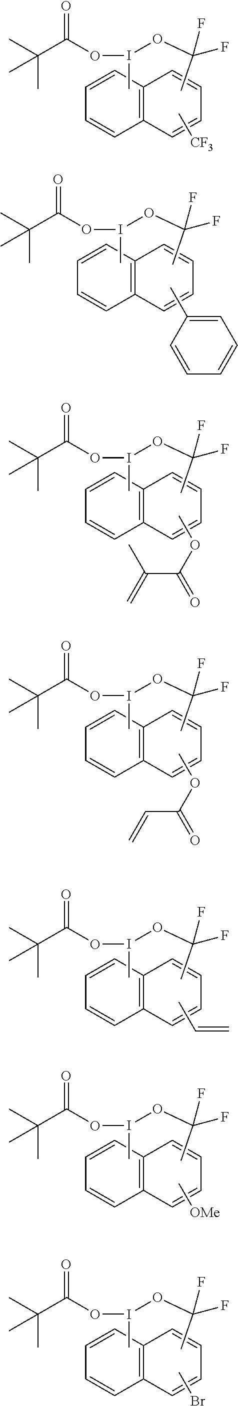

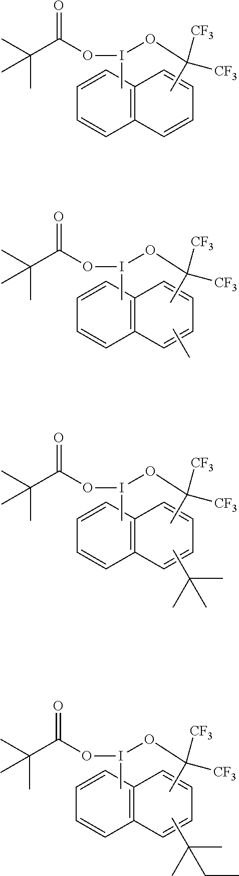

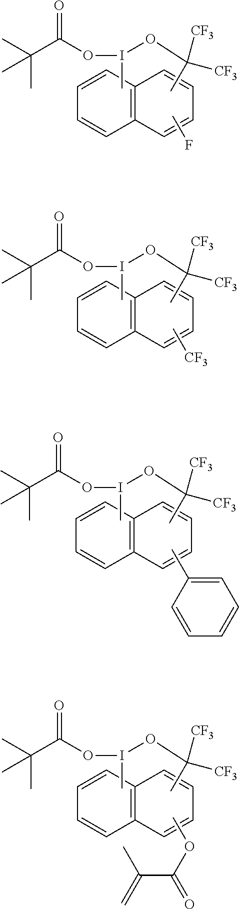

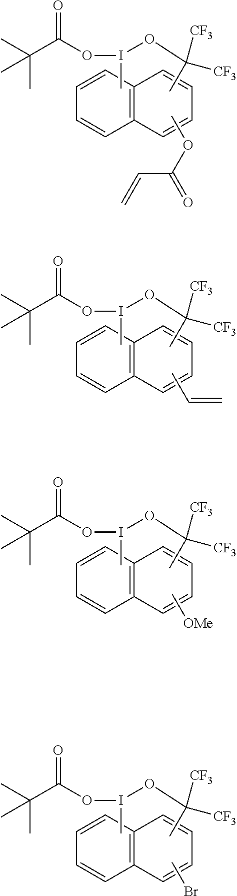

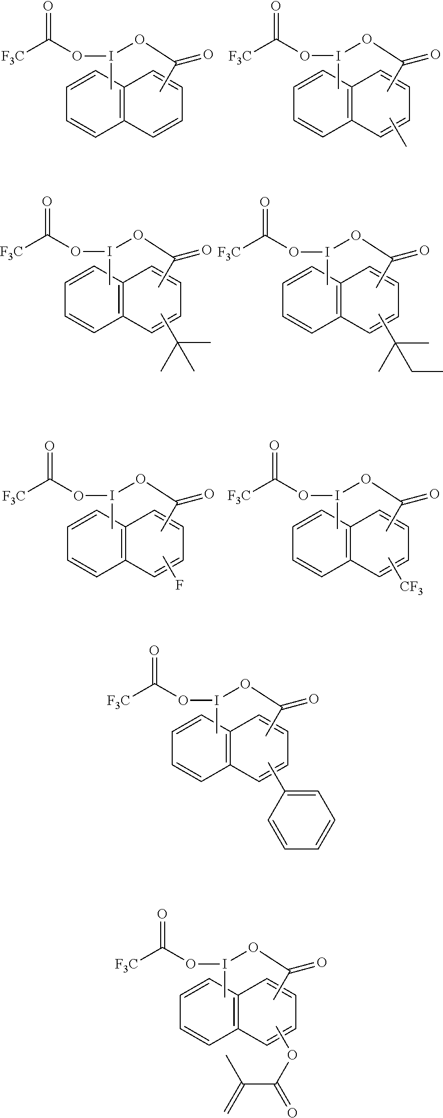

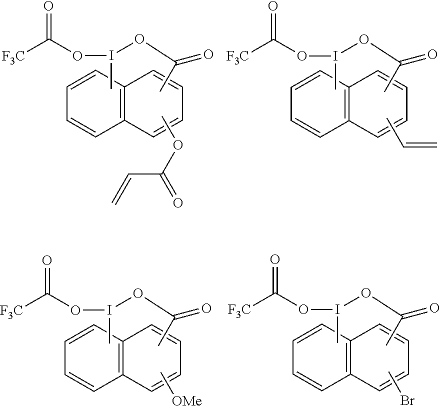

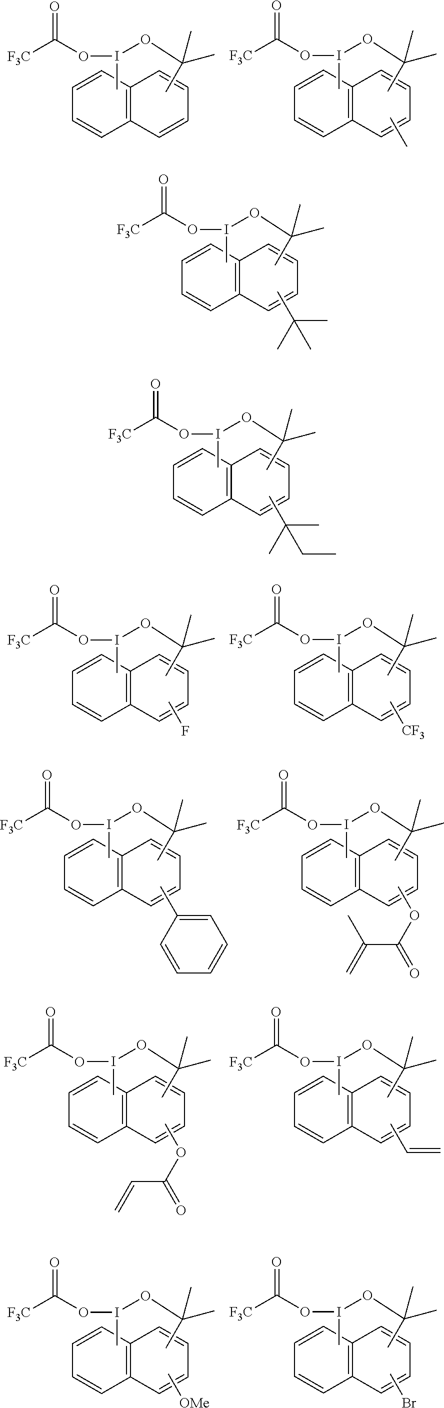

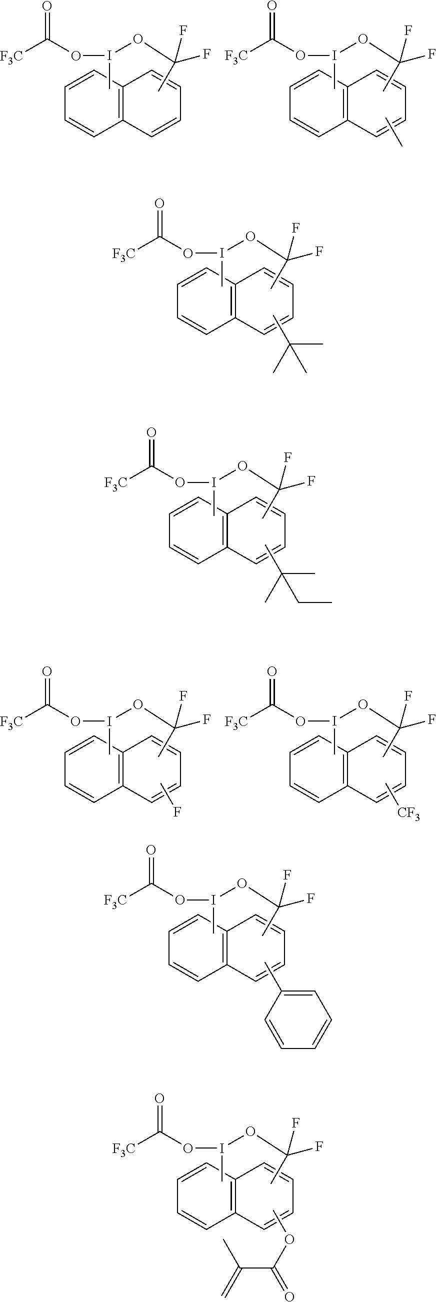

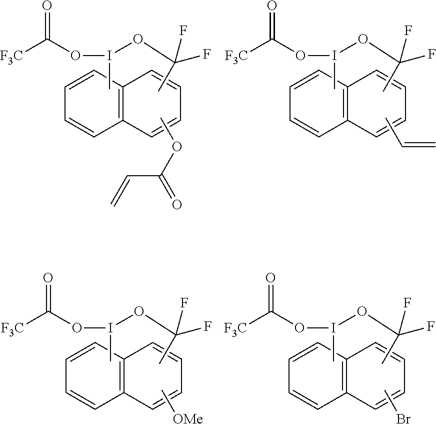

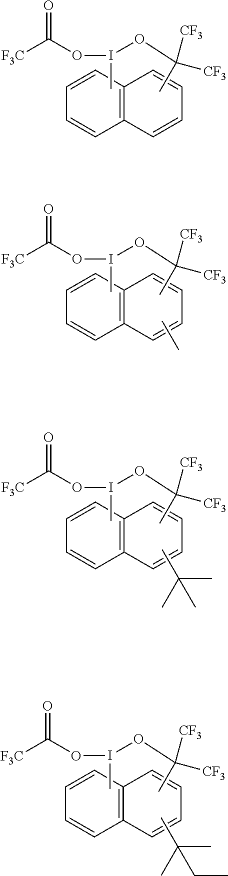

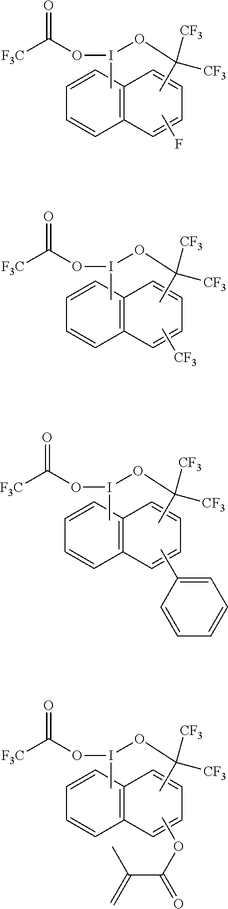

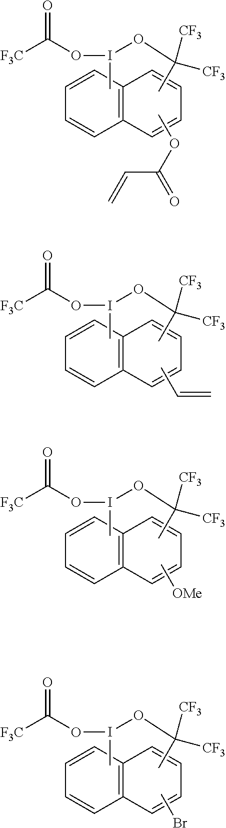

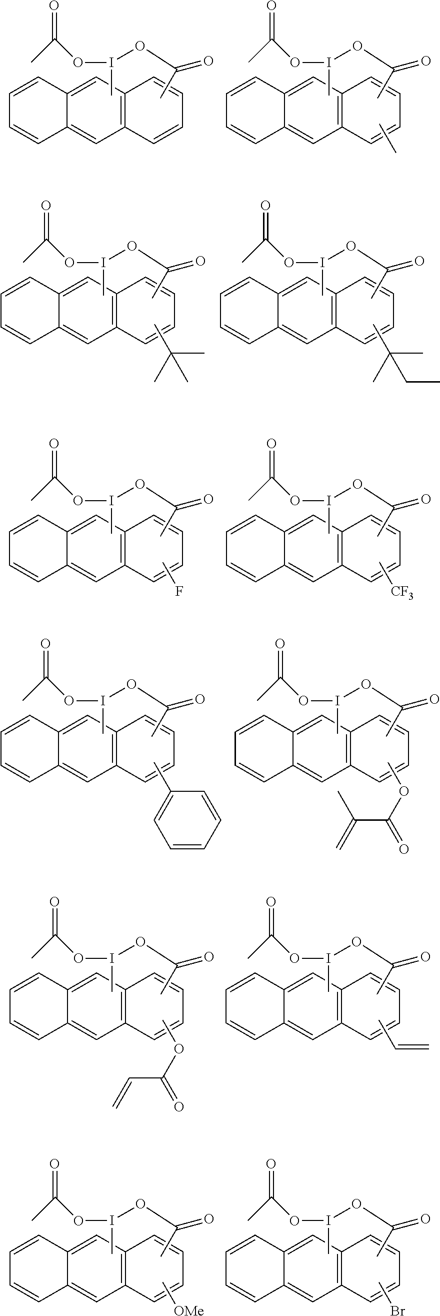

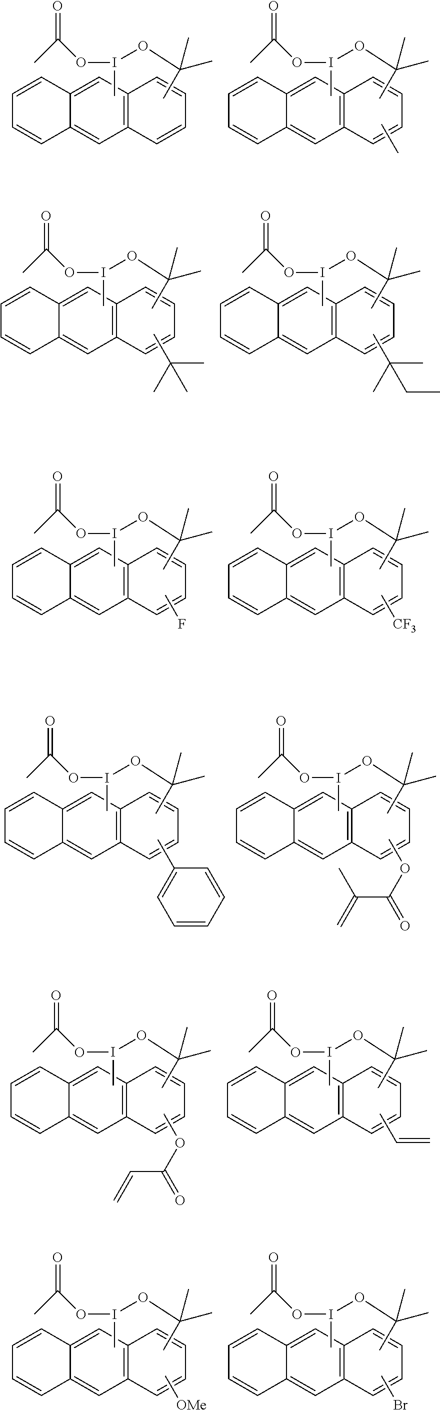

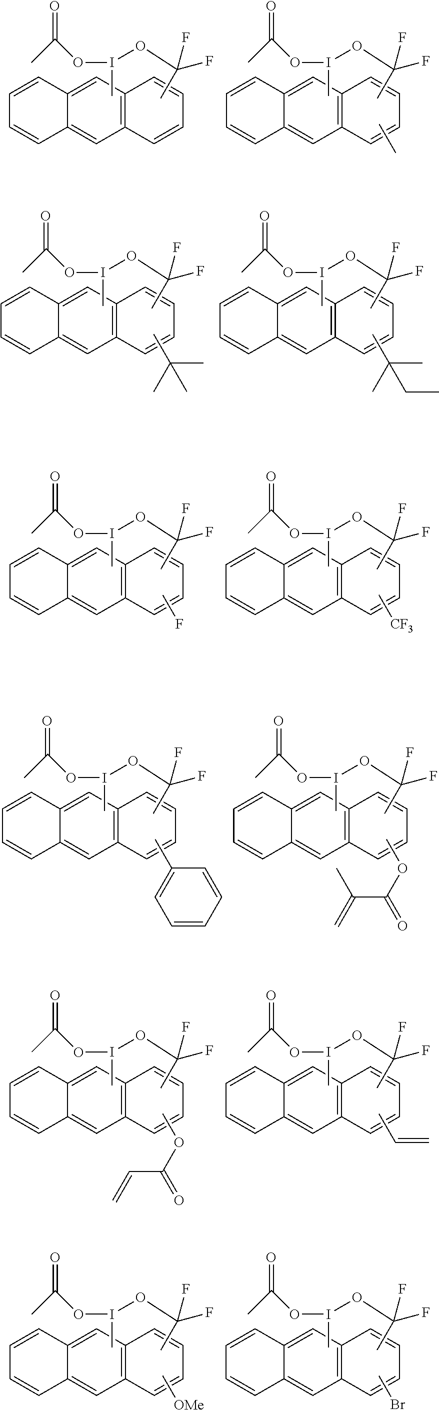

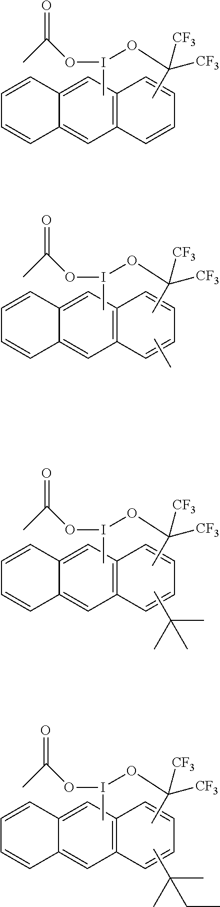

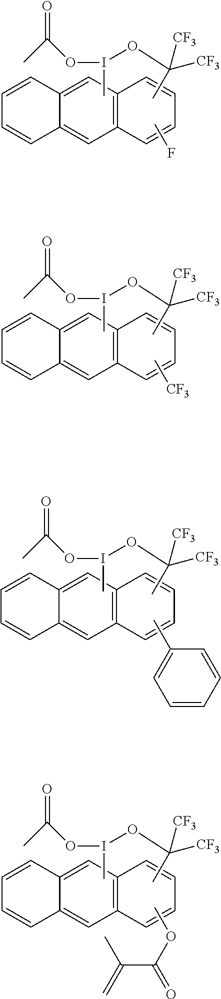

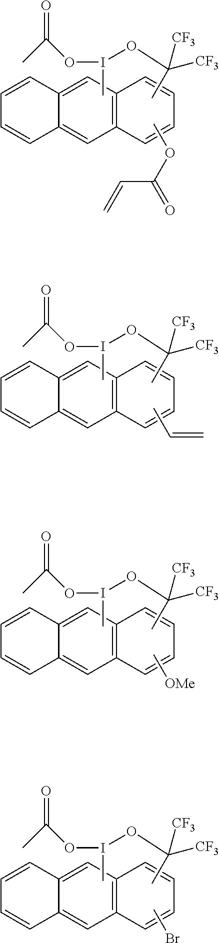

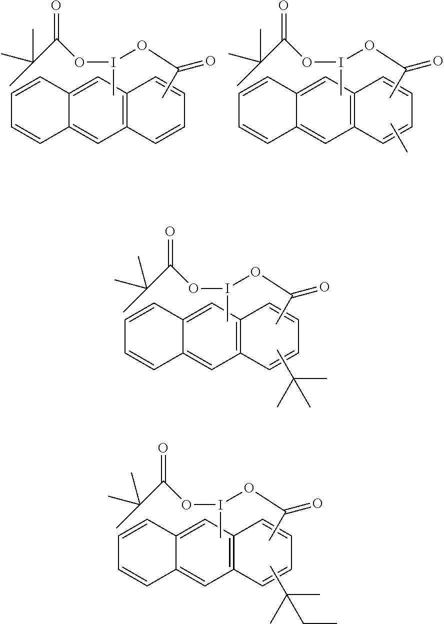

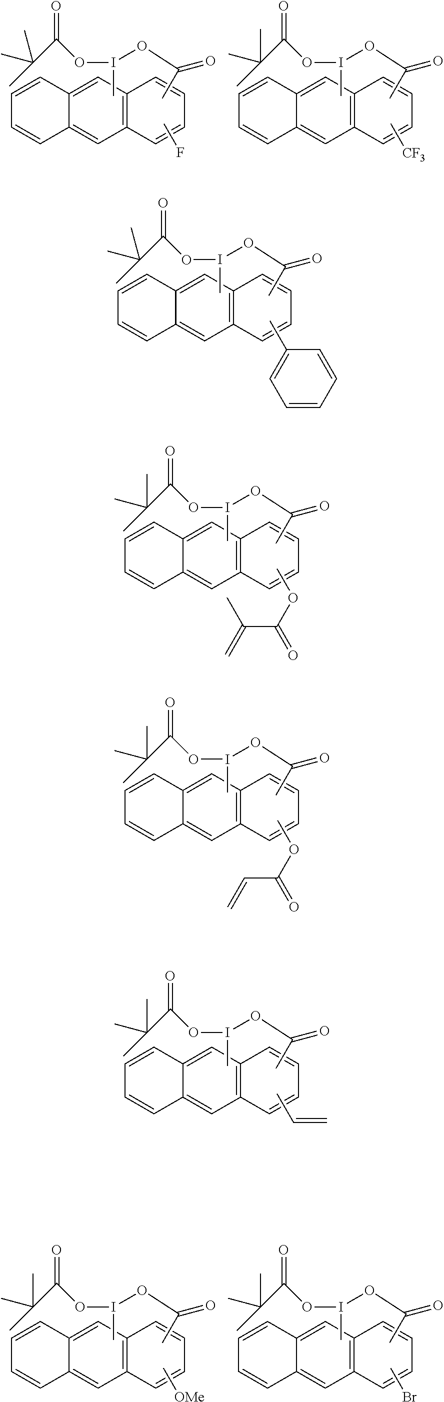

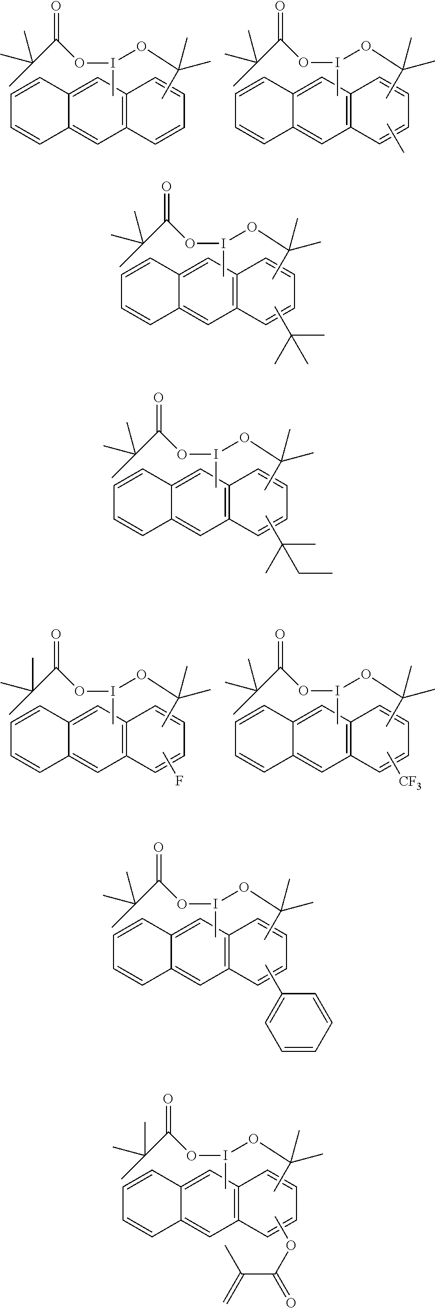

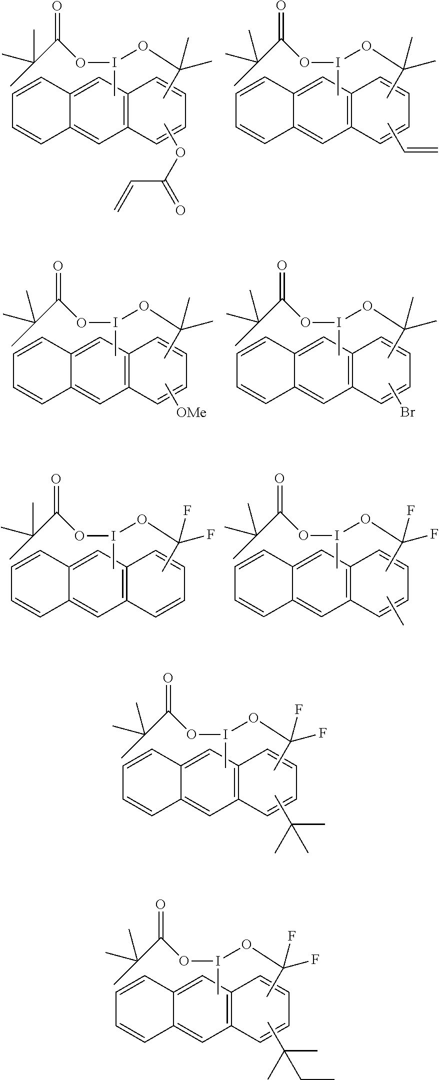

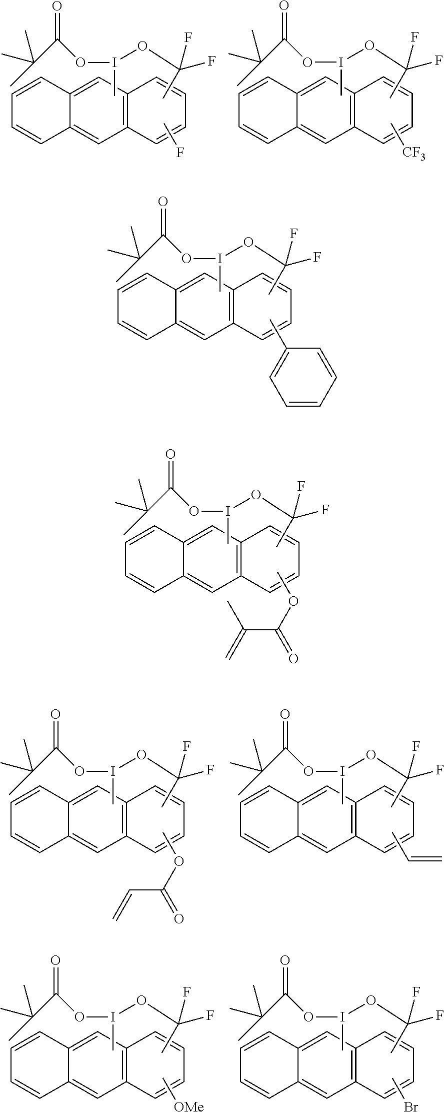

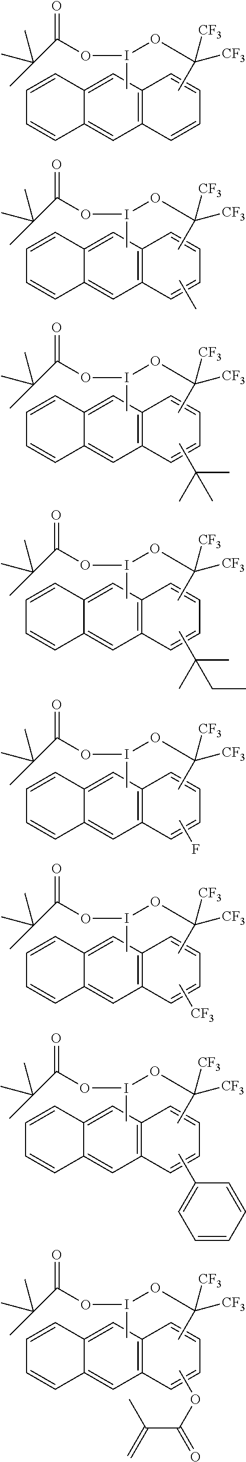

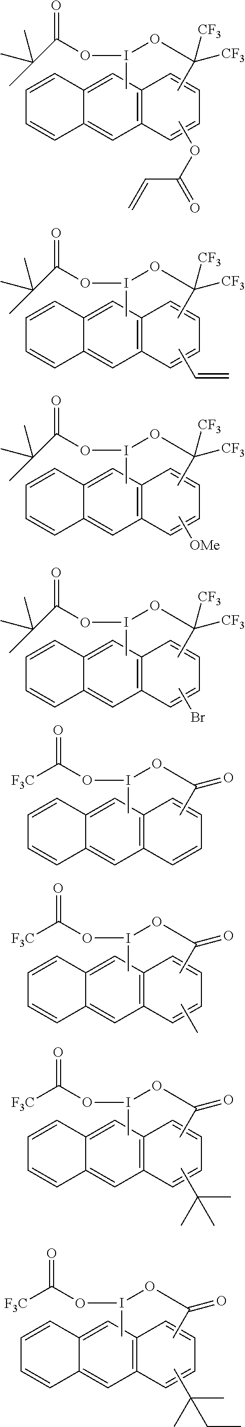

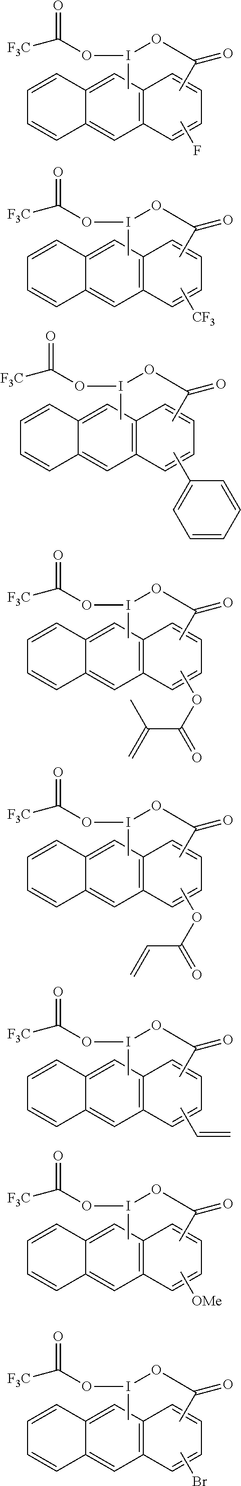

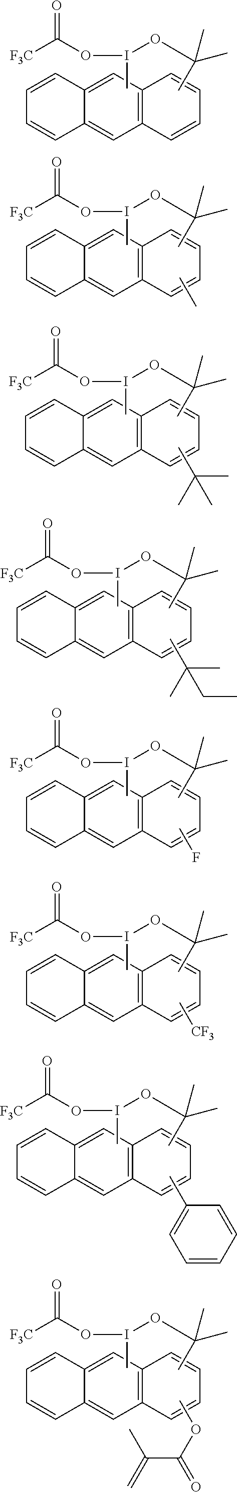

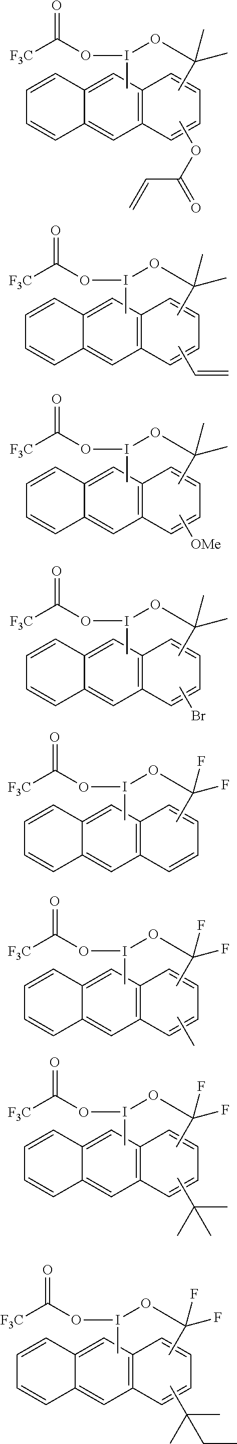

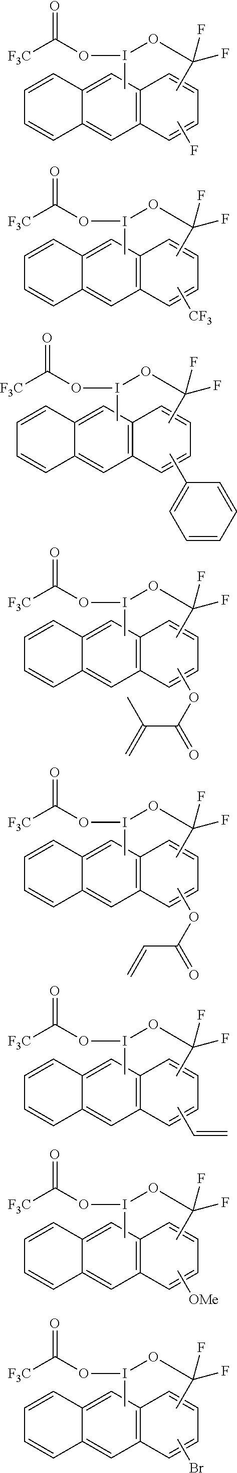

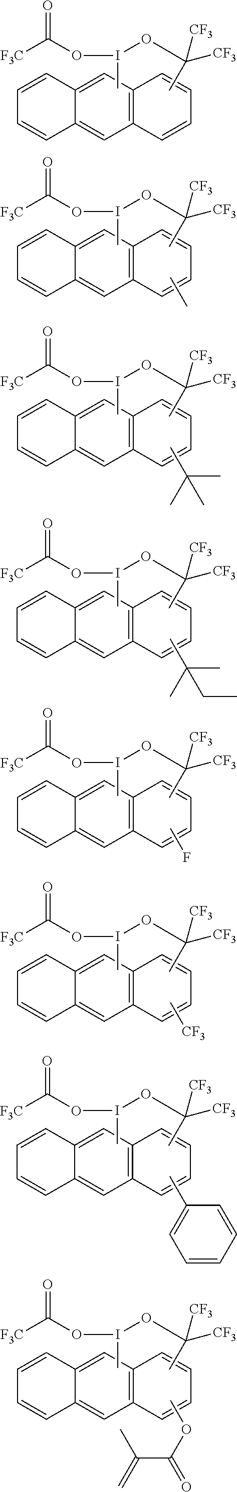

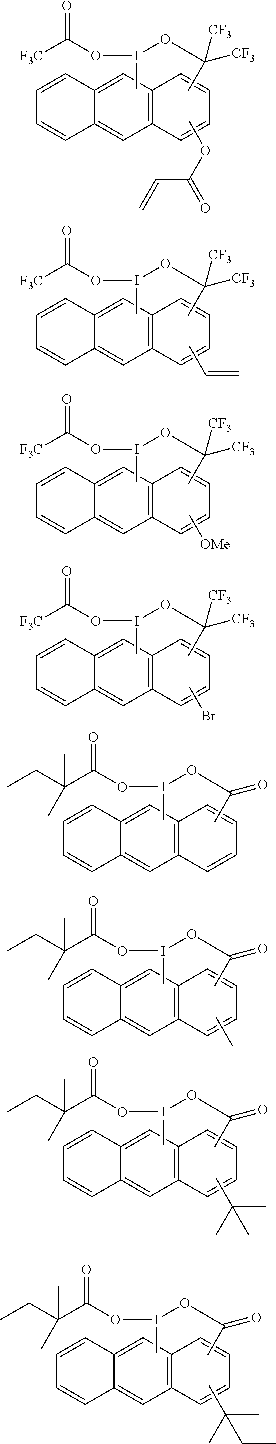

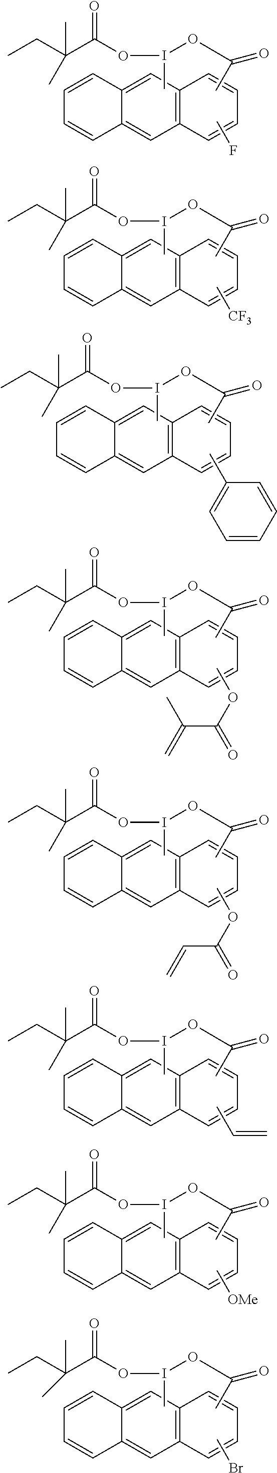

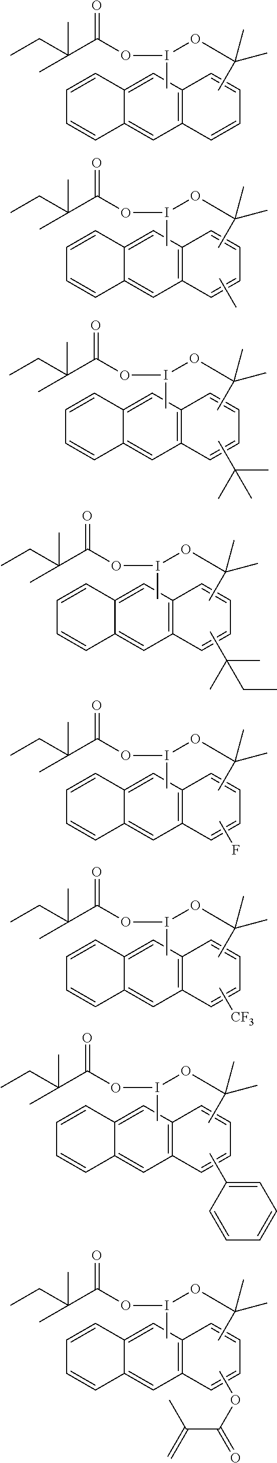

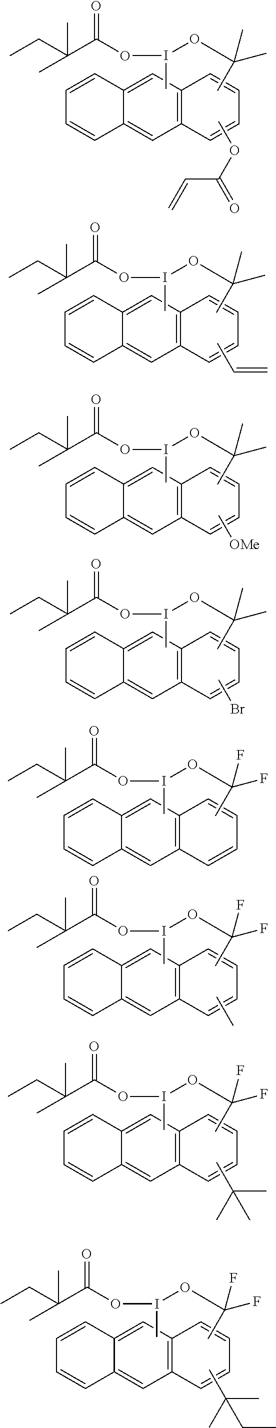

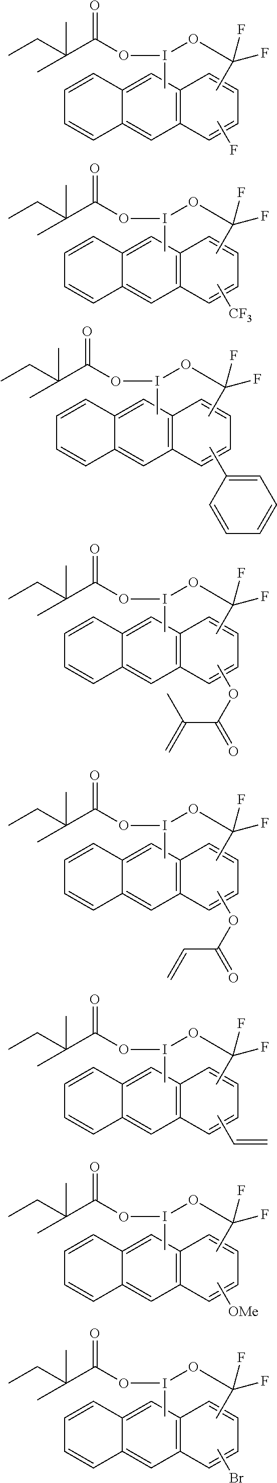

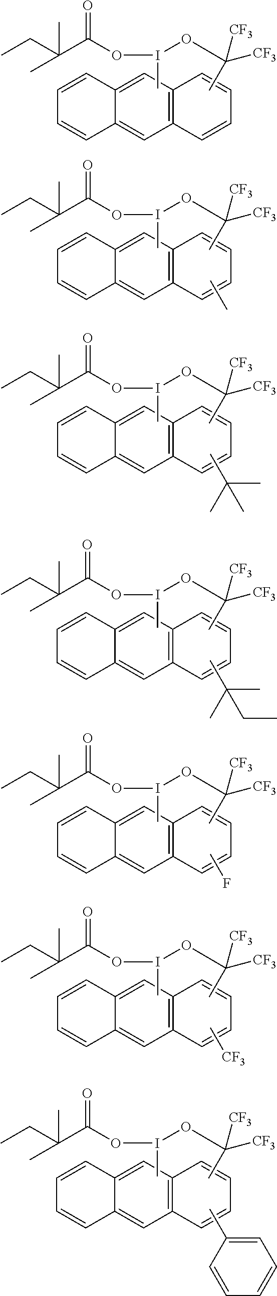

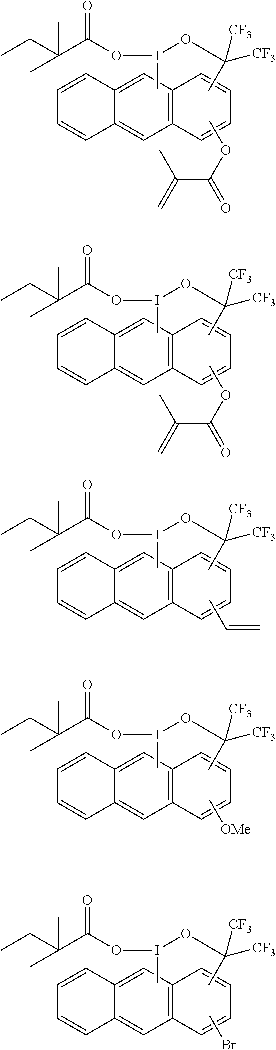

In the general formula (5), m2 is an integer of 0 to 2.
When m2 is 0, n2 is an integer of 1 to 3, n3 is an integer of 0 to 5, and 1≤(n2+n3)≤6 is satisfied.
When m2 is 1, n2 is an integer of 1 to 3, n3 is an integer of 0 to 7, and 1≤(n2+n3)≤8 is satisfied.
When m2 is 2, n2 is an integer of 1 to 3, n3 is an integer of 0 to 9, and 1≤(n2+n3)≤10 is satisfied.

In the general formula (5), R⁶¹ and R⁶² are each independently a halogen atom, or a hydrocarbyl group having 1 to 10 carbon atoms and optionally containing a heteroatom. In addition, R⁶¹ and R⁶² are optionally bound to each other to form a ring together with carbon atoms to which these are bound and an atom between the carbon atoms. Examples of the halogen atom include a fluorine atom, a chlorine atom, a bromine atom, and an iodine atom. The hydrocarbyl group having 1 to 10 carbon atoms may be saturated or unsaturated, and may be any of straight, branched or cyclic. Specific examples thereof include alkyl groups each having 1 to 10 carbon atoms, such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, tricyclo[5.2.1.0^{2,6}]decanyl group and an adamantyl group; alkenyl groups such as a vinyl group and an allyl group; aryl groups each having 6 to 10 carbon atoms, such as a phenyl group and a naphthyl group; and any group obtained by combination thereof. Some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained. R⁶¹ and R⁶² are each preferably a hydrocarbyl group having 1 to 4 carbon atoms.

In the general formula (5), R⁶³ is a halogen atom, or a hydrocarbyl group having 1 to 40 carbon atoms and optionally containing a heteroatom. Examples of the halogen atom include a fluorine atom, a chlorine atom, a bromine atom, and an iodine atom. The hydrocarbyl group having 1 to 40 carbon atoms may be saturated or unsaturated, and may be any of straight, branched or cyclic. Specific examples thereof include alkyl groups each having 1 to 40 carbon atoms, such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. Some or all of hydrogen atoms in the hydrocarbyl group are each optionally substituted by a group containing a heteroatom such as an oxygen atom, a sulfur atom, a nitrogen atom, or a halogen atom, some of —CH₂— in the hydrocarbyl group are each optionally substituted by a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained. When n3 is 2 to 9, R⁶³s are the same as or different from each other. In addition, plural R⁶³s are optionally bound to each other to form a ring together with carbon atoms in an aromatic ring to which these are bound.

Herein, R⁶³ can be a substituent at any position on the aromatic ring in the above formula.

Specific examples of the hypervalent iodine compound represented by the general formula (5) include the following, but not limited thereto.

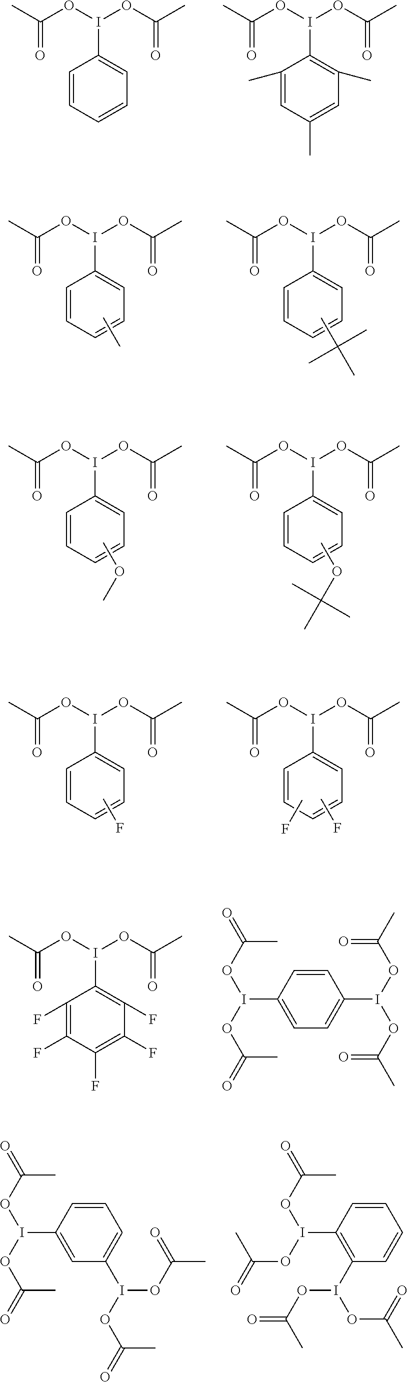

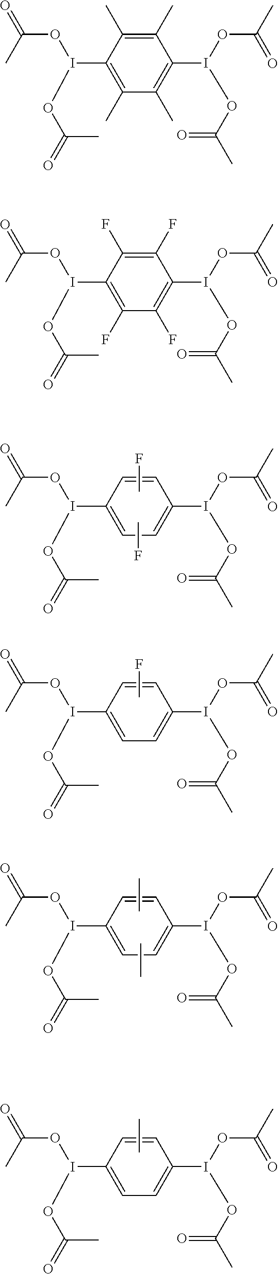

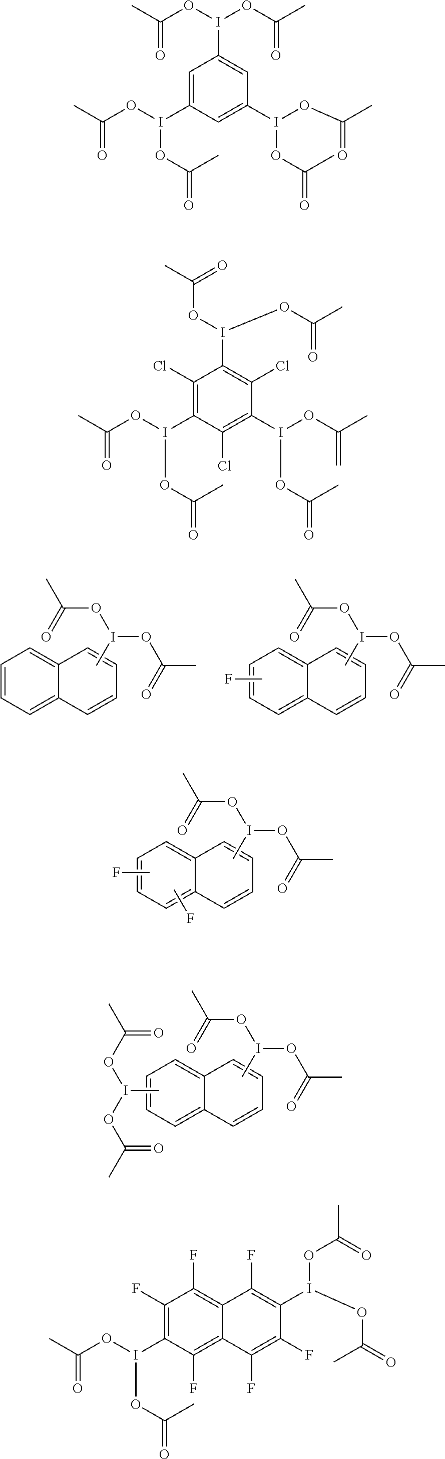

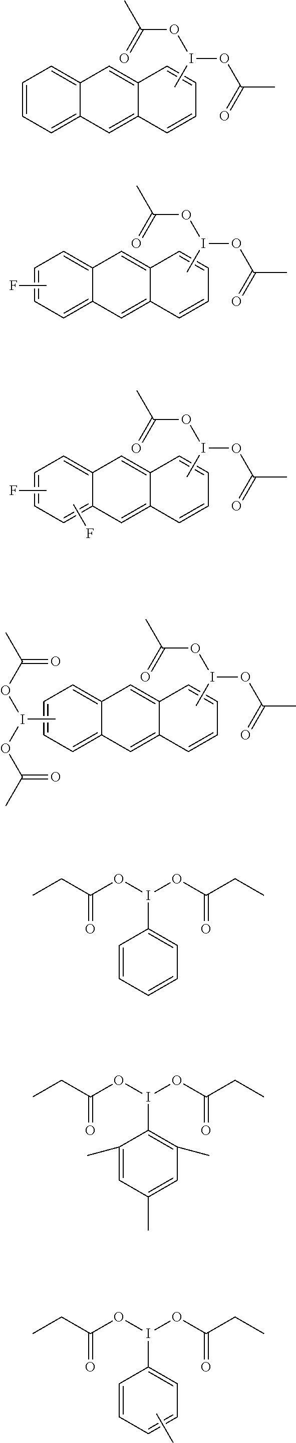

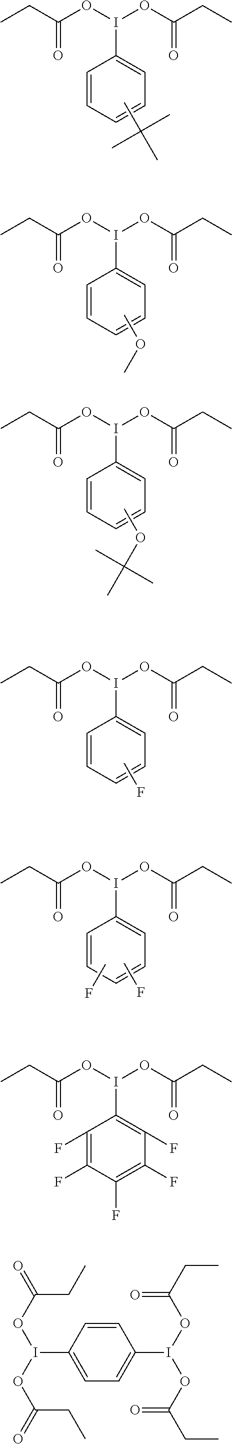

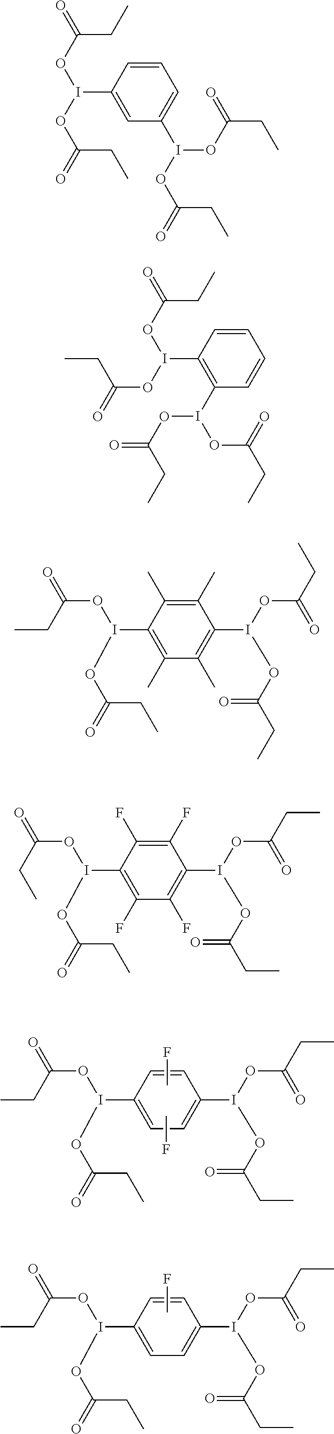

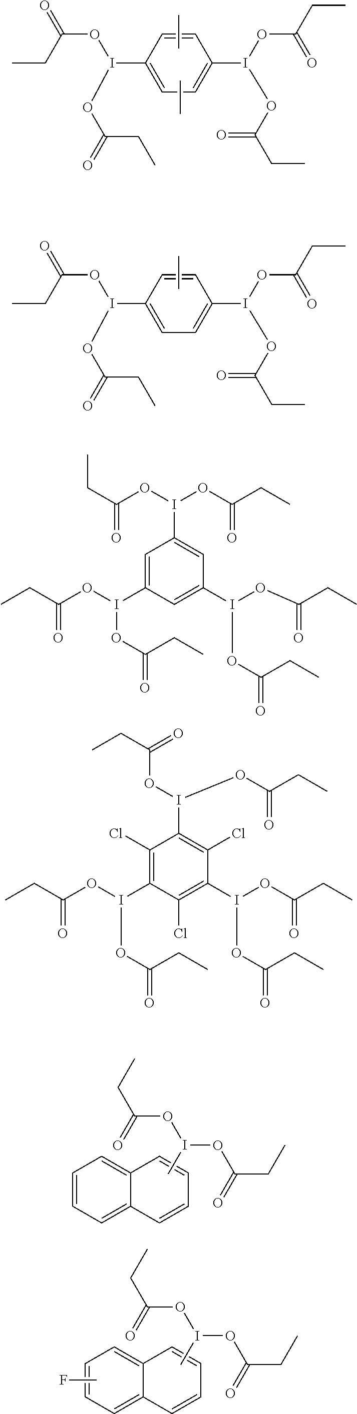

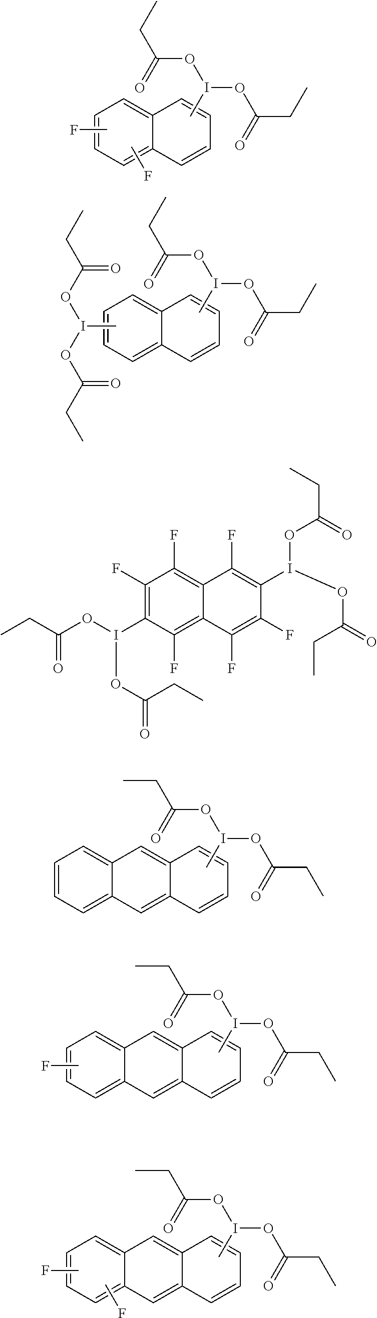

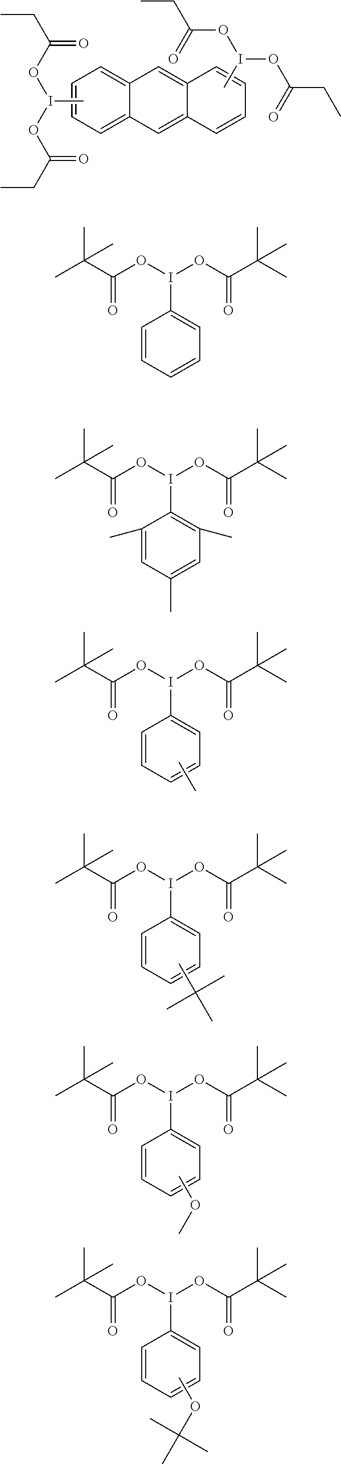

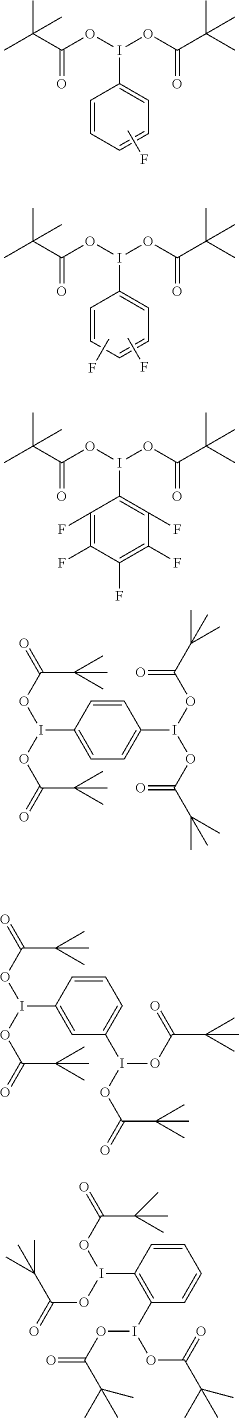

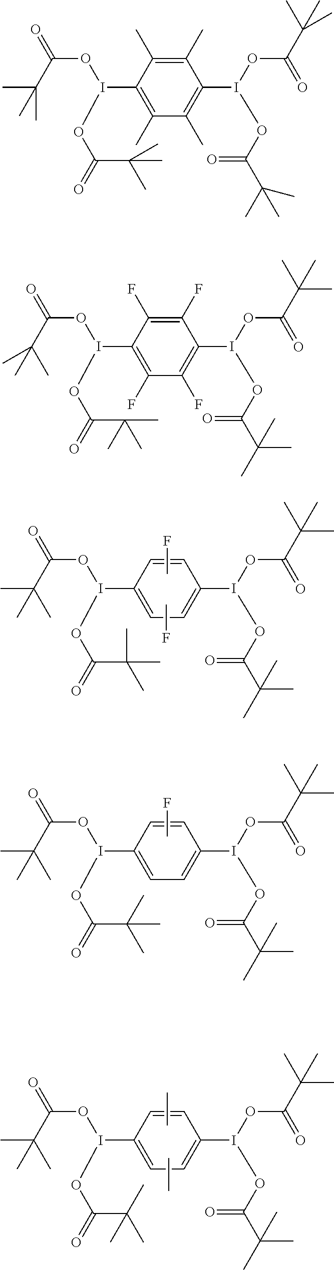

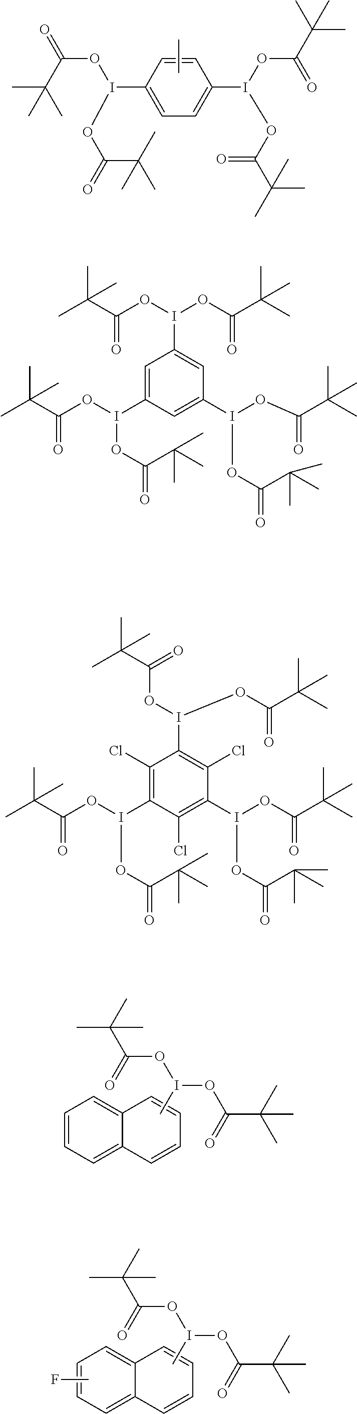

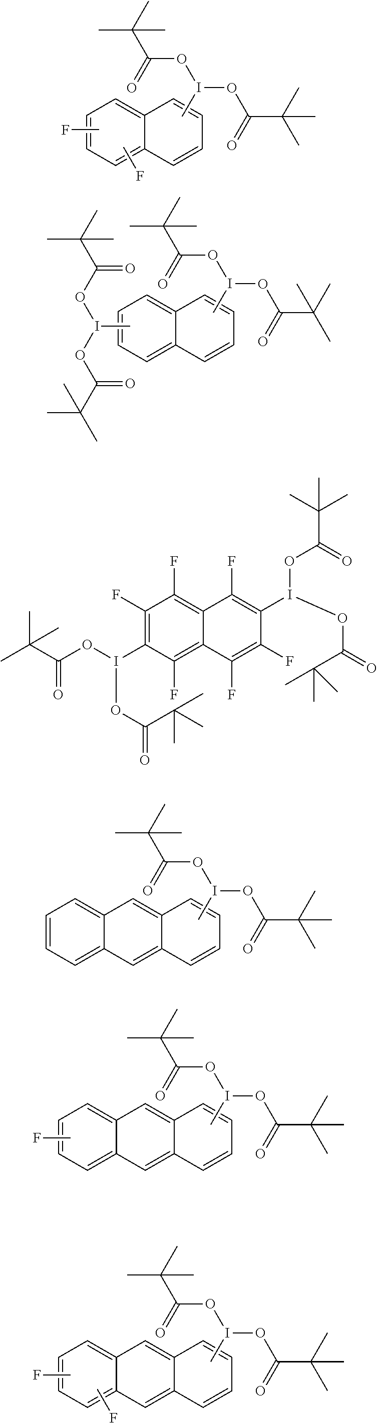

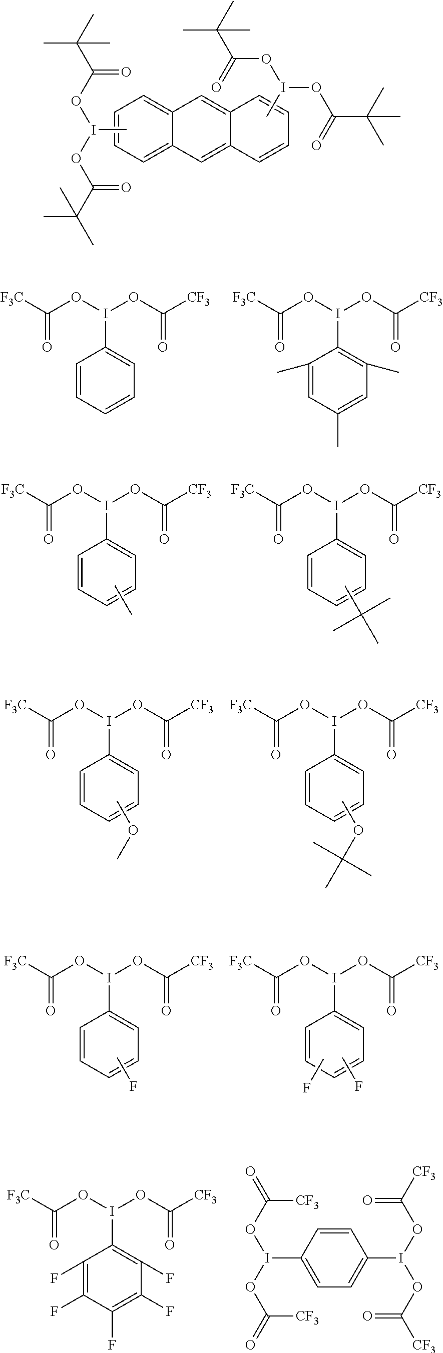

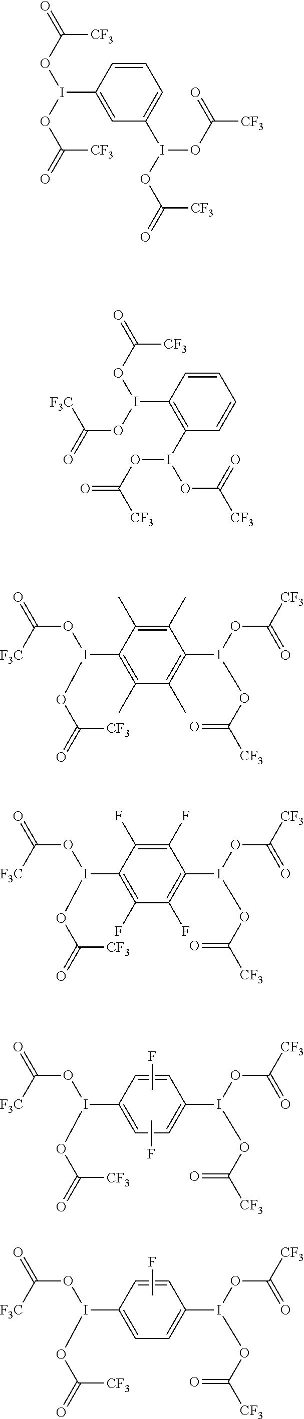

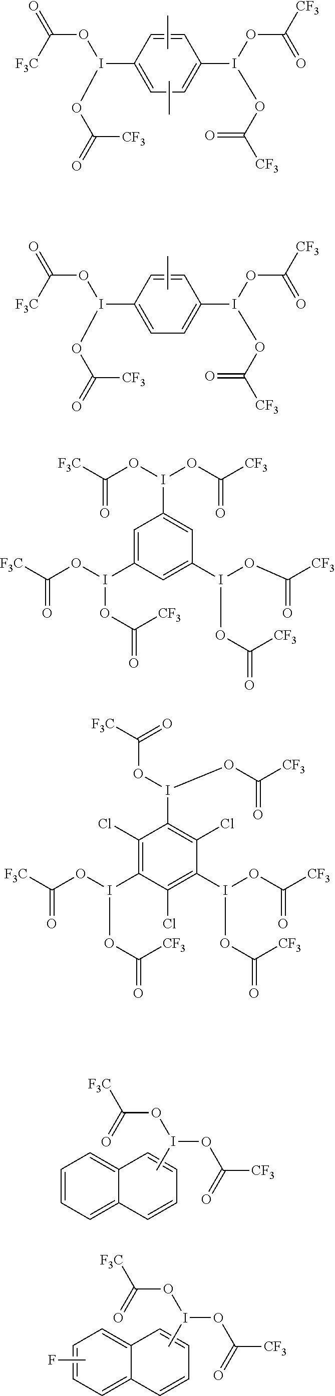

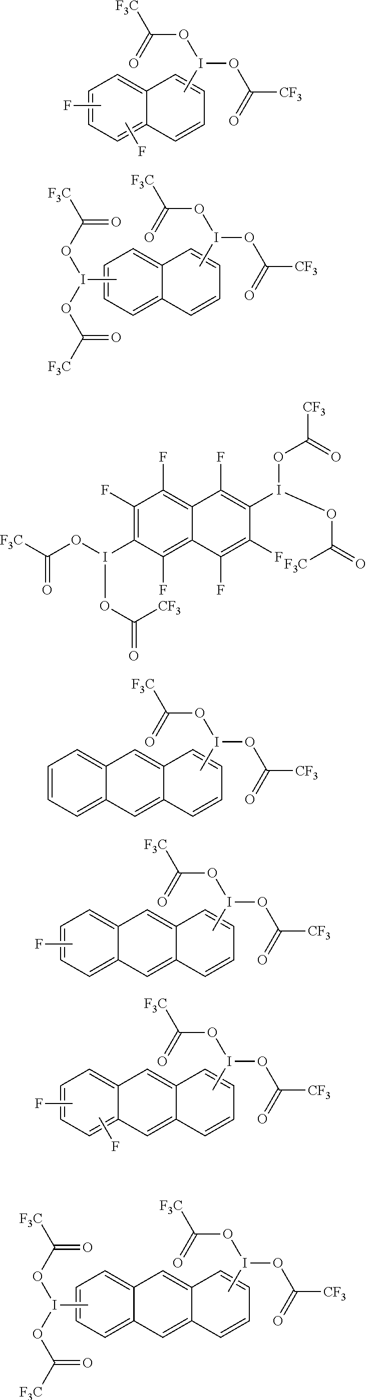

When the resist composition of the present invention contains any other hypervalent iodine compound, such any other hypervalent iodine compound used here may be only the hypervalent iodine compound represented by the general formula (4), may be only the hypervalent iodine compound represented by the general formula (5), or may be a combination of the hypervalent iodine compound represented by the general formula (4) and the hypervalent iodine compound represented by the general formula (5). In addition, the hypervalent iodine compound represented by the general formula (4) and the hypervalent iodine compound represented by the general formula (5) may be each used singly or in combinations of two or more different kinds thereof.

When the resist composition of the present invention contains such any other hypervalent iodine compound, the content ratio of the hypervalent iodine compound to the carboxy group-containing compound (when the carboxy group-containing compound is the carboxy group-containing polymer, the content ratio of the hypervalent iodine compound to a carboxylic acid-containing repeating unit in the polymer) is preferably 1:99 to 99:1, more preferably 10:90 to 90:10, further preferably 20:80 to 80:20 in terms of the molar ratio. In addition, such any other hypervalent iodine compound is preferably contained at a molar ratio of such any other hypervalent iodine compound to the hypervalent iodine compound represented by the formula (1), any other hypervalent iodine compound hypervalent iodine compound represented by formula (1), of 1:99 to 99:1, more preferably 1:99 to 50:50.

### [Solvent]

The resist composition of the present invention contains a solvent. The solvent is not particularly limited as long as it can dissolve the hypervalent iodine compound represented by the formula (1), the carboxy group-containing compound, such any other hypervalent iodine compound and any other component described below and thus can form a film. Such a solvent is preferably an organic solvent, and specific examples thereof include ketones such as cyclohexanone, methyl-2-n-pentyl ketone and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate and propylene glycol mono-tert-butyl ether acetate; carboxylic acids such as formic acid, acetic acid and propionic acid; lactones such as γ-butyrolactone; and any mixed solvent thereof.

The content of the solvent in the resist composition of the present invention is preferably an amount so that the solid content concentration in the resist composition is 0.1 to 20% by mass, more preferably an amount so that the concentration is 0.1 to 15% by mass, further preferably an amount so that the concentration is 0.1 to 10% by mass. In the present invention, the term of solid content refers to all components of the resist composition excluding the solvent. The solvent may be used singly or as a mixture of two or more kinds thereof.

The resist composition of the present invention may further contain a surfactant. The surfactant is preferably fluorine-based and/or silicone-based surfactant(s). Specific examples of such surfactant(s) include any surfactant described in paragraph [0276] in US 2008/0248425 A. Surfactants other than the fluorine-based and/or silicone-based surfactants described in paragraph [0280] in US 2008/0248425 A can also be further used.

When the resist composition of the present invention contains the above surfactant, the content is preferably 0.0001 to 2% by mass in the total solid content. The surfactant may be used singly or in combinations of two or more kinds thereof.

The resist composition of the present invention may further contain at least one selected from a radical scavenger and a crosslinking agent. An optical reaction in photolithography is thus controlled and the sensitivity can be adjusted.

Specific examples of the radical scavenger include hindered phenols, quinones, hindered amines, and a thiol compound. Specifically, specific examples of the hindered phenols include dibutylhydroxytoluene (BHT) and 2,2′-methylenebis(4-methyl-6-tert-butylphenol). Specific examples of the quinones include 4-methoxyphenol (metoquinone) and hydroquinone. Specific examples of the hindered amines include 2,2,6,6-tetramethylpiperidine and 2,2,6,6-tetramethylpiperidine-N-oxy radical. Specific examples of the thiols include dodecanethiol and hexadecanethiol.

When the resist composition of the present invention contains the radical scavenger, the content is preferably 0.01 to 10% by mass in the total solid content. The radical scavenger may be used singly or in combinations of two or more kinds thereof.

Specific examples of the crosslinking agent include a compound having a carbon-carbon unsaturated bond such as a vinyl group, a (meth)acrylate group, an allyl group, an alkynyl group, or an aromatic ring, as a functional group. Specifically, specific examples of the compound having a vinyl group include linear alkene, branched alkene, and cyclic alkene each optionally having a substituent. Specific examples of the compound having a (meth)acrylate group include acrylic acid, methacrylic acid, acrylic acid ester and methacrylic acid ester each optionally having a substituent. Specific examples of the compound having an allyl group include allyl alcohol, allyl ether, allyl ester, allylamide, allylamine and allyl group-containing isocyanurate each optionally having a substituent. Specific examples of the compound having an alkynyl group include linear alkyne, branched alkyne, cyclic alkyne, alkynyl alcohol, alkynyl ether, alkynyl ester, alkynylamide, alkynylamine and alkynyl group-containing isocyanurates each optionally having a substituent. Specific examples of the compound having an aromatic ring include arenes, heteroarenes, styrene, stilbene, phenylacetylene, acenaphthylene and chalcone each optionally having a substituent. The crosslinking agent may have only any one of the functional groups, or may have a plurality thereof. The number of the functional groups contained in the crosslinking agent is preferably 1 or more and 10 or less, more preferably 2 or more and 8 or less.

When the resist composition of the present invention contains the crosslinking agent, the content is preferably 0.01 to 50% by mass in the total solid content. The crosslinking agent may be used singly or in combinations of two or more kinds thereof.

The resist composition of the present invention contains the hypervalent iodine compound and the carboxy group-containing compound as main components as described above, but is not required to contain any acid-labile group-containing base polymer and photo-acid generator contained in a conventional chemically amplified resist composition. However, the resist composition of the present invention can form a positive type or negative type pattern by the difference in solubility generated between an exposed section and an unexposed section particularly by EB or EUV exposure. The mechanism, although not completely clear, is presumed as follows, for example.

A hypervalent iodine compound preferred in the present invention is a compound having a tricoordinate hypervalent iodine having a carboxylate ligand. It can be assumed that when such a tricoordinate iodine compound is mixed with a carboxy-group-containing compound, exchange with the carboxylate ligand occurs as an equilibrium reaction. In this event, if the original carboxylate ligand can be removed by some method, a hypervalent iodine compound having a new ligand is gen For example, if acetic acid having a low boiling point generated by mixing relatively easily available Dess-martin periodinane as the hypervalent iodine compound and a large-molecular weight carboxylic acid compound is removed, ligand exchange is completed. Here, a polymer in which the carboxy-group-containing compound is crosslinked with the hypervalent iodine compound is obtained.

The polymer crosslinked with the hypervalent iodine compound is generated during film formation. The reason is that such a crosslinked polymer, even if synthesized in advance, is not dissolved in many organic solvents and therefore a solution cannot be prepared. It is presumed that this is caused, because the hypervalent iodine compound which is originally polarized and therefore is low in solvent solubility much further deteriorates in solubility due to use of the carboxy group-containing compound as a ligand. It is here desirable to provide a step of removing the original low-molecular-weight carboxylic acid component in film formation and in a subsequent baking step, thereby not only completing a ligand exchange reaction, but also forming a resist film.

The resist film in the present invention thus formed on the substrate is changed in polarity due to decomposition of the hypervalent iodine compound as a main component by light, and a pattern is formed in a development step. Herein, a positive type or negative type pattern can be formed by appropriately selecting the developer.

The resist composition of the present invention can be a positive type or a negative type by selection of the components. In the case of a positive type, a polymer in which the hypervalent iodine compound is bound during film formation is contained. This compound is decomposed by light and formed into a monovalent iodine compound, and at the same time the binding between the carboxy group-containing compound and the hypervalent iodine compound is released and the molecular weight is also decreased. It is presumed that, as a result, a positive type pattern in which an exposed area is removed by an organic solvent is formed.

On the other hand, in the case of a negative type, a polymer crosslinked by the hypervalent iodine compound generated during film formation is contained. The polymer is decomposed by light, resulting in the occurrence of crosslinking or replacing of binding, and the occurrence of an increase in molecular weight and polarity conversion. It is presumed that, as a result, a negative type pattern in which an unexposed area is removed by an aqueous alkali solution is formed.

It can be said from the above presumptions that the resist composition of the present invention is a non-chemically amplified resist composition. The resist composition of the present invention does not require any acid-labile group-containing base polymer and photo-acid generator unlike a conventional chemically amplified resist composition, and therefore an adverse effect due to acid diffusion (for example, image blurs) is not caused and a fine pattern can be resolved.

The resist composition of the present invention is extremely effective particularly for EUV lithography. The reason for this is that the resist composition of the present invention is characterized in that the resist composition has an iodine atom having high ability to absorb EUV light and furthermore the hypervalent iodine compound represented by the formula (1) has a carboxylate ligand capable of resulting in the occurrence of the above ligand exchange, on one iodine atom, and thus crosslinking with the carboxy group-containing compound after film formation progresses at a higher density, to result in an increase in difference of the rate of dissolution between an unexposed area and an exposed area, namely, dissolution contrast as compared with the case of use of only any other hypervalent iodine compound. In other words, the resist composition of the present invention can achieve high sensitivity, high resolvability and low LWR by these characteristics.

Thus, when a non-chemically amplified resist containing an amide-type or thiocarbonyl-type hypervalent iodine compound and a carboxylic acid compound (carboxy group-containing compound) is used, the entire resist and a decomposed product after exposure are enhanced in solubility in the developer. Thus, patterning excellent in sensitivity and roughness resolvability is made possible.

As a resist composition for EUV lithography, capable of forming a fine pattern, a metal resist is proposed, which contains as a main component, a compound of tin as a metal having high ability to absorb EUV light as in an iodine atom (for example, Patent Document 2). However, as described above, such a metal resist has many problems, for example, insufficient solubility in a solvent, storage stability, and defects by the residue after etching due to inclusion of a metal element. In this regard, the resist composition of the present invention, in which no metal element is used, thus is more advantageous than a metal resist in terms of defects, and does not have the problem about solubility in a solvent. Furthermore, the resist composition of the present invention can be applied to any case of a positive type and a negative type, and therefore can be widely used in a variety of applications. For example, a metal resist adopted in negative type development in a contact hole forming step requires a reverse process step after pillar patterning, but such a reverse process step is not necessary about a positive type. Accordingly, it can be said that the resist composition of the present invention is more useful than a metal resist also from the viewpoint of process simplicity.

JP 2015-180928 A and JP 2018-95853 A describe a resist composition containing a hypervalent iodine compound as an additive, and a resist composition in which a hypervalent iodine compound is incorporated into a polymer skeleton of a base polymer. However, these Patent Documents merely describe the resist composition characterized by being able to be improved in line edge roughness, and mention neither the ability of such a hypervalent iodine compound to be photolytically degraded, nor the ability of such a hypervalent iodine compound to function as a material of a non-chemically amplified resist composition, at all. Furthermore, according to the description and specific examples of the amount of compounding, such a hypervalent iodine compound does not serve as a main component. In addition, Patent Document 3 proposes a positive type resist composition in which a hypervalent iodine compound is used, but does not describe the hypervalent iodine compound represented by the formula (1) in the present invention, and does not mention improvements in resolvability and LWR due to use of such a compound. Accordingly, it is considered that the non-chemically amplified resist composition of the present invention, having extremely high sensitivity, also exhibiting excellent resolving power, and being extremely effective for precise microfabrication, is not conceived from these Patent Documents. In other words, the present invention can be clearly said to provide novel resist composition and patterning process.

### [Laminate]

The present invention provides a laminate including a substrate, and a resist film formed on the substrate. The resist film is a film made of the resist composition. Such a laminate including a resist film obtained from the non-chemically amplified resist composition of the present invention can be widely used in a variety of applications and is extremely highly useful for resist process techniques because a resist film which is a film made of the resist composition not only has extremely high sensitivity and furthermore exhibits excellent limit resolvability and is extremely effective for precise microfabrication, but also can be applied to both of positive type patterning and negative type patterning.

In this case, a resist underlayer film can also be, if necessary, further provided between the substrate and the resist film.

In addition, the resist film in the laminate of the present invention preferably contains a product of a ligand exchange reaction between the hypervalent iodine compound and a carboxy group-containing compound. In other words, the laminate is obtained from a substrate and a resist film obtained from the resist composition of the present invention formed on the substrate, and the resist film is preferably formed by ligand exchange between the hypervalent iodine compound and a carboxy group-containing compound.

As described above, a low-molecular-weight carboxylic acid as a by-product in film formation and in a subsequent baking step, is removed to allow a ligand exchange reaction of the hypervalent iodine compound with the carboxy group-containing compound to progress, thereby forming a resist film containing a product of the ligand exchange reaction (namely, provide a formed film). Ligand exchange is completed, and thus a polymer is provided in which the carboxy group-containing compound is crosslinked by the hypervalent iodine compound. It is preferable to thus complete a ligand exchange reaction and also form a resist film.

### [Patterning Process]

In a case where the resist composition of the present invention is used for manufacturing various integrated circuits, known lithography techniques can be applied. Examples of the patterning process include a method including the steps of forming a resist film on a substrate or a resist underlayer film on a substrate on which the resist underlayer film is laminated, with the resist composition; exposing the resist film to a high energy line; and developing the exposed resist film with a developer. Hereinafter, the resist underlayer film is also simply referred to as “underlayer film”.

First, the resist composition of the present invention is applied to a substrate for integrated circuit manufacturing, an underlayer film of a substrate (Si, SiO₂, SiN, SiON, TiN, WSi, BPSG, SOG, an organic anti-reflection film, or the like) on which the underlayer film is laminated, a substrate for mask circuit manufacturing, or an underlayer film of a substrate (Cr, CrO, CrON, MoSi₂, SiO₂, or the like) on which the underlayer film is laminated, by an appropriate application process such as spin coating, roll coating, flow coating, dip coating, spray coating, or doctor coating so that the film thickness by application is 0.01 to 2 μm. The resultant is pre-baked on a hot plate at preferably 60 to 200° C. for 10 seconds to 30 minutes, more preferably 80 to 180° C. for 30 seconds to 20 minutes, thereby forming a resist film. Herein, the underlayer film means a film formed between a substrate and a resist film in a multilayer resist process, and the underlayer film is not particularly limited and conventionally known one can be used.

Next, the resist film is exposed with a high energy line. Examples of the high energy line include ultraviolet rays (g-line (436 nm), h-line (405 nm), i-line (365 nm), and the like), far-ultraviolet rays, EB, EUV, X-rays, soft X-rays, excimer laser light (KrF excimer laser light, ArF excimer laser light, and the like), γ-rays, and synchrotron radiations. The high energy line used here is preferably an i-line, a KrF excimer laser, an ArF excimer laser, an electron beam or an extreme-ultraviolet ray. In a case where an ultraviolet ray, a far-ultraviolet ray, EUV, an X-ray, a soft X-ray, excimer laser light, a γ-ray, a synchrotron radiation or the like is used as the high energy line, irradiation is performed directly or with a mask for formation of an objective pattern so that the amount of exposure is preferably about 1 to 300 mJ/cm², more preferably about 10 to 200 mJ/cm². When EB is used as the high energy line, lithography is performed directly or with a mask for formation of an objective pattern so that the amount of exposure is preferably about 0.1 to 2000 μC/cm², more preferably about 0.5 to 1500 μC/cm². The resist composition of the present invention is suitable particularly for fine patterning with EB or EUV among high energy lines.

After exposure, PEB is, if necessary, performed. It is here preferable to perform PEB on a hot plate or in an oven in conditions of 30 to 150° C. for 10 seconds to 30 minutes, more preferably of 60 to 120° C. for 30 seconds to 20 minutes, after exposure.

After exposure or after PEB, patterning is performed, if necessary, by development with a developer. Examples of the developer used here include aqueous alkali solution such as an aqueous tetramethylammonium hydroxide solution; and organic solvents such as 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, isoamyl alcohol, n-butanol, n-pentanol, cyclohexanol, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxy propionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 1-propanol, 3-methoxybutanol, 3-methyl-3-methoxybutanol, 1-methoxy-2-propanol, 1-ethoxy-2-propanol, diacetone alcohol and 4-methyl-2-pentanol. Such a developer may be used singly or as a mixture of two or more kinds thereof.

After development, rinse is, if necessary, performed. A rinse liquid is preferably a solvent which dissolve the developer when mixed with a developer and not to dissolve the resist film. As suqch a solvent, an alcohol having 3 to 10 carbon atoms, an ether compound having 8 to 12 carbon atoms, or an alkane, alkene, alkyne or aromatic solvent having 6 to 12 carbon atoms is preferably used. Alternatively, water may be used as the rinse liquid instead of the organic solvent.

Such rinse can be performed to reduce the occurrence of collapse and/or defects of a resist pattern. Such rinse is not necessarily essential, and the amount of a solvent used can be reduced by not performing such rinse.

The resist composition of the present invention can form a positive type or negative type pattern by the difference in solubility generated between an exposed section and an unexposed section by exposure as described above. Therefore, a developer that dissolves an exposed area and that does not dissolve an unexposed area or a developer that dissolves an unexposed area and that does not dissolve an exposed area can be used as the developer. Thus, the patterning process of the present invention can form a positive type or negative type pattern by appropriately selecting the developer, and therefore can be widely applied to various kinds of fine patterning.

### EXAMPLES

Hereinafter, the present invention is specifically described with reference to Synthesis Examples, Examples and Comparative Examples, but the present invention is not limited to the following Examples.

### [1] Preparation of Hypervalent Iodine Compound

The hypervalent iodine compounds used in Examples are represented by the following formulae (I-1) to (I-2).

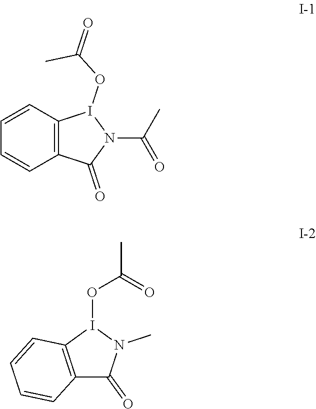 [SMILES: CC(=O)OI1c2ccccc2C(=O)N1C(C)=O ; CC(=O)OI1c2ccccc2C(=O)N1C]

I-1 and I-2 were each synthesized as follows.

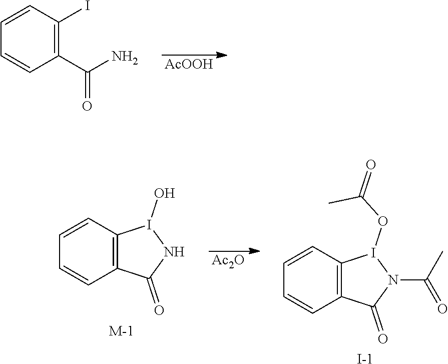

### [Synthesis Example 1-1] Synthesis of I-1

2-Iodobenzamide (5 g, 20 mmol) was added to 20 mL of 2.0 M peracetic acid, and stirred at 40° C. for 5 hours. The temperature was returned to room temperature, 100 mL of isopropyl ether (IPE) was added, and a solid was separated by filtration. The resulting solid was dried at 40° C. for 2 hours, thereby obtaining M-1 (4.2 g, yield percentage 78%). A nuclear magnetic resonance spectrum of M-1 obtained is as follows.

¹H NMR: (500 MHz, DMSO-d₆) δ 7.29 (m, 1H), 7.38 (d, J=8.3 Hz, 1H), 7.42 (m, 1H), 7.49 (br, 1H), 7.76 (br, 1H), 7.81 (m, 1H) ppm.

M-1 (4.2 g, 16 mmol) was dispersed in acetic anhydride (20 mL), and stirred at 140° C. for 5 hours. The temperature was returned to room temperature, 100 mL of IPE was added, and a solid was separated by filtration. The resulting solid was dried at 40° C. for 2 hours, thereby obtaining I-1 (3.9 g, yield percentage 70%). A nuclear magnetic resonance spectrum and a mass spectrometric spectrum of I-1 obtained are as follows.

¹H NMR: (500 MHz, CDCl₃) δ 1.94 (s, 3H), 2.34 (s, 3H), 7.74 (m, 1H), 7.81 (m, 1H), 8.10 (m, 1H), 8.23 (m, 1H) ppm.

Single quadrupole mass spectrometry (ESI): POSITIVE M⁺H⁺ 347.9 (corresponding to C₁₁H₁₁INO₄)

### [Synthesis Example 1-2] Synthesis of I-2

I-2 was also synthesized by the same method as in I-1. A nuclear magnetic resonance spectrum and a mass spectrometric spectrum of I-2 obtained are as follows.

¹H NMR: (500 MHz, CDCl₃) δ 2.18 (s, 3H), 3.24 (s, 3H), 7.68 (t, J=7.5 Hz, 1H), 7.80 (m, 1H), 8.10-8.22 (m, 2H) ppm.

Single quadrupole mass spectrometry (ESI): POSITIVE M⁺H⁺ 319.9 (corresponding to C₁₀H₁₁INO₃)

### [2] Synthesis of Polymer

Monomers used for polymer synthesis are as follows.

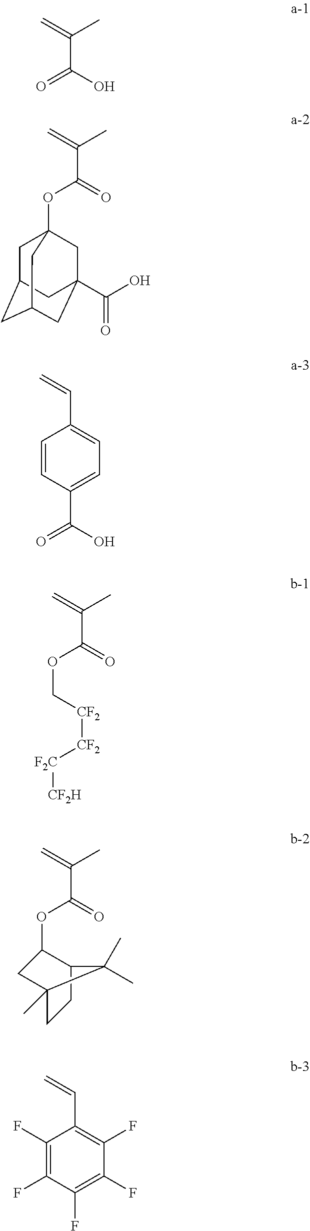

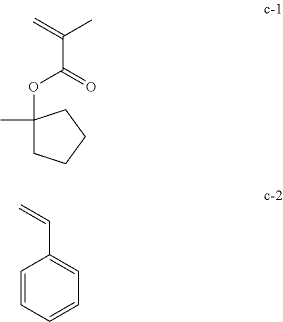

### [Synthesis Example 2-1] Synthesis of Polymer P-1

Under a nitrogen atmosphere, monomer a-1 (56 g), monomer b-1 (105 g), 5.4 g of V-601 (manufactured by FUJIFILM Wako Pure Chemical Corporation) and 180 g of MEK were taken in a flask, to prepare a monomer-polymerization initiator solution. After 55 g of MEK was taken in another flask whose atmosphere was a nitrogen atmosphere, and heated to 80° C. with stirring, the monomer-polymerization initiator solution was dropped over 4 hours. After the completion of dropping, the polymerization liquid was continuously stirred for 2 hours with the temperature thereof being kept at 80° C., and then cooled to room temperature. The resulting polymerization liquid was dropped to 4000 g of hexane vigorously stirred, and a polymer precipitated was separated by filtration. Furthermore, the resulting polymer was washed with hexane 1200 g twice, and thereafter dried in vacuum at 50° C. for 20 hours, thereby obtaining polymer P-1 as a white powder (yield: 155 g, yield percentage: 96%). The Mw and the Mw/Mn of polymer P-1 were respectively 7700 and 1.82. Herein, the Mw and Mn are values measured in terms of polystyrene by GPC with THF as a solvent. Specifically, measurement was performed in the following conditions (the same applied to the following).
Apparatus: HLC-8320GPC
Columns: TSK guardcolumn
   TSKgel G4000HXL
   TSKgel G2000HXL
   TSKgel superH5000
Pump, column constant temperature: 40° C.
Eluent: THF
Detector: RI (differential refractive) detector
Amount of injection: 100 μl

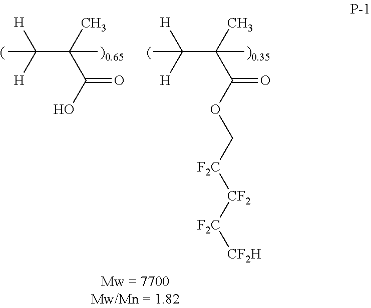

### [Synthesis Examples 2-2 to 2-10] Synthesis of Polymers P-2 to P-10

Each polymer shown in Table 1 was synthesized by the same process as in Synthesis Example 2-1 except that the types of monomers and the compounding ratio thereof were changed. Herein, polymer P-10 is a polymer having no carboxy group (—COOH), and does not correspond to the carboxy group-containing compound in the present invention.

TABLE 1

| | | | Introduction | | Introduction | | |
|---|---|---|---|---|---|---|---|
| | | | ratio | | ratio | | |
| | Polymer | Unit 1 | (% by mol) | Unit 2 | (% by mol) | Mw | Mw/Mn |
| Synthesis | P-1 | a-1 | 65 | b-1 | 35 | 7700 | 1.82 |
| Example 1 | | | | | | | |
| Synthesis | P-2 | a-1 | 50 | b-2 | 50 | 8400 | 1.84 |
| Example 2 | | | | | | | |
| Synthesis | P-3 | a-1 | 60 | b-3 | 40 | 8100 | 1.79 |
| Example 3 | | | | | | | |
| Synthesis | P-4 | a-2 | 65 | b-1 | 35 | 8300 | 1.83 |
| Example 4 | | | | | | | |
| Synthesis | P-5 | a-2 | 50 | b-2 | 50 | 8300 | 1.83 |
| Example 5 | | | | | | | |
| Synthesis | P-6 | a-2 | 60 | b-3 | 40 | 8200 | 1.82 |
| Example 6 | | | | | | | |
| Synthesis | P-7 | a-3 | 65 | b-1 | 35 | 8000 | 1.80 |
| Example 7 | | | | | | | |
| Synthesis | P-8 | a-3 | 50 | b-2 | 50 | 8600 | 1.84 |
| Example 8 | | | | | | | |
| Synthesis | P-9 | a-3 | 60 | b-3 | 40 | 7900 | 1.81 |
| Example 9 | | | | | | | |
| Synthesis | P-10 | c-1 | 60 | c-2 | 40 | 9800 | 1.82 |
| Example 10 | | | | | | | |

### [3] Preparation of Resist Composition

### Examples 1-1 to 1-22 and Comparative Examples 1-1 to 1-4

Resist compositions (R-01 to R-22) and comparative resist compositions (CR-01 to CR-02) were each prepared by dissolving the hypervalent iodine compound, any other hypervalent iodine compound and the polymer in a solvent containing a 0.01% by mass of surfactant (PF-636, manufactured by OMNOVA Solutions Inc.) at a compositional ratio shown in Table 2 below, and filtrating the resulting solution with a 0.2-μm Teflon (registered trademark) filter. Comparative resist compositions (CR-03 to CR-04) were each prepared by dissolving a polymer, a photo-acid generator and a sensitivity modifier in a solvent containing a 0.01% by mass surfactant (PF-636, manufactured by OMNOVA Solutions Inc.) at a compositional ratio shown in Table 3, and filtrating the resulting solution with a 0.2-μm Teflon (registered trademark) filter.

TABLE 2

| | | | | Other | | Carboxy | | | | | |
|---|---|---|---|---|---|---|---|---|---|---|---|
| | | Hypervalent | | hypervalent | | group- | | | | | |
| | | iodine | | iodine | | containing | | | | | |
| | Resist | compound | | compound | | compound | | Solvent 1 | | Solvent 2 | |
| | composition | (parts by mass) | | (parts by mass) | | (parts by mass) | | (parts by mass) | | (parts by mass) | |
| Example 1-1 | R-01 | I-1 | (10) | — | | P-1 | (17.4) | PGMEA | (800) | AcOH | (200) |
| Example 1-2 | R-02 | I-2 | (10) | — | | P-1 | (13.5) | PGMEA | (800) | AcOH | (200) |
| Example 1-3 | R-03 | I-1 | (10) | — | | P-2 | (21.9) | PGMEA | (800) | AcOH | (200) |
| Example 1-4 | R-04 | I-1 | (10) | — | | P-3 | (15.2) | PGMEA | (800) | AcOH | (200) |
| Example 1-5 | R-05 | I-1 | (10) | — | | P-4 | (24.3) | PGMEA | (800) | AcOH | (200) |
| Example 1-6 | R-06 | I-1 | (10) | — | | P-5 | (34.5) | PGMEA | (800) | AcOH | (200) |
| Example 1-7 | R-07 | I-1 | (10) | — | | P-6 | (27.9) | PGMEA | (800) | AcOH | (200) |
| Example 1-8 | R-08 | I-1 | (10) | — | | P-7 | (21.8) | PGMEA | (800) | AcOH | (200) |
| Example 1-9 | R-09 | I-1 | (10) | — | | P-8 | (26.4) | PGMEA | (800) | AcOH | (200) |
| Example 1-10 | R-10 | I-1 | (10) | — | | P-9 | (19.8) | PGMEA | (800) | AcOH | (200) |
| Example 1-11 | R-11 | I-1 | (10) | — | | P-1 | (17.6) | HBM | (800) | AcOH | (200) |
| Example 1-12 | R-12 | I-1 | (10) | — | | P-1 | (17.4) | PGMEA | (800) | PA | (200) |
| Example 1-13 | R-13 | I-1 | (5) | — | | P-1 | (17.6) | PGMEA | (800) | AcOH | (200) |
| Example 1-14 | R-14 | I-1 | (5) | O-1 | (2.5) | P-1 | (17.5) | PGMEA | (800) | AcOH | (200) |

| Example 1-15 | R-15 | I-1 (5) | | — | P-1 | (17.5) | PGMEA | (800) | AcOH | (200) |
|---|---|---|---|---|---|---|---|---|---|---|
| | | I-2 (5) | | | | | | | | |
| Example 1-16 | R-16 | I-1 | (10) | — | m-1 | (8.4) | PGMEA | (800) | AcOH | (200) |
| Example 1-17 | R-17 | I-1 | (10) | — | m-2 | (4.1) | PGMEA | (800) | AcOH | (200) |
| Example 1-18 | R-18 | I-1 | (10) | — | m-3 | (8.4) | PGMEA | (800) | AcOH | (200) |
| Example 1-19 | R-19 | I-1 | (10) | — | m-4 | (7.7) | PGMEA | (800) | AcOH | (200) |
| Example 1-20 | R-20 | I-1 | (10) | — | m-5 | (11.7) | PGMEA | (800) | AcOH | (200) |
| Example 1-21 | R-21 | I-1 | (10) | — | m-6 | (8.9) | PGMEA | (800) | AcOH | (200) |
| Example 1-22 | R-22 | I-2 | (10) | — | m-6 | (6.8) | PGMEA | (800) | AcOH | (200) |

| | | | | | | | | | | |
|---|---|---|---|---|---|---|---|---|---|---|
| Comparative | CR-01 | — | O-1 | (10) | P-1 | (15) | PGMEA | (800) | AcOH | (200) |
| Example 1-1 | | | | | | | | | | |
| Comparative | CR-02 | — | O-1 | (10) | m-1 | (7.5) | PGMEA | (800) | AcOH | (200) |
| Example 1-2 | | | | | | | | | | |

TABLE 3

| | | | Photo-acid | Sensitivity | | |
|---|---|---|---|---|---|---|
| | Resist | Polymer | generator | modifier | Solvent 1 | Solvent 2 |
| | composition | (parts by mass) | (parts by mass) | (parts by mass) | (parts by mass) | (parts by mass) |
| Comparative | CR-03 | P-10(80) | PAG-1(19) | Q-1(6) | PGMEA(1890) | GBL(210) |
| Example 1-3 | | | | | | |
| Comparative | CR-04 | P-10(80) | PAG-1(19) | I-1(5) | PGMEA(1890) | GBL(210) |
| Example 1-4 | | | | | | |

In Tables 2 and 3, other hypervalent iodine compounds O-1, carboxy group-containing compounds m-1 to m-6, photo-acid generators PAG-1, sensitivity modifiers Q-1 and solvents are as follows.

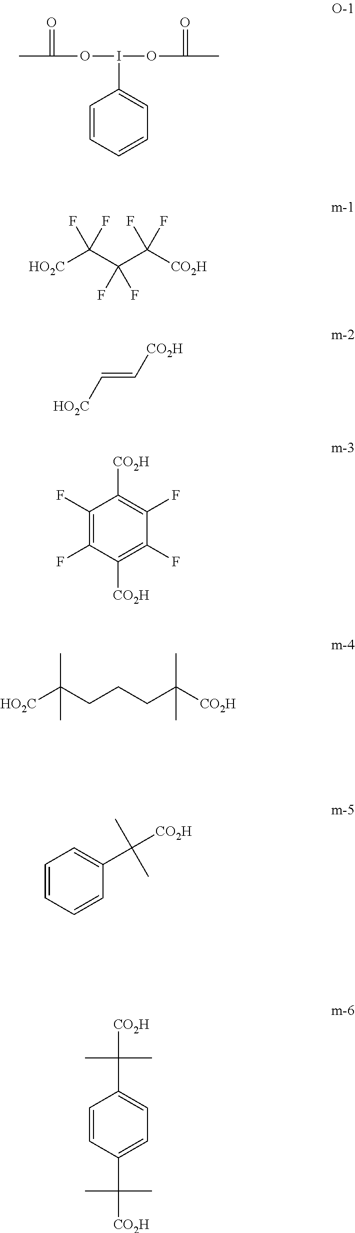

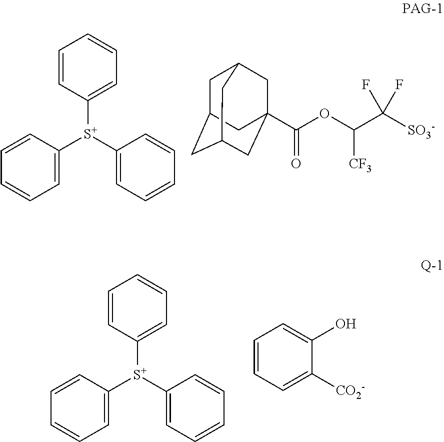

Solvents: PGMEA (propylene glycol monomethyl ether acetate)
   AcOH (acetic acid)
   HBM (methyl 2-hydroxyisobutyrate)
   PA (propionic acid)
   GBL (γ-butyrolactone)

### [4] EUV Lithography Evaluation (Line-and-Space Pattern and Positive Tone Development)

### Examples 2-1 to 2-22 and Comparative Examples 2-1 to 2-4

Each resist composition (R-01 to R-22 and CR-01 to CR-04) was applied to a Si substrate on which a silicon-containing Spin-on hard mask SHB-A940 (silicon content 43% by mass) manufactured by Shin-Etsu Chemical Co., Ltd. was formed at a thickness of 20 nm, by spin-coating, and subjected to post apply bake (PAB) with a hot plate at a temperature shown in Table 4 for 60 seconds, thereby producing a resist film having a thickness of 40 nm. A 36 nm line-and-space (LS) (1:1) pattern was exposed with an EUV scanner NXE3400 manufactured by ASML Holding N.V. (NA 0.33, σ 0.9, 900 dipole illumination), and thereafter PEB on a hot plate at a temperature shown in Table 4 for 60 seconds and then development with a developer shown in Table 4 for 30 seconds were performed, thereby forming an LS pattern having a space width of 18 nm and a pitch of 36 nm.

The resist pattern obtained was evaluated as follows. The results are shown in Table 4.

### [Evaluation of Sensitivity]

The LS pattern was observed with a length measurement SEM (CG-6300) manufactured by Hitachi High-Tech Corporation, the optimal amount of exposure Eop (mJ/cm²), in which an LS pattern having a space width of 18 nm and a pitch of 36 nm was obtained, was determined, and this amount was defined as sensitivity.

### [Evaluation of LWR]

The dimensions at 10 positions in the longitudinal direction of the space width of the LS pattern obtained by irradiation in the optimal amount of exposure were measured with a length measurement SEM (CG-6300) manufactured by Hitachi High-Tech Corporation, and a value three times (3a) the standard deviation (a) was determined as LWR, from the above results. As this value is smaller, a pattern small in roughness and uniform in space width is obtained.

### [Evaluation of Limit Resolvability]

The line width (nm) at a limit of resolving during formation of a pattern with an increase in amount of exposure little by little from the optimal amount of exposure in which the LS pattern was formed was determined with a length measurement SEM (CG-6300) manufactured by Hitachi High-Tech Corporation, and this line width was defined as the limit resolution (nm). It is indicated that, as this value is smaller, a finer pattern having excellent limit resolvability can be formed.

TABLE 4

| | | | | | | Limit |
|---|---|---|---|---|---|---|
| | Resist | PAB/PEB | | Eop | LWR | resolution |
| | composition | (° C.) | Developer | (mJ/cm²) | (nm) | (nm) |
| Example 2-1 | R-01 | 130/90 | nBA | 28 | 2.6 | 9 |
| Example 2-2 | R-02 | 130/90 | nBA | 29 | 3.1 | 9 |
| Example 2-3 | R-03 | 130/90 | nBA | 27 | 3.0 | 10 |
| Example 2-4 | R-04 | 130/90 | nBA | 26 | 2.6 | 9 |
| Example 2-5 | R-05 | 130/90 | nBA | 33 | 2.4 | 10 |
| Example 2-6 | R-06 | 130/90 | nBA | 33 | 2.7 | 11 |
| Example 2-7 | R-07 | 130/90 | nBA | 32 | 2.8 | 12 |
| Example 2-8 | R-08 | 130/90 | nBA | 33 | 2.6 | 12 |
| Example 2-9 | R-09 | 130/90 | nBA | 27 | 2.4 | 11 |
| Example 2-10 | R-10 | 130/90 | nBA | 29 | 2.8 | 9 |
| Example 2-11 | R-11 | 130/90 | nBA | 25 | 2.3 | 11 |
| Example 2-12 | R-12 | 130/90 | nBA | 24 | 2.3 | 10 |
| Example 2-13 | R-13 | 130/90 | CHA | 24 | 2.2 | 8 |
| Example 2-14 | R-14 | 130/90 | nBA | 23 | 2.3 | 9 |
| Example 2-15 | R-15 | 130/90 | nBA | 26 | 2.4 | 10 |
| Example 2-16 | R-16 | 130/90 | nBA | 29 | 2.7 | 9 |
| Example 2-17 | R-17 | 130/90 | nBA | 26 | 2.6 | 10 |
| Example 2-18 | R-18 | 130/90 | nBA | 30 | 2.8 | 10 |
| Example 2-19 | R-19 | 130/90 | nBA | 26 | 2.6 | 11 |
| Example 2-20 | R-20 | 130/90 | nBA | 26 | 2.5 | 9 |
| Example 2-21 | R-21 | 130/90 | nBA | 25 | 2.9 | 9 |
| Example 2-22 | R-22 | 130/90 | nBA | 27 | 2.2 | 11 |
| Comparative | CR-01 | 130/90 | nBA | 41 | 3.8 | 15 |
| Example 2-1 | | | | | | |
| Comparative | CR-02 | 130/90 | nBA | 39 | 4.3 | 18 |
| Example 2-2 | | | | | | |
| Comparative | CR-03 | 105/90 | TMAH | 85 | 4.6 | 19 |
| Example 2-3 | | | | | | |
| Comparative | CR-04 | 105/90 | TMAH | 85 | 4.8 | 18 |
| Example 2-4 | | | | | | |

Developers: nBA (butyl acetate)
   CHA (cyclohexyl acetate)
   TMAH (aqueous 2.38% by mass tetramethyl ammonium hydroxide solution)

### [5] EUV Lithography Evaluation (Line-and-Space Pattern and Negative Tone Development)

### Examples 3-1 to 3-22 and Comparative Examples 3-1 to 3-4

Each resist composition (R-1 to R-22 and CR-01 to CR-04) was applied to a Si substrate on which a silicon-containing Spin-on hard mask SHB-A940 (silicon content 43% by mass) manufactured by Shin-Etsu Chemical Co., Ltd. was formed at a thickness of 20 nm, by spin-coating, and subjected to post apply bake (PAB) with a hot plate at a temperature shown in Table 5 for 60 seconds, thereby producing a resist film having a thickness of 40 nm. The resist film was subjected to exposure of a 36 nm line-and-space (LS) (1:1) pattern with an EUV scanner NXE3400 manufactured by ASML Holding N.V. (NA 0.33, a 0.9, 900 dipole illumination), and thereafter bake (PEB) on a hot plate at a temperature shown in Table 5 for 60 seconds and then development with a developer shown in Table 5 for 30 seconds, thereby forming an LS pattern having a space width of 18 nm and a pitch of 36 nm.

The resist pattern obtained was evaluated as follows. The results are shown in Table 5.

### [Evaluation of Sensitivity]

The LS pattern was observed with a length measurement SEM (CG-6300) manufactured by Hitachi High-Tech Corporation, the optimum amount of exposure Eop (mJ/cm²), in which an LS pattern having a space width of 18 nm and a pitch of 36 nm, was determined, and this amount was defined as sensitivity.

### [Evaluation of LWR]

The dimensions at 10 positions in the longitudinal direction of the space width of the LS pattern obtained by irradiation in the optimal amount of exposure were measured with a length measurement SEM (CG-6300) manufactured by Hitachi High-Tech Corporation, and a value three times (3σ) the standard deviation (σ) was determined as LWR, from the above results. As this value is smaller, a pattern small in roughness and uniform in space width is obtained.

### [Evaluation of Limit Resolvability]

The line width (nm) at a limit of resolving during formation of a pattern with an increase in amount of exposure little by little from the optimal amount of exposure in which the LS pattern was formed was determined with a length measurement SEM (CG-6300) manufactured by Hitachi High-Tech Corporation, and this line width was defined as the limit resolution (nm). It is indicated that, as this value is smaller, a finer pattern having excellent limit resolvability can be formed.

TABLE 5

| | | | | | | Limit |
|---|---|---|---|---|---|---|
| | Resist | PAB/PEB | | Eop | LWR | resolution |
| | composition | (° C.) | Developer | (mJ/cm²) | (nm) | (nm) |
| Example 3-1 | R-01 | 130/90 | TMAH | 28 | 2.9 | 9 |
| Example 3-2 | R-02 | 130/90 | TMAH | 29 | 3.1 | 10 |
| Example 3-3 | R-03 | 130/90 | TMAH | 32 | 3.5 | 11 |
| Example 3-4 | R-04 | 130/90 | TMAH | 32 | 3.2 | 9 |
| Example 3-5 | R-05 | 130/90 | TMAH | 31 | 2.8 | 9 |
| Example 3-6 | R-06 | 130/90 | TMAH | 34 | 3.2 | 13 |
| Example 3-7 | R-07 | 130/90 | TMAH | 32 | 3.2 | 12 |
| Example 3-8 | R-08 | 130/90 | TMAH | 34 | 3.5 | 13 |
| Example 3-9 | R-09 | 130/90 | TMAH | 29 | 3.0 | 11 |
| Example 3-10 | R-10 | 130/90 | TMAH | 28 | 3.0 | 10 |
| Example 3-11 | R-11 | 130/90 | TMAH | 29 | 2.9 | 14 |
| Example 3-12 | R-12 | 130/90 | TMAH | 29 | 3.2 | 11 |
| Example 3-13 | R-13 | 130/90 | TMAH | 22 | 2.9 | 10 |
| Example 3-14 | R-14 | 130/90 | TMAH | 26 | 2.8 | 9 |
| Example 3-15 | R-15 | 130/90 | TMAH | 30 | 2.9 | 12 |
| Example 3-16 | R-16 | 130/90 | TMAH | 31 | 3.3 | 11 |
| Example 3-17 | R-17 | 130/90 | TMAH | 26 | 3.0 | 10 |
| Example 3-18 | R-18 | 130/90 | TMAH | 31 | 3.3 | 11 |
| Example 3-19 | R-19 | 130/90 | TMAH | 28 | 3.1 | 12 |
| Example 3-20 | R-20 | 130/90 | TMAH | 26 | 3.0 | 10 |
| Example 3-21 | R-21 | 130/90 | TMAH | 27 | 3.4 | 10 |
| Example 3-22 | R-22 | 130/90 | TMAH | 29 | 2.7 | 11 |
| Comparative | CR-01 | 130/90 | TMAH | 42 | 4.2 | 16 |
| Example 3-1 | | | | | | |
| Comparative | CR-02 | 130/90 | TMAH | 41 | 4.3 | 18 |
| Example 3-2 | | | | | | |
| Comparative | CR-03 | 105/90 | nBA | 83 | 4.6 | 18 |
| Example 3-3 | | | | | | |
| Comparative | CR-04 | 105/90 | nBA | 86 | 4.9 | 18 |
| Example 3-4 | | | | | | |

It has been found from the results shown in Table 4 and Table 5 that the resist composition of the present invention is excellent in sensitivity, LWR and resolvability in each of a positive tone and a negative tone in line-and-space patterning by EUV exposure.

### [6] EUV Lithography Evaluation (Contact Hole Pattern)

### Examples 4-1 to 4-22 and Comparative Examples 4-1 to 4-4

Each resist composition (R-01 to R-22 and CR-01 to CR-04) was applied to a Si substrate on which a silicon-containing Spin-on hard mask SHB-A940 (silicon content 43% by mass) manufactured by Shin-Etsu Chemical Co., Ltd. was formed at a thickness of 20 nm, by spin-coating, and subjected to post apply bake (PAB) with a hot plate at a temperature shown in Table 6 for 60 seconds, thereby producing a resist film having a thickness of 50 nm. Next, the resist film was exposed with an EUV scanner NXE3400 manufactured by ASML Holding N.V. (NA 0.33, a 0.9/0.6, quadrupole illumination, mask of a hole pattern with a pitch of 64 nm and a bias of +20% as dimensions on a wafer), subjected to bake (PEB) on a hot plate at a temperature shown in Table 6 for 60 seconds, and developed with a developer shown in Table 6 for 30 seconds, then a hole pattern having a dimension of 32 nm was obtained.

The resist pattern obtained was evaluated as follows. The results are shown in Table 6.

### [Evaluation of Sensitivity]

The contact hole pattern was observed with a length measurement SEM (CG-6300) manufactured by Hitachi High-Tech Corporation, the optimal amount of exposure Eop (mJ/cm²), in which a hole pattern having a dimension of 32 nm was obtained, was determined.

### [Evaluation of CD Uniformity (CDU)]

The dimensions at 50 positions of the hole pattern obtained by irradiation in the optimal amount of exposure were measured, and a value three times (3σ) the standard deviation (σ) calculated from the above results was defined as CDU. As this value is smaller, a pattern uniform in hole diameter is obtained.

### [Evaluation of Limit Resolvability]

The hole diameter (nm) at a limit of resolving during formation of a hole pattern with a decrease in amount of exposure little by little from the optimal amount of exposure in which the hole pattern was formed was determined with a length measurement SEM (CG-6300) manufactured by Hitachi High-Tech Corporation, and this hole diameter was defined as the limit resolution (nm). It is indicated that, as this value is smaller, a pattern having excellent limit resolvability and a finer hole diameter can be formed.

TABLE 6

| | | | | | | Limit |
|---|---|---|---|---|---|---|
| | Resist | PAB/PEB | | Eop | CDU | resolution |
| | composition | (° C.) | Developer | (mJ/cm²) | (nm) | (nm) |
| Example 4-1 | R-01 | 130/90 | nBA | 15 | 1.9 | 18 |
| Example 4-2 | R-02 | 130/90 | nBA | 17 | 2.2 | 19 |
| Example 4-3 | R-03 | 130/90 | nBA | 19 | 2.3 | 21 |
| Example 4-4 | R-04 | 130/90 | nBA | 20 | 2.3 | 19 |
| Example 4-5 | R-05 | 130/90 | nBA | 23 | 2.1 | 20 |
| Example 4-6 | R-06 | 130/90 | nBA | 20 | 2.1 | 20 |
| Example 4-7 | R-07 | 130/90 | nBA | 20 | 2.2 | 21 |
| Example 4-8 | R-08 | 130/90 | nBA | 22 | 2.1 | 22 |
| Example 4-9 | R-09 | 130/90 | nBA | 19 | 1.9 | 20 |
| Example 4-10 | R-10 | 130/90 | nBA | 19 | 2.0 | 19 |
| Example 4-11 | R-11 | 130/90 | nBA | 16 | 1.9 | 22 |
| Example 4-12 | R-12 | 130/90 | nBA | 15 | 1.9 | 19 |
| Example 4-13 | R-13 | 130/90 | CHA | 12 | 1.7 | 18 |
| Example 4-14 | R-14 | 130/90 | nBA | 16 | 1.7 | 17 |
| Example 4-15 | R-15 | 130/90 | nBA | 16 | 1.6 | 17 |
| Example 4-16 | R-16 | 130/90 | nBA | 18 | 2.2 | 19 |
| Example 4-17 | R-17 | 130/90 | nBA | 15 | 2.1 | 20 |
| Example 4-18 | R-18 | 130/90 | nBA | 18 | 2.1 | 18 |
| Example 4-19 | R-19 | 130/90 | nBA | 16 | 2.1 | 21 |
| Example 4-20 | R-20 | 130/90 | nBA | 16 | 2.0 | 19 |
| Example 4-21 | R-21 | 130/90 | nBA | 15 | 2.1 | 19 |
| Example 4-22 | R-22 | 130/90 | nBA | 17 | 1.7 | 21 |
| Comparative | CR-01 | 130/90 | nBA | 26 | 2.8 | 29 |
| Example 4-1 | | | | | | |
| Comparative | CR-02 | 130/90 | nBA | 27 | 2.8 | 28 |
| Example 4-2 | | | | | | |
| Comparative | CR-03 | 105/90 | TMAH | 41 | 3.9 | 35 |
| Example 4-3 | | | | | | |
| Comparative | CR-04 | 105/90 | TMAH | 39 | 4.0 | 31 |
| Example 4-4 | | | | | | |

It has been found from the results shown in Table 6 that the resist composition of the present invention is excellent in sensitivity, CDU and resolvability in contact hole patterning by EUV exposure.

The present description includes the following embodiments.

[1]: A resist composition comprising a hypervalent iodine compound represented by the following formula (1), a carboxy group-containing compound, and a solvent:

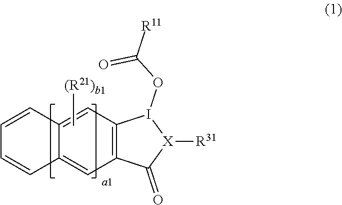

wherein a1 is 0, 1 or 2; when a1 is 0, b1 is 0, 1, 2, 3 or 4; when a1 is 1, b1 is 0, 1, 2, 3, 4, 5 or 6; when a1 is 2, b1 is 0, 1, 2, 3, 4, 5, 6, 7 or 8; R¹¹ is each independently a halogen atom, or a hydrocarbyl group having 1 to 10 carbon atoms and optionally containing a heteroatom; R²¹ is each independently a halogen atom, or a hydrocarbyl group having 1 to 40 carbon atoms and optionally containing a heteroatom; when b1 is 2 or more, R²¹s are the same as or different from each other, and plural R²¹s are optionally bound to each other to form a ring together with carbon atoms in an aromatic ring to which these are bound; “X” is a nitrogen atom or a sulfur atom, and optionally has R³¹ in the case of being a nitrogen atom; and R³¹ is a hydrogen atom, a halogen atom, or a hydrocarbyl group having 1 to 20 carbon atoms and optionally containing a heteroatom.

[2]: The resist composition according to [1], wherein the carboxy group-containing compound corresponds to one or both of a polymer containing a repeating unit represented by the following formula (2) and a compound represented by the following formula (3):

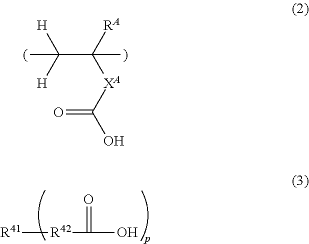

wherein R^{A} is a hydrogen atom, a halogen atom, a methyl group or a trifluoromethyl group; X^{A} is a single bond, a phenylene group, a naphthylene group, or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; * represents a point of attachment to a carbon atom in a backbone; “p” is 1, 2, 3 or 4; R⁴¹ is a p-valent hydrocarbon group having 1 to 40 carbon atoms or a p-valent heterocyclic group having 2 to 40 carbon atoms, and when “p” is 2, R⁴¹ is optionally an ether bond, a carbonyl group, an azo group, a thioether bond, a carbonate bond, a carbamate bond, a sulfinyl group or a sulfonyl group; some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; R⁴² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when “p” is 2, 3 or 4, R⁴²s are the same as or different from each other.

[3]: The resist composition according to [1] or [2] further comprising at least one of a hypervalent iodine compound represented by the following formula (4) or (5):

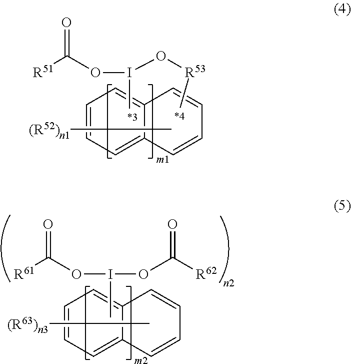

wherein m1 and m2 are each an integer of 0 to 2, and n1 is an integer of 0 to 4 when m1 is 0, n1 is an integer of 0 to 6 when m1 is 1, and n1 is an integer of 0 to 8 when m1 is 2; when m2 is 0, n2 is an integer of 1 to 3, n3 is an integer of 0 to 5, and 1≤(n2+n3)≤6 is satisfied; when m2 is 1, n2 is an integer of 1 to 3, n3 is an integer of 0 to 7, and 1≤(n2+n3)≤8 is satisfied; when m2 is 2, n2 is an integer of 1 to 3, n3 is an integer of 0 to 9, and 1≤(n2+n3)≤10 is satisfied; R⁵¹ is a halogen atom, or a hydrocarbyl group having 1 to 10 carbon atoms and optionally containing a heteroatom; R⁵² is a halogen atom, or a hydrocarbyl group having 1 to 40 carbon atoms and optionally containing a heteroatom; when n1 is 2 to 8, R⁵²s are the same as or different from each other, and plural R⁵²s are optionally bound to each other to form a ring together with carbon atoms in an aromatic ring to which these are bound; R⁵³ is a hydrocarbylene group having 1 to 10 carbon atoms and optionally containing a heteroatom; *3 and *4 each represent a point of attachment to a carbon atom in an aromatic ring in the formula, provided that *3 and *4 are bound to adjacent carbon atoms in an aromatic ring; R⁶¹ and R⁶² are each independently a halogen atom, or a hydrocarbyl group having 1 to 10 carbon atoms and optionally containing a heteroatom, and R⁶¹ and R⁶² are optionally bound to each other to form a ring together with carbon atoms to which these are bound and an atom between the carbon atoms; when n2 is 2 to 3, R⁶¹s and R⁶²s are the same as or different from each other; R⁶³ is a halogen atom, or a hydrocarbyl group having 1 to 40 carbon atoms and optionally containing a heteroatom; and when n3 is 2 to 9, R⁶³s are the same as or different from each other, and plural R⁶³s are optionally bound to each other to form a ring together with carbon atoms in an aromatic ring to which these are bound.

[4]: A laminate comprising a substrate, and a resist film formed on the substrate, the resist film being a film made of the resist composition according to any one of [1] to [3].

[5]: The laminate according to [4], further comprising a resist underlayer film between the substrate and the resist film.

[6]: The laminate according to [4] or [5], wherein the resist film contains a product of a ligand exchange reaction between the hypervalent iodine compound and a carboxy group-containing compound.

[7]: A patterning process comprising the steps of: forming a resist film on a substrate or a resist underlayer film on a substrate on which the resist underlayer film is laminated, with the resist composition according to any one of [1] to [3]; exposing the resist film to a high energy line, and developing the exposed resist film with a developer.

[8]: The patterning process according to [7], wherein an i-line, a KrF excimer laser, an ArF excimer laser, an electron beam or an extreme-ultraviolet ray is used as the high energy line.

[9]: The patterning process according to [7] or [8], wherein a developer that dissolves an exposed area and that does not dissolve an unexposed area is used as the developer.

[10]: The patterning process according to [7] or [8], wherein a developer that dissolves an unexposed area and that does not dissolve an exposed area is used as the developer.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A resist composition comprising a hypervalent iodine compound represented by the following formula (1), a carboxy group-containing compound, and a solvent: 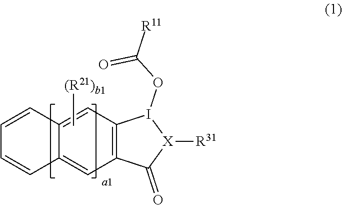
wherein a1 is 0, 1 or 2; when a1 is 0, b1 is 0, 1, 2, 3 or 4; when a1 is 1, b1 is 0, 1, 2, 3, 4, 5 or 6; when a1 is 2, b1 is 0, 1, 2, 3, 4, 5, 6, 7 or 8; R¹¹ is each independently a halogen atom, or a hydrocarbyl group having 1 to 10 carbon atoms and optionally containing a heteroatom; R²¹ is each independently a halogen atom, or a hydrocarbyl group having 1 to 40 carbon atoms and optionally containing a heteroatom; when b1 is 2 or more, R²¹s are the same as or different from each other, and plural R²¹s are optionally bound to each other to form a ring together with carbon atoms in an aromatic ring to which these are bound; “X” is a nitrogen atom or a sulfur atom, and optionally has R³¹ in the case of being a nitrogen atom; and R³¹ is a hydrogen atom, a halogen atom, or a hydrocarbyl group having 1 to 20 carbon atoms and optionally containing a heteroatom.

2. The resist composition according to claim 1, wherein the carboxy group-containing compound corresponds to one or both of a polymer containing a repeating unit represented by the following formula (2) and a compound represented by the following formula (3): 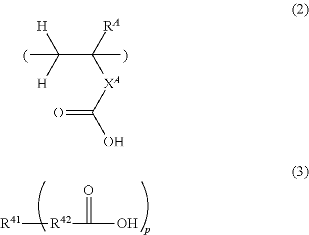
wherein R^{A} is a hydrogen atom, a halogen atom, a methyl group or a trifluoromethyl group; X^{A} is a single bond, a phenylene group, a naphthylene group, or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; * represents a point of attachment to a carbon atom in a backbone; “p” is 1, 2, 3 or 4; R⁴¹ is a p-valent hydrocarbon group having 1 to 40 carbon atoms or a p-valent heterocyclic group having 2 to 40 carbon atoms, and when “p” is 2, R⁴¹ is optionally an ether bond, a carbonyl group, an azo group, a thioether bond, a carbonate bond, a carbamate bond, a sulfinyl group or a sulfonyl group; some or all of hydrogen atoms in the p-valent hydrocarbon group or the p-valent heterocyclic group are each optionally substituted by a group containing a heteroatom, and some of —CH₂— in the p-valent hydrocarbon group are each optionally substituted by a group containing a heteroatom; R⁴² is a single bond or a hydrocarbylene group having 1 to 10 carbon atoms, some or all of hydrogen atoms in the hydrocarbylene group are each optionally substituted by a group containing a heteroatom, and some of —CH₂— in the hydrocarbylene group are each optionally substituted by a group containing a heteroatom; and when “p” is 2, 3 or 4, R⁴²s are the same as or different from each other.

3. The resist composition according to claim 1, further comprising at least one of a hypervalent iodine compound represented by the following formula (4) or (5): 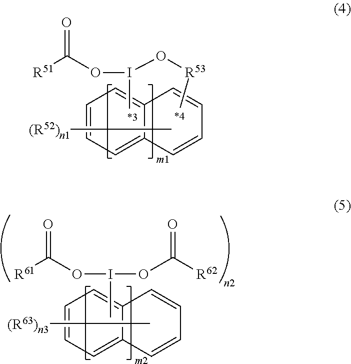
wherein m1 and m2 are each an integer of 0 to 2, and n1 is an integer of 0 to 4 when m1 is 0, n1 is an integer of 0 to 6 when m1 is 1, and n1 is an integer of 0 to 8 when m1 is 2; when m2 is 0, n2 is an integer of 1 to 3, n3 is an integer of 0 to 5, and 1≤(n2+n3)≤6 is satisfied; when m2 is 1, n2 is an integer of 1 to 3, n3 is an integer of 0 to 7, and 1≤(n2+n3)≤8 is satisfied; when m2 is 2, n2 is an integer of 1 to 3, n3 is an integer of 0 to 9, and 1≤(n2+n3)≤10 is satisfied; R⁵¹ is a halogen atom, or a hydrocarbyl group having 1 to 10 carbon atoms and optionally containing a heteroatom; R⁵² is a halogen atom, or a hydrocarbyl group having 1 to 40 carbon atoms and optionally containing a heteroatom; when n1 is 2 to 8, R⁵²s are the same as or different from each other, and plural R⁵²s are optionally bound to each other to form a ring together with carbon atoms in an aromatic ring to which these are bound; R⁵³ is a hydrocarbylene group having 1 to 10 carbon atoms and optionally containing a heteroatom; *3 and *4 each represent a point of attachment to a carbon atom in an aromatic ring in the formula, provided that *3 and *4 are bound to adjacent carbon atoms in an aromatic ring; R⁶¹ and R⁶² are each independently a halogen atom, or a hydrocarbyl group having 1 to 10 carbon atoms and optionally containing a heteroatom, and R⁶¹ and R⁶² are optionally bound to each other to form a ring together with carbon atoms to which these are bound and an atom between the carbon atoms; when n2 is 2 to 3, R⁶¹s and R⁶²s are the same as or different from each other; R⁶³ is a halogen atom, or a hydrocarbyl group having 1 to 40 carbon atoms and optionally containing a heteroatom; and when n3 is 2 to 9, R⁶³s are the same as or different from each other, and plural R⁶³s are optionally bound to each other to form a ring together with carbon atoms in an aromatic ring to which these are bound.

4. The resist composition according to claim 2, further comprising at least one of a hypervalent iodine compound represented by the following formula (4) or (5): 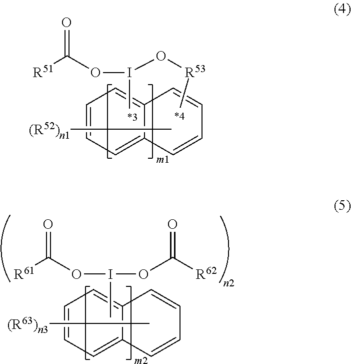
wherein m1 and m2 are each an integer of 0 to 2, and n1 is an integer of 0 to 4 when m1 is 0, n1 is an integer of 0 to 6 when m1 is 1, and n1 is an integer of 0 to 8 when m1 is 2; when m2 is 0, n2 is an integer of 1 to 3, n3 is an integer of 0 to 5, and 1≤(n2+n3)≤6 is satisfied; when m2 is 1, n2 is an integer of 1 to 3, n3 is an integer of 0 to 7, and 1≤(n2+n3)≤8 is satisfied; when m2 is 2, n2 is an integer of 1 to 3, n3 is an integer of 0 to 9, and 1≤(n2+n3)≤10 is satisfied; R⁵¹ is a halogen atom, or a hydrocarbyl group having 1 to 10 carbon atoms and optionally containing a heteroatom; R⁵² is a halogen atom, or a hydrocarbyl group having 1 to 40 carbon atoms and optionally containing a heteroatom; when n1 is 2 to 8, R⁵²s are the same as or different from each other, and plural R⁵²s are optionally bound to each other to form a ring together with carbon atoms in an aromatic ring to which these are bound; R⁵³ is a hydrocarbylene group having 1 to 10 carbon atoms and optionally containing a heteroatom; *3 and *4 each represent a point of attachment to a carbon atom in an aromatic ring in the formula, provided that *3 and *4 are bound to adjacent carbon atoms in an aromatic ring; R⁶¹ and R⁶² are each independently a halogen atom, or a hydrocarbyl group having 1 to 10 carbon atoms and optionally containing a heteroatom, and R⁶¹ and R⁶² are optionally bound to each other to form a ring together with carbon atoms to which these are bound and an atom between the carbon atoms; when n2 is 2 to 3, R⁶¹s and R⁶²s are the same as or different from each other; R⁶³ is a halogen atom, or a hydrocarbyl group having 1 to 40 carbon atoms and optionally containing a heteroatom; and when n3 is 2 to 9, R⁶³s are the same as or different from each other, and plural R⁶³s are optionally bound to each other to form a ring together with carbon atoms in an aromatic ring to which these are bound.

5. A laminate comprising a substrate, and a resist film formed on the substrate, the resist film being a film made of the resist composition according to claim 1.

6. A laminate comprising a substrate, and a resist film formed on the substrate, the resist film being a film made of the resist composition according to claim 2.

7. A laminate comprising a substrate, and a resist film formed on the substrate, the resist film being a film made of the resist composition according to claim 3.

8. The laminate according to claim 5, further comprising a resist underlayer film between the substrate and the resist film.

9. The laminate according to claim 6, further comprising a resist underlayer film between the substrate and the resist film.

10. The laminate according to claim 7, further comprising a resist underlayer film between the substrate and the resist film.

11. The laminate according to claim 5, wherein the resist film contains a product of a ligand exchange reaction between the hypervalent iodine compound and a carboxy group-containing compound.

12. The laminate according to claim 6, wherein the resist film contains a product of a ligand exchange reaction between the hypervalent iodine compound and a carboxy group-containing compound.

13. A patterning process comprising the steps of: forming a resist film on a substrate or a resist underlayer film on a substrate on which the resist underlayer film is laminated, with the resist composition according to claim 1; exposing the resist film to a high energy line, and developing the exposed resist film with a developer.

14. A patterning process comprising the steps of: forming a resist film on a substrate or a resist underlayer film on a substrate on which the resist underlayer film is laminated, with the resist composition according to claim 2; exposing the resist film to a high energy line, and developing the exposed resist film with a developer.

15. A patterning process comprising the steps of: forming a resist film on a substrate or a resist underlayer film on a substrate on which the resist underlayer film is laminated, with the resist composition according to claim 3; exposing the resist film to a high energy line, and developing the exposed resist film with a developer.

16. The patterning process according to claim 13, wherein an i-line, a KrF excimer laser, an ArF excimer laser, an electron beam or an extreme-ultraviolet ray is used as the high energy line.

17. The patterning process according to claim 13, wherein a developer that dissolves an exposed area and that does not dissolve an unexposed area is used as the developer.

18. The patterning process according to claim 16, wherein a developer that dissolves an exposed area and that does not dissolve an unexposed area is used as the developer.

19. The patterning process according to claim 13, wherein a developer that dissolves an unexposed area and that does not dissolve an exposed area is used as the developer.

20. The patterning process according to claim 16, wherein a developer that dissolves an unexposed area and that does not dissolve an exposed area is used as the developer.
